(19) United States
(12) Patent Application Publication
(10) Pub. No.: US 2023/0059013 A1
(43) Pub. Date: Feb. 23, 2023

(54) LIGHT SOURCE MODULE

(71) Applicant: Nuvoton Technology Corporation Japan, Kyoto (JP)

(72) Inventors: Masayuki HATA, Osaka (JP); Kazuhiko YAMANAKA, Osaka (JP); Kiyoshi FUJIHARA, Shiga (JP); Shinji YOSHIDA, Shiga (JP)

(21) Appl. No.: 17/982,886

(22) Filed: Nov. 8, 2022

Related U.S. Application Data
(63) Continuation of application No. PCT/JP2021/018078, filed on May 12, 2021.

(30) Foreign Application Priority Data
May 14, 2020 (JP) 2020-085548

(51) Int. Cl. H01S 5/02257; H01S 5/042; H01S 5/10; H01S 5/40; H01S 5/183

(52) U.S. Cl. CPC H01S 5/02257; H01S 5/04256; H01S 5/1092; H01S 5/4012; H01S 5/18361; H01S 5/18388

(57) ABSTRACT

A light source module includes a first semiconductor laser element hermetically sealed, a second semiconductor laser element hermetically sealed, and firth to fourth optical elements. A first laser beam prior to reaching the first optical element has divergence angle θfd1 in a direction along a second optical axis and divergence angle θsd1 in a direction along a third optical axis, and satisfy 90°>θfd1>θsd1>0°. Divergence angle θfd12 of a first laser beam in the direction along the second optical axis decreases from divergence angle θfd1, the first laser beam having exited the first optical element. A component of a first laser beam in the direction along the second optical axis is collimated, the first laser beam having exited the second optical element. The same applies to the second semiconductor laser element.

### CROSS REFERENCE TO RELATED APPLICATIONS

This is a continuation application of PCT International Application No. PCT/JP2021/018078 filed on May 12, 2021, designating the United States of America, which is based on and claims priority of Japanese Patent Application No. 2020-085548 filed on May 14, 2020, The entire disclosures of the above-identified applications, including the specifications, drawings and claims are incorporated herein by reference in their entirety.

### FIELD

The present disclosure relates to a light source module.

### BACKGROUND

Patent Literature (PTL) 1 discloses a light source module that includes a semiconductor laser element and combines laser beams emitted from the semiconductor laser element.

FIG. 49 is a perspective view of a configuration of conventional light source module 1z.

Conventional light source module 1z includes semiconductor laser element 11z mounted above each of submounts 50z, Submount 50z is disposed above each step of multistep base 5z including stair-like steps provided to case 2z.

Semiconductor laser element 11z, lens 320z, lens 350z, and reflecting mirror 370z are fixed to each step of multistep base 5z. Lens 320z and lens 350z collimate laser beams emitted from each of semiconductor laser elements 11z in a vertical axis direction and a horizontal axis direction, respectively.

Reflecting mirrors 370z disposed at the respective steps of multistep base 5z combine laser beams emitted from semiconductor laser elements 11z, and lens 380z focuses the laser beams onto an end face portion of optical fiber 4z.

In the conventional technique, in order to decrease the beam width of laser beams in the vertical axis direction and collimate the laser beams, it is necessary to dispose lens 320z, which is a first collimating optical element, and laser emission point 60z of semiconductor laser element 11z not only in precise positions but also in close proximity to each other.

However, it is difficult to fix laser emission point 60z of semiconductor laser element 11z completely in a predetermined position within an error of several microns or submicrons.

Accordingly, the positions of optical components such as lenses 320z and 350z are adjusted relative to laser emission point 60z of semiconductor laser element 11z with high precision, and the optical components are fixed with a resin-based adhesive such as an ultraviolet curable adhesive.

In the meantime, conventional light source module 1z has a structure in which semiconductor laser elements 11z are hermetically sealed in case 2z. In conventional light source module 1z, however, those elements are hermetically sealed together with optical components such as lenses 320z, 350z, and 380z and reflecting mirror 370z. In other words, in case 2z, semiconductor laser elements 11z are exposed to the optical components of a light collection optical system.

### CITATION LIST

### Patent Literature

PTL 1: Japanese Unexamined Patent Application Publication No, 2013-235943

### SUMMARY

### Technical Problem

In such a case, since the optical components have a large surface area, contamination etc. on the surface of the optical components easily becomes foreign objects in case 2z. Moreover, if a resin-based adhesive is used to fix the optical components, impurities contained in the resin etc. are released into the atmosphere. The contamination on the surface of the optical components and the impurities contained in the resin may attach to semiconductor laser element 11z as foreign objects. The attachment of the foreign objects to semiconductor laser element 11z can degrade the performance of semiconductor laser element 11z. For these reasons, according to the conventional technique, it is difficult to achieve a compact light source module that inhibits the deterioration of semiconductor laser elements and has high laser beam coupling efficiency in an object.

In view of this, the present disclosure has an object to provide a compact light source module that inhibits the deterioration of semiconductor laser elements and has high laser beam coupling efficiency in an object.

### Solution to Problem

In order to achieve the above object, a light source module according to one aspect of the present disclosure comprises: a first semiconductor laser module including a first semiconductor laser element hermetically sealed and a first optical element on which a first laser beam emitted from the first semiconductor laser element is incident; a second optical element on which the first laser beam having passed through the first optical element is incident; a second semiconductor laser module including a second semiconductor laser element hermetically sealed and a third optical element on which a second laser beam emitted from the second semiconductor laser element is incident; and a fourth optical element on which the second laser beam having passed through the third optical element is incident, wherein the first laser beam having passed through the second optical element and the second laser beam having passed through the fourth optical element are combined, a traveling direction of the first laser beam along a first optical axis is defined as a first direction, the first optical axis being an optical axis from the first semiconductor laser element to the second optical element, the first laser light has a second optical axis perpendicular to the first direction, and a third optical axis perpendicular to the first direction and the second optical axis, the first optical element has power along the second optical axis greater than power along the third optical axis, the first laser beam prior to reaching the first optical element has a first divergence angle θfd1 and a second divergence angle θsd1, the first divergence angle θfd1 being a divergence angle in a direction along the second optical axis, the second divergence angle θsd1 being a divergence angle in a direction along the third optical axis, the first divergence angle θfd1 and the second divergence angle θsd1 satisfy 90°>θfd1>θsd1>0, a third divergence angle θfd12 decreases from the first divergence angle θfd1, the third divergence angle θfd12 being a divergence angle of the first laser beam exiting the first optical element in the direction along the second optical axis, a component of the first laser beam in the direction along the second optical axis are collimated, the first laser beam exiting the second optical element, a traveling direction of the second laser beam along a fourth optical axis is defined as a second direction, the fourth optical axis being an optical axis from the second semiconductor laser element to the fourth optical element, the second laser beam has a fifth optical axis perpendicular to the second direction, and a sixth optical axis perpendicular to the second direction and the fifth optical axis, the third optical element has power along the fifth optical axis greater than power along the sixth optical axis, the second laser beam prior to reaching the third optical element has a fourth divergence angle θfd2 and a fifth divergence angle θsd2, the fourth divergence angle θfd2 being a divergence angle in a direction along the fifth optical axis, the fifth divergence angle θsd2 being a divergence angle in a direction along the sixth optical axis, the fourth divergence angle θfd2 and the fifth divergence angle θsd2 satisfy 90°>θfd2>θsd2>0, a sixth divergence angle θfd22 decreases from the fourth divergence angle θfd2, the sixth divergence angle θfd22 being a divergence angle of the second laser beam exiting the third optical element in the direction along the fifth optical axis, and a component of the second laser beam in the direction along the fifth optical axis is collimated, the second laser beam exiting the fourth optical element.

Moreover, a light source module according to one aspect of the present disclosure comprises: a semiconductor laser module including a first semiconductor laser element hermetically sealed, a second semiconductor laser element hermetically sealed, a first optical element on which a first laser beam emitted from the first semiconductor laser element is incident, and a third optical element on which second laser beam emitted from the second semiconductor laser element is incident; a second optical element on which the first laser beam having passed through the first optical element is incident; and a fourth optical element on which the second laser beam having passed through the third optical element is incident, wherein the first laser beam having passed through the second optical element and the second laser beam having passed through the fourth optical element are combined, a traveling direction of the first laser beam along a first optical axis is defined as a first direction, the first optical axis being an optical axis from the first semiconductor laser element to the second optical element, the first laser beam has a second optical axis perpendicular to the first direction, and a third optical axis perpendicular to the first direction and the second optical axis, the first optical element has power along the second optical axis greater than power along the third optical axis, the first laser beam prior to reaching the first optical element has a first divergence angle θfd1 and a second divergence angle θsd1, the first divergence angle θfd1 being a divergence angle in a direction along the second optical axis, the second divergence angle θsd1 being a divergence angle in a direction along the third optical axis, the first divergence angle θfd1 and the second divergence angle θsd1 satisfy 90°>θfd1>θsd1>0, a third divergence angle θfd12 decreases from the first divergence angle θfd1, the third divergence angle θfd12 being a divergence angle of the first laser beam exiting the first optical element in the direction along the second optical axis, a component of the first laser beam in the direction along the second optical axis is collimated, the first laser beam exiting the second optical element, a traveling direction of the second laser beam along a fourth optical axis is defined as a second direction, the fourth optical axis being an optical axis from the second semiconductor laser element to the fourth optical element, the second laser beam has a fifth optical axis perpendicular to the second direction, and a sixth optical axis perpendicular to the second direction and the fifth optical axis, the third optical element has power along the fifth optical axis greater than power along the sixth optical axis, the second laser beam prior to reaching the third optical element has a fourth divergence angle θfd2 and a fifth divergence angle θsd2, the fourth divergence angle θfd2 being a divergence angle in a direction along the fifth optical axis, the fifth divergence angle θsd2 being a divergence angle in a direction along the sixth optical axis, the fourth divergence angle θfd2 and the fifth divergence angle θsd2 satisfy 90° θfd2>θsd2>0, a sixth divergence angle θfd22 decreases from the fourth divergence angle θfd2, the sixth divergence angle θfd22 being a divergence angle of the second laser beam exiting the third optical element in the direction along the fifth optical axis, and a component of the second laser beam in the direction along the fifth optical axis is collimated, the second laser beam exiting the fourth optical element.

### Advantageous Effects

The present disclosure achieves a compact light source module that inhibits the deterioration of semiconductor laser elements and has high laser beam coupling efficiency in an object.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a perspective view of a configuration of a light source module according to Embodiment 1,

FIG. 2 is a perspective view of a configuration of a first semiconductor laser module according to Embodiment 1.

FIG. 3 is a cross-sectional view of the configuration of the first semiconductor laser module according to Embodiment 1.

FIG. 4A is a schematic diagram illustrating an optical system of the first semiconductor laser module according to Embodiment 1.

FIG. 4B is an enlarged view of the optical system in the vicinity of the first semiconductor laser module according to Embodiment 1,

FIG. 4C is an enlarged view of an optical system in the vicinity of a second semiconductor laser module according to Embodiment 1,

FIG. 5 is a schematic diagram illustrating steps of a method of manufacturing the first semiconductor laser module according to Embodiment 1.

FIG. 6 is an exploded diagram illustrating components of the first semiconductor laser module according to Embodiment 1.

FIG. 7 is a perspective view for illustrating a method of adjusting positions of a second optical element and a fifth optical element according to Embodiment 1,

FIG. 8A is a cross-sectional view of the first semiconductor laser module and its surroundings according to Embodiment 1.

FIG. 8B is a cross-sectional view of a first semiconductor laser module and its surroundings according to the first example of Embodiment 1.

FIG. 8C is a cross-sectional view of a first semiconductor laser module and its surroundings according to the second example of Embodiment 1.

FIG. 9A is a cross-sectional view of a first semiconductor laser module and its surroundings according to Comparative Example 1.

FIG. 9B is a cross-sectional view of a first semiconductor laser module and its surroundings according to Comparative Example 2.

FIG. 10A is a schematic diagram illustrating the periphery of an optical fiber according to Embodiment 1.

FIG. 10B is a schematic diagram illustrating the periphery of an optical fiber according to Comparative Example 1.

FIG. 11 is a perspective view of a configuration of a light source module according to Embodiment 2.

FIG. 12A is a schematic diagram illustrating an optical system of a first semiconductor laser module according to Embodiment 2.

FIG. 12B is a schematic diagram illustrating convergence angles according to Embodiment 2.

FIG. 13 is an exploded perspective view of a configuration of the first semiconductor laser module included in the light source module according to Embodiment 2.

FIG. 14 is a perspective view for illustrating a method of adjusting positions of a second optical element and a fifth optical element according to Embodiment 2.

FIG. 15 is a diagram illustrating incident light amount distributions of laser beams prior to reaching a twelfth optical element after exiting a seventh optical element according to Embodiments 1 and 2.

FIG. 16 is a cross-sectional view of a configuration of a first semiconductor laser module included in a light source module according to Variation 1 of Embodiment 2.

FIG. 17 is a schematic diagram illustrating the configuration of the first semiconductor laser module and a method of manufacturing the same according to Variation 1 of Embodiment 2.

FIG. 18 is a cross-sectional view of a configuration of a first semiconductor laser module included in a light source module according to Variation 2 of Embodiment 2.

FIG. 19 is a schematic diagram illustrating a method of manufacturing the first semiconductor laser module according to Variation 2 of Embodiment 2.

FIG. 20 is a schematic diagram illustrating an optical system of a first semiconductor laser module included in a light source module according to Variation 3 of Embodiment 2.

FIG. 21A is a schematic diagram illustrating one example of a method of manufacturing the first semiconductor laser module according to Variation 3 of Embodiment 2.

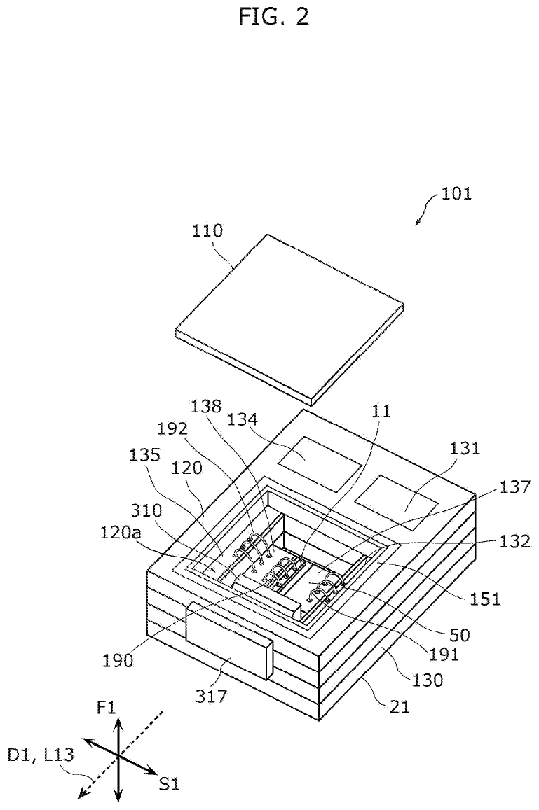

FIG. 2B is a schematic diagram illustrating another example of the method of manufacturing the first semiconductor laser module according to Variation 3 of Embodiment 2.

FIG. 22 is a schematic diagram illustrating an optical system of a first semiconductor laser module included in a light source module according to Variation 4 of Embodiment 2.

FIG. 23 is a cross-sectional view of an optical system of a first semiconductor laser module included in a light source module according to Variation 5 of Embodiment 2.

FIG. 24 is a schematic diagram illustrating an optical system of a first semiconductor laser module included in a light source module according to Variation 6 of Embodiment 2.

FIG. 25 is a schematic diagram illustrating an optical system of a first semiconductor laser module included in a light source module according to Variation 7 of Embodiment 2.

FIG. 26 is a schematic diagram illustrating an optical system of a first semiconductor laser module included in a light source module according to Variation 8 of Embodiment 2.

FIG. 27 is a schematic diagram illustrating an optical system of a first semiconductor laser module included in a light source module according to Variation 9 of Embodiment 2.

FIG. 28 is a schematic diagram illustrating an optical system of a first semiconductor laser module included in a light source module according to Variation 10 of Embodiment 2.

FIG. 29 is a perspective view of an optical system of a light source module according to Embodiment 3.

FIG. 30 is a cross-sectional view of a cross section of the optical system of the light source module according to Embodiment 3, taken along line XXX-XXX shown in FIG. 29.

FIG. 31 is a perspective view of a configuration of one light source module included in the light source module according to Embodiment 3.

FIG. 32A is a perspective view of a configuration of one semiconductor laser module included in a light source module according to Variation 1 of Embodiment 3.

FIG. 32B is a schematic cross-sectional view of a configuration of the surroundings of one semiconductor laser element included in the one semiconductor laser module according to Variation 1 of Embodiment 3.

FIG. 33 is a diagram illustrating a configuration of one semiconductor laser module included in a light source module according to Variation 2 of Embodiment 3.

FIG. 34 is a perspective view of a configuration of a light source module according to Embodiment 4.

FIG. 35A is a perspective view of one example of an optical system of the light source module according to Embodiment 4.

FIG. 35B is a perspective view of a configuration of the surroundings of a first semiconductor laser module according to Embodiment 4.

FIG. 36 is a schematic diagram illustrating the optical system of the light source module according to Embodiment 4.

FIG. 37A is a perspective view of a state in which the first semiconductor laser module according to Embodiment 4 is disposed,

FIG. 37B is a perspective view of a state in which a semiconductor laser module unit according to Embodiment 4 is fixed.

FIG. 37C is a perspective view for illustrating a method of adjusting positions of a second optical element and a fifth optical element according to Embodiment 4.

FIG. 38 is a perspective view of a configuration of the surroundings of a first semiconductor laser module according to Variation 1 of Embodiment 4.

FIG. 39 is a schematic diagram illustrating an optical system of a light source module according to Variation 2 of Embodiment 4.

FIG. 40 is a perspective view of a configuration of the surroundings of a first semiconductor laser module according to Variation 2 of Embodiment 4.

FIG. 41 is a perspective view of a configuration of a light source module according to Embodiment 5.

FIG. 42 is a perspective view of a configuration of a light source module according to Variation 1 of Embodiment 5.

FIG. 43 is a perspective view of a configuration of a first semiconductor laser module according to Embodiment 6.

FIG. 44 is a schematic diagram illustrating a method of manufacturing the first semiconductor laser module according to Embodiment 6.

FIG. 45 is a perspective view of a configuration of a first semiconductor laser module according to Embodiment 7,

FIG. 46 is a perspective view of a configuration of a first semiconductor laser module according to Embodiment 8,

FIG. 47 is a schematic diagram illustrating an optical system of a light source module according to Embodiment 8.

FIG. 48 is a perspective view of a configuration of first semiconductor laser module 101x according to Embodiment 9.

FIG. 49 is a perspective view of a configuration of a conventional light source module.

### DESCRIPTION OF EMBODIMENTS

Hereinafter, light source modifies according to embodiments of the present disclosure will be described with reference to the drawings. It should be noted that each of the subsequently-described embodiments shows a specific example of the present disclosure. The numerical values, shapes, materials, constituent elements, the arrangement and connection of the constituent elements, steps and the order of the steps, etc. shown in the following embodiments are mere examples, and are not intended to limit the scope of the present disclosure.

The respective figures are schematic diagrams and are not necessarily precise illustrations. Therefore, for example, the scales etc. in the respective figures are not necessarily uniform. Additionally, in the drawings, substantially identical components are assigned the same reference signs, and overlapping description is omitted or simplified.

In the present specification, terms indicating relationships between structural elements, such as “equal to”, terms indicating shapes of structural elements, such as “plate shape” or “curved shape”, and numerical ranges not only refer to their strict meanings, but also include a scope of essential equivalents, such as a difference of approximately several percent.

Moreover, in the present specification, terms such as “above” (or “upper”) and “below” (or “lower”) do not indicate the upward direction (vertically upward) and the downward direction (vertically downward) in an absolute spatial sense, respectively, but rather are used as terms defining relative positional relationships based on layering orders in layered configurations. Furthermore, terms such as “above” and “below” are used not only in cases where two constituent elements are disposed with an interval therebetween and another constituent element is present between the stated two constituent elements, but also in cases where two constituent elements are disposed in close contact with each other.

Moreover, in the present specification and the figures, the following provides definitions regarding a first laser beam emitted from a first semiconductor laser element and reaching an object. An optical axis from the first semiconductor laser element to first, second, fifth, and seventh optical elements is defined as a first optical axis, and a traveling direction of the first laser beam on the first optical axis is defined as a first direction. In addition, a fast axis of the first laser beam is defined as a second optical axis, and a slow axis of the first laser beam is defined as a third optical axis. It should be noted that the first direction is perpendicular to the second optical axis, and the third optical axis is perpendicular to the first direction and the second optical axis.

Furthermore, the following provides definitions regarding a second laser beam emitted from a second semiconductor laser element and reaching an object. An optical axis from the second semiconductor laser element to third, fourth, sixth, and seventh optical elements is defined as a fourth optical axis. A traveling direction of the second laser beam on the fourth optical axis is defined as a second direction. A fast axis of the second laser beam is defined as a fifth optical axis, and a slow axis of the second laser beam is defined as a sixth optical axis. It should be noted that the second direction is perpendicular to the fifth optical axis, and the sixth optical axis is perpendicular to the second direction and the fifth optical axis.

Moreover, the x-axis, the y-axis, and the z-axis represent the three axes in a three-dimensional orthogonal coordinate system regarding the first semiconductor laser element, and an x direction, a y direction, and a z direction indicate positive directions along the x-axis, the y-axis, and the z-axis.

Furthermore, the ξ-axis, the η-axis, and the ζ-axis represent the three axes in a three-dimensional orthogonal coordinate system regarding the first semiconductor laser element, and a ξ direction, a η direction, and a ζ direction indicate positive directions along the ξ-axis, the η-axis, and the ζ-axis.

In each embodiment and each variation, a traveling direction of a first laser beam, which has just been emitted from the first semiconductor laser element, along the first optical axis is the z direction, a direction of the first laser beam parallel to the second optical axis is the x direction, and a direction of the first laser beam parallel to the third optical axis is the y direction.

In addition, a traveling direction of a first laser beam, which has just been emitted from the first semiconductor laser element, along the first optical axis may be referred to as the ζ direction, a direction of the first laser beam parallel to the second optical axis may be referred to as the ξ direction, and a direction of the first laser beam parallel to the third optical axis may be referred to as the η direction. (It should be noted that if the ξ direction, the η direction, and the ζ direction are not illustrated, the ξ direction, the η direction, and the ζ direction coincide with the x direction, the y direction, and the x direction, respectively.

Accordingly, if a traveling direction, a fast axis, and a slow axis are deflected by a laser beam passing through or being reflected by an optical element, correspondence relationships between first to sixth directions and spatial directions (e.g., the x direction and the ξ direction) change.

In the subsequently-described embodiments, the x direction and the Σ direction may be referred to using “above”, and a direction opposite to the x direction and the ξ direction may be referred to using “below”. Moreover, a surface on an upper side may be referred to as a top surface, and a surface on a lower side may be referred to as a under surface. Furthermore, in the present specification, a “plan view” refers to a view of a light source module from the x direction and the ξ direction, and a figure illustrating such a view is referred to as a “plan view”.

### Embodiment 1

### [Configuration]

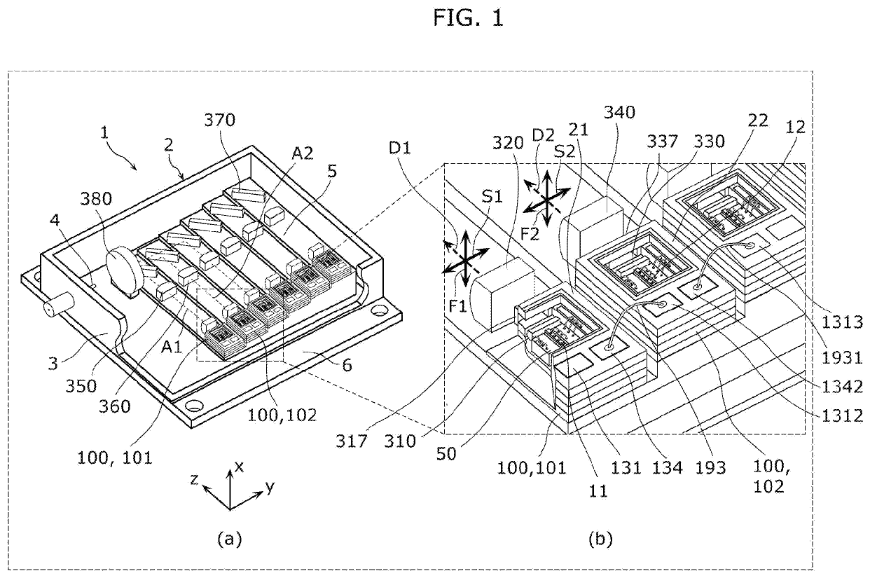

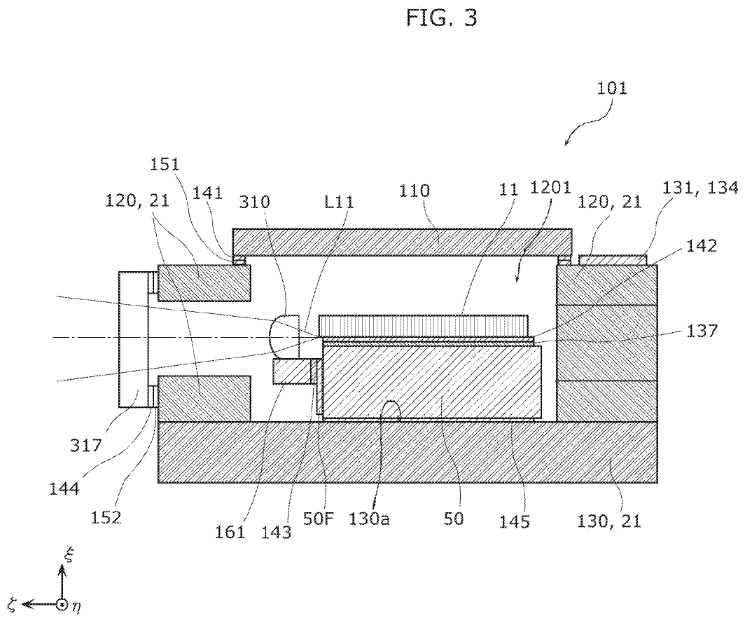

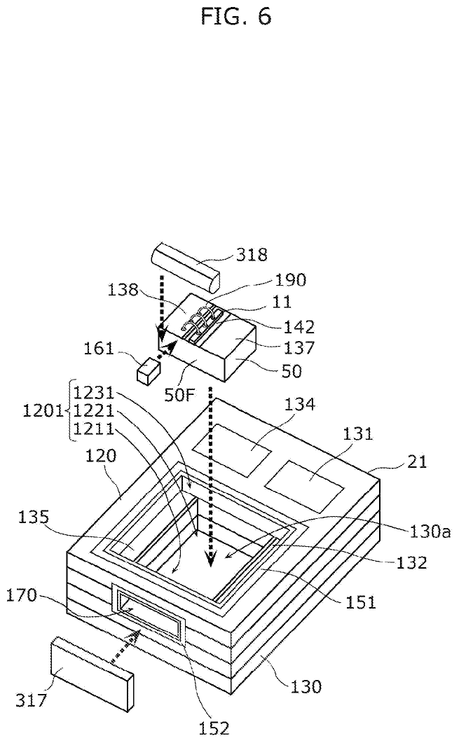

First, a configuration of a light source module according to Embodiment 1 will be described with reference to FIG. 1, FIG. 2, FIG. 3, and FIG. 6.

FIG. 1 is a perspective view of a configuration of light source module 1 according to Embodiment 1. More specifically, (a) in FIG. 1 is a perspective view of an entire configuration of light source module 1. (b) in FIG. 1 is an enlarged perspective view of semiconductor laser modules 100, FIG. 2 is a perspective view of a configuration of first semiconductor laser module 101 according to Embodiment 1, FIG. 3 is a cross-sectional view of the configuration of first semiconductor laser module 101. FIG. 6 is an exploded diagram illustrating components of first semiconductor laser module 101. In FIG. 1, a portion of side wall 3 and a portion of first package 21 for description are not shown for purposes of illustration.

It should be noted that in the Specification and Drawings, a first laser beam and a second laser beam may be referred to in the following ways.

Specifically, the first laser beam may be referred to as: first laser beam L11 prior to reaching a first optical element after being emitted from a first semiconductor laser element; first laser beam L12 prior to reaching a light-transmissive window; first laser beam L13 prior to reaching a second optical element; first laser beam L14 prior to reaching a fifth optical element; first laser beam L15 prior to reaching a seventh optical element; first laser beam L16 prior to reaching a twelfth optical element; and first laser beam L17 when passing through the twelfth optical element after having exited the seventh optical element.

Specifically, the second laser beam may be referred to as: second laser beam L21 prior to reaching a third optical element after being emitted from a second semiconductor laser element; second laser beam L22 prior to reaching a light-transmissive window; second laser beam L23 prior to reaching a fourth optical element; second laser beam L24 prior to reaching a sixth optical element; second laser beam L25 prior to reaching a seventh optical element; second laser beam L26 prior to reaching a twelfth optical element; and second laser beam L27 when passing through the twelfth optical element after having exited the seventh optical element.

It should be noted that optical axis A1, first direction D1, second optical axis F1, and third optical axis S1 may be stated with regard to the first laser beam, and that optical axis A2, second direction D2, fifth optical axis F2, and sixth optical axis S2 may be stated with regard to the second laser beam.

As shown in FIG. 1, light source module 1 includes case 2, fast axis collimator lenses (FAC lenses), slow axis collimator lenses (SAC lenses), seventh optical element 370 including reflecting mirrors, twelfth optical element 380 that is a condenser lens, optical fiber 4, and semiconductor laser modules 100. It should be noted that the FAC lenses are second optical element 320 and fourth optical element 340, and the SAC lenses are fifth optical element 350 and sixth optical element 350 in the present embodiment.

Light source module 1 is capable of causing an optical system to spatially combine and send out laser beams emitted from respective semiconductor laser modules 100.

Case 2 includes base 6, side wall 3, and a lid (not shown).

Side wall 3 is perpendicular to base 6 of case 2, Moreover, side wall 3 surrounds semiconductor laser modules 100 etc. Furthermore, side wall 3 includes terminals not shown, and the terminals electrically connect the outside and inside of case 2. Side wall 3 comprises, for example, Cu, Cu alloy, Fe—Ni—Co alloy, or Al. Base 6 comprises, for example, Cu, Cu alloy, Al, and a ceramic (e.g., AlN or BeO) having a high heat conductivity. The lid is a component covering the upper part of case 2.

Multistep base 5 including stair-like steps is provided in case 2, Semiconductor laser modules 100 are disposed on the respective steps of multistep base 5.

Semiconductor laser modules 100 each convert inputted electric power and emit a laser beam. In the present embodiment, six semiconductor laser modules 100 are provided. For purpose of identification, these semiconductor laser modules may be referred to as first to sixth semiconductor laser modules, Semiconductor laser modules 100 are arranged in a direction along third optical axis S1. Hereinafter, first semiconductor laser module 101 that is one example of semiconductor laser modules 100 will be described.

First semiconductor laser module 101 includes at least first package 21, lid 110, first semiconductor laser element 11, light-transmissive window 317, and first optical element 310. Hereinafter, first, components of first semiconductor laser module 101 will be described in detail.

### <First Package>

As shown in FIG. 1, FIG. 2, FIG. 3, and FIG. 6, first package 21 includes frame body 120, bottom 130, and a power feeding portion provided to frame body 120. In first package 21, frame body 120 is stacked on and fixed to bottom 130. In first package 21, a direction from bottom 130 toward frame body 120 is defined as the upper direction, and a surface of first package 21 in a top view is defined as a top surface.

Bottom 130 is a plate-shaped component comprising an inorganic material having a high heat conductivity. Bottom 130 may comprise a metal such as Cu or Cu alloy, or may comprise a ceramic or a polycrystalline body such as AlN, SiC, or diamond, Frame body 120 is a frame-shaped component that is mainly located only in the peripheral portion of bottom 130 and in the center of which opening 1201 (a first opening) including an opening portion is provided in a plan view. Opening 1201 is quadrilateral in a plan view. Frame body 120 comprises, as a main material, an inorganic insulating material such as alumina ceramic or MN ceramic. The top surface of a portion that is close to the central portion of bottom 130 and is not covered with frame body 120 is semiconductor laser element mounting surface 130a.

Frame body 120 includes a power feeding portion inside and on the surface. The power feeding portion includes, for example, anode extraction electrode 131, cathode extraction electrode 134, anode electrode 132, and cathode electrode 135 each including patterned metal wiring.

As shown in FIG. 6, opening 170 (a second opening) connected to opening 1201 is provided to one side surface of first package 21, and second preliminary bonding film 152 including a metal multilayer film such as Ni, Pt, or Au is provided in the vicinity of opening 170. In other words, opening 170 spatially connects opening 1201 and the outside of first semiconductor laser module 101. Moreover, first preliminary bonding film 151 comprising an inorganic material (a metal such as Ni, Pt or Au) is provided on the top surface of frame body 120, along the periphery of opening 1201.

Anode extraction electrode 131 connects anode electrode 132 and the outside of first semiconductor laser module 101. Cathode extraction electrode 134 connects cathode electrode 135 and the outside of first semiconductor laser module 101. Anode extraction electrode 131 and cathode extraction electrode 134 are provided on the top surface of frame body 120 that is across opening 1201 from light-transmissive window 317 to be described later. In other words, anode extraction electrode 131 and cathode extraction electrode 134 are disposed across opening 1201 from light-transmissive window 317 of first package 21. Anode extraction electrode 131 and cathode extraction electrode 134 are provided on the top surface of first package 21 (i.e., the top surface of frame body 120) above semiconductor laser element mounting surface 130a.

Anode electrode 132 and cathode electrode 135 electrically connect the inside of opening 1201 and the outside of first semiconductor laser module 101. A flat platform on which anode electrode 132 is provided and a flat platform on which cathode electrode 135 is provided are provided inside opening 1201. The two flat platforms are located on opposite sides of quadrilateral opening 1201, and none of the two flat platforms is located on a side on which opening 170 is provided. To put it another way, inside opening 1201, flat platforms are provided in a direction orthogonal to the direction from opening 170 toward anode extraction electrode 131, anode electrode 132 is provided on one of the flat platforms, and cathode electrode 135 is provided on the other of the flat platforms. Anode extraction electrode 131 and cathode extraction electrode 134 are configured to be electrically connected to anode electrode 132 and cathode electrode 135, respectively, with metal wirings, via electrodes, etc. Anode electrode 132, cathode electrode 135, and bottom 130 are electrically insulated from each other.

### <Lid>

Lid 110 comprises an inorganic material such as a metal or a ceramic material. A preliminary bonding film not shown such as Au is provided on part or all of the surface of lid 110, Lid 110 covers an upper portion of opening 1201.

### <First Semiconductor Laser Element>

First semiconductor laser element 11 is a laser element in which a semiconductor stacked film and an optical waveguide are provided on a semiconductor substrate, First semiconductor laser element 11 converts electric power externally inputted to the optical waveguide into stimulated emission light such as a laser beam, and causes the stimulated emission light to be emitted from a luminous point that is one end of the optical waveguide. Second optical axis F1 that is a fast axis of laser beam is in a stacking direction of the semiconductor stacked film of first semiconductor laser element 11, and third optical axis S1 that is a slow axis orthogonal to the fast axis is parallel to stacking surfaces of the semiconductor stacked film. In first semiconductor laser element 11, it is possible to change a wavelength of a first laser beam to be emitted, depending on a constituent semiconductor material. For example, if first semiconductor laser element 11 is configured as a nitride-based semiconductor laser element comprising a nitride such as Al, Ga, or In as a main component, first semiconductor laser element 11 is capable of emitting the first laser beam having a peak wavelength between a wavelength of 350 nm and a wavelength of 550 nm. Moreover, for example, if first semiconductor laser element 11 is configured as a semiconductor laser element including a semiconductor comprising Al, Ga, In, As, or P as a main component, first semiconductor laser element 11 is capable of emitting the first laser beam having a peak wavelength between a wavelength of 600 nm and a wavelength of 1600 nm. It should be noted that first semiconductor laser element 11 is not limited to the semiconductor laser elements each comprising the above-described semiconductor material, and the wavelength of the first laser beam emitted by first semiconductor laser element 11 is not limited to the above-described wavelengths.

First semiconductor laser element 11 is quadrilateral and elongated in a waveguide direction of the optical waveguide. The optical waveguide has, for example, a width of at least 5 μm and at most 300 μm, and a length of at least 500 μm and at most 5 mm. With regard to first semiconductor laser element 11, the first laser beam is a multiple transverse mode laser beam in a multimode along the slow axis.

Although first semiconductor laser element 11 is a laser element in which Fabry-Perot mirrors are provided at the both ends of an optical waveguide, the present disclosure is not limited to this example. For example, first semiconductor laser element 11 may be what is called a superluminescent diode in which no mirror is provided on a luminous point side of an optical waveguide. Moreover, first semiconductor laser element 11 may be an element used in a so-called external cavity semiconductor laser device, which performs laser oscillation by disposing a cavity mirror on a light emission direction side as a component separate from first semiconductor laser element 11, without providing a mirror on a luminous point side of an optical waveguide.

Furthermore, in the present embodiment, first semiconductor laser element 11, together with submount 50, is disposed inside opening 1201.

### <Submount>

In the present embodiment, first semiconductor laser element 11 is fixed on submount 50. Submount 50 is in a block shape and comprises crystals such as AlN or SiC or an insulating material such as a ceramic. First metal film 137 and second metal film 138 that are patterned are insulated from each other on the top surface of the block shape. Second bonding material 142 is disposed on first metal film 137, First metal film 137 and second metal film 138 each include one or more metal films among, for example, Ni, Cu, Pt, and Au. Second bonding material 142 comprises, for example, an inorganic material like a solder material such as AuSn or SnAgCu. Although submount 50 is a component different from first package 21 in the present embodiment, submount 50 may be integrally formed as part of first package 21.

### <First Optical Element>

First optical element 310 is an optical component on which the first laser beam emitted from first semiconductor laser element 11 is incident, and includes one or more optical elements. In the present embodiment, first optical element 310 includes one optical component.

First optical element 310 has power along second optical axis F1 greater than power along third optical axis S1, As an example, first optical element 310 is a cylindrical lens having a power axis and a non-power axis. The power axis and the non-power axis are perpendicular to each other, and the power axis is parallel to second optical axis F1. First optical element 310 includes a projecting curved face along the power axis, that is, a convex cylindrical face.

First optical element 310 comprises an inorganic transparent material such as glass, and includes antireflection coating films tuned in to the wavelength of the first laser beam, on an incident face and an exit face for the first laser beam. In the present embodiment, first optical element 310 is, for example, a plana-convex cylindrical lens having an incident face for the first laser beam that is flat, and an exit face for the first laser beam that is convex. Such first optical element 310 is capable of reducing a divergence angle along second optical axis F1,

### <Light-Transmissive Window>

Light-transmissive window 317 is an optical component that is fixed to first package 21 and through which the first laser beam exiting first optical element 310 passes. Light-transmissive window 317 and part of first optical element 310 may be integrally formed. Moreover, light-transmissive window 317 may be formed of a composite part obtained by fixing optical elements to a frame etc. In the present embodiment, light-transmissive window 317 is an optical component that is a quadrilateral inorganic glass plate and has an incident face and an exit face on each of which an antireflection coating film is formed.

### <Semiconductor Laser Module>

Next, a configuration of first semiconductor laser module 101 will be described, FIG. 2 is a perspective view of the configuration of first semiconductor laser module 101, and shows a state in which lid 110 is detached from first package 21 upward.

First semiconductor laser element 11 is disposed on the top surface of submount 50. At this tame, the optical waveguide of first semiconductor laser element 11 is disposed on a submount 50 side. In other words, first semiconductor laser element 11 is fixed by what is called junction-down mounting. As shown in FIG. 2, first laser beam L11 is emitted and travels from a luminous point of first semiconductor laser element 11 not shown toward first optical element 310 and light-transmissive window 317, and exits light-transmissive window 317.

The first laser beam is also light emitted by first semiconductor laser module 101. In other words, in the present embodiment, the light emitted by first semiconductor laser module 101 travels in the same direction as the first laser beam right after being emitted from first semiconductor laser element 11. Accordingly, second optical axis F1 is parallel to a stacking direction of bottom 130 and frame body 120 of first package 21. Third optical axis S1 is parallel to semiconductor laser element mounting surface 130a of bottom 130.

As shown in FIG. 3, first metal film 137 and second bonding material 142 are disposed in stated order between submount 50 and first semiconductor laser element 11. At this time, first metal film 137 is exposed on submount 50 so as to extend from between submount 50 and first semiconductor laser element 11 in a direction toward anode electrode 132. Second metal film 138 is disposed on a cathode electrode 135 side of first semiconductor laser element 11.

Submount 50 is disposed above bottom 130 and fixed via fifth bonding material 145, Fifth bonding material 145 comprises, for example, an inorganic material (e.g., a solder material such as AuSn or a metal such as Au) having a thickness of at least 1 μm and at most 50 μm.

First optical element 310 is a planoconvex cylindrical lens including a convex cylindrical face, and is disposed so as to cause a power axis and a non-power axis to be parallel to second optical axis F1 of the first laser beam and third optical axis S1, respectively. As a result, first optical element 31 is a lens having power only relative to a fast axis of incident light, and serves as an FA lens. An FA lens is capable of controlling a divergence angle along a fast axis of a laser beam.

First optical element 310 is provided above first supporting component 161.

First supporting component 161 supports first optical element 310 and includes a glass block. More specifically, first supporting component 161 is provided to a side surface of submount 50 on a ζ direction side via metal film 50F and third bonding material 143. Third bonding material 143 comprises, for example, an inorganic material (e.g., SnSb).

Light-transmissive window 317 is fixed to first package 21 with a bonding material (hereinafter referred to as fourth bonding material 144) comprising an inorganic material, More specifically, light-transmissive window 317 is fixed to a side surface of frame body 120 on the ζ direction side via fourth bonding material 144 and second preliminary bonding film 152. To put it another way, light-transmissive window 317 serves as a window of first package 21. Light-transmissive window 317 not only hermetically seals first package 21 but also allows the first laser beam emitted from first semiconductor laser element 11 to pass to the outside of first semiconductor laser module 101. Light-transmissive window 317 is provided outside frame body 120 so as to cover opening 170. Moreover, fourth bonding material 144 comprises, for example, an inorganic material (e.g., a solder material such as AuSn). Furthermore, second preliminary bonding film 152 comprises, for example, an inorganic material (e.g., a metal such as Ni, Pt, or Au).

Lid 110 is connected to the top surface (a surface in the direction) of frame body 120 via first bonding material 141 and first preliminary bonding film 151 so as to cover opening 1201. First bonding material 141 comprises, for example, an inorganic material like a solder material such as SnAu, SnAgCu, or In. At this time, lid 110 does not cover anode extraction electrode 131 and cathode extraction electrode 134 that are provided on the top surface of frame body 120.

First semiconductor laser module 101 further includes metal wires 190, 191, and 192. First semiconductor laser element 11 and the power feeding portion of frame body 120 are electrically connected.

Specifically, metal wire 190 connects a surface of first semiconductor laser element 11 on a semiconductor substrate side and second metal film 138 of submount 50. A surface of first semiconductor laser element 11 on an optical waveguide side is electrically connected to first metal film 137 by second bonding material 142.

Metal wire 191 electrically connects first metal film 137 of submount 50 and anode electrode 132 of first package 21. Accordingly, anode electrode 132 is electrically connected to first semiconductor laser element 11 via metal wire 191, first metal film 137, and second bonding material 142.

Metal wire 192 electrically connects second metal film 138 of submount 50 and cathode electrode 135 of first package 21. Accordingly, cathode electrode 135 is electrically connected to first semiconductor laser element 11 via metal wire 192, second metal film 138, and metal wire 190.

The above-described configuration allows first semiconductor laser element 11 to connect to the outside of first package 21 via the power feeding portion including, for example, anode extraction electrode 131 and cathode extraction electrode 134.

As shown in FIG. 3, in first semiconductor laser module 101 according to the present embodiment, the above-described configuration hermetically seals first optical element 310 and first semiconductor laser element 11 within a structure composed of first package 21, lid 110, and light-transmissive window 317.

As a result, first semiconductor laser element 11 is protected from impurities such as organic substance from the outside of first package 21 while being supplied with electric power from the outside of first package 21. Accordingly, it is possible to inhibit the deterioration of first semiconductor laser element 11 caused by impurities such as organic substance attaching to the luminous point of first semiconductor laser element 11 while first semiconductor laser element 11 is in operation.

Additionally, in first package 21, each constituent element is fixed with a bonding material comprising an inorganic material such as a metal. In consequence, impurities such as organic substance are not easily precipitated around first semiconductor laser element 11. Accordingly, it is possible to inhibit the deterioration of first semiconductor laser element 11 caused by the attachment of impurities such as organic substance.

In the present embodiment, due to the above-described configuration, light-transmissive window 317 is provided to a side surface of frame body 120 in first direction D1, and first optical element 310 and first semiconductor laser element 11 are provided toward light-transmissive window 317. Such a configuration makes it possible to output the first laser beam emitted from first semiconductor laser element 11 to the outside. In addition, such a configuration allows first semiconductor laser element 11 to emit first laser beam L11 from a predetermined height, and first optical element 310, which is the FA lens, to reduce a divergence angle of first laser beam L11 along second optical axis F1 (the fast axis).

In the above-described configuration, it is possible to elongate anode electrode 132 and cathode electrode 135 in first direction D1 that is an emission direction of the first laser beam, and dispose anode electrode 132 and cathode electrode 135 at respective positions close to submount 50 in a direction orthogonal to first direction D1. Such a configuration makes it possible to provide metal wires 190, 191, and 192 easily as shown in FIG. 2, As a result, it is possible to supply higher electric power to first semiconductor laser element 11 from the outside of first package 21. Accordingly, it is possible to cause first semiconductor laser module 101 to emit a laser beam having a higher optical output.

It is desirable that first package 21 be quadrilateral and elongated in first direction D1, which is the emission direction of the first laser beam, in the above-described configuration. Anode extraction electrode 131 and cathode extraction electrode 134 are disposed across opening 1201 from light-transmissive window 317 of first package 21. Such a configuration makes it possible to dispose light-transmissive window 317 and first optical element 310 dose to a first laser beam emission portion of first semiconductor laser module 101. For this reason, it is possible to configure first semiconductor laser module 101 easily, and to increase a degree of freedom in the optical design of first semiconductor laser module 101.

It should be noted that among semiconductor laser modifies 100, second to sixth semiconductor laser modules have the same configuration as first semiconductor laser module 101 and produce the same advantageous effects as first semiconductor laser module 101.

For example, in second semiconductor laser module 102, second semiconductor laser element 12 is fixed to an opening of second package 22 via submount 50. Second semiconductor laser element 12 is hermetically sealed by second package 22, light-transmissive window 337, and lid 110. Third optical element 330 is further fixed inside second package 22. Accordingly, it is possible to cause a second laser beam emitted from second semiconductor laser element 12 to be incident on third optical element 330, have a reduced divergence angle along second optical axis F1 (the fast axis), and exit to the outside through light-transmissive window 337.

Second package 22 includes frame body 120, bottom 130, and a power feeding portion provided to frame body 120, The power feeding portion is a wiring electrically connecting the inside and outside of second package 22. Anode extraction electrode 1312 and cathode extraction electrode 1342 are provided on the top surface of second package 22 (i.e., the top surface of frame body 120). Anode extraction electrode 1312 and cathode extraction electrode 1342 are provided in positions of second package 22 opposite to an attachment position for light-transmissive window 317, relative to a semiconductor laser element mounting position.

As shown in FIG. 1, in light source module 1, cathode extraction electrode 134 of first semiconductor laser module 101 is electrically connected to anode extraction electrode 1312 of second semiconductor laser module 102 disposed adjacent to first semiconductor laser module 101, by metal wire 193. Cathode extraction electrode 1342 of second semiconductor laser module 102 is electrically connected to anode extraction electrode 1313 of third semiconductor laser module 103 disposed adjacent to second semiconductor laser module 102, by metal wire 1931. As stated above, it is possible to electrically connect adjacent semiconductor laser modules 100 in series easily in light source module 1.

In the present embodiment, first and second semiconductor laser modules 101 and 102 are arranged next to each other on multistep base 5.

A direction in which first laser beam L11 is emitted from first semiconductor laser element 11 coincides with a direction in which second laser beam L21 is emitted from second semiconductor laser element 12. At this time, first and second semiconductor laser modules 101 and 102 are quadrilateral and elongated in the direction of first and second laser beams L11 and L21. Accordingly, it is possible to dispose first and second semiconductor laser modules 101 and 102 close to each other, and to downsize light source module 1.

Similarly, since it is possible to dispose first to sixth semiconductor laser modules densely in light source module 1, it is possible to downsize light source module 1. Moreover, in the first to sixth semiconductor laser modules, anode extraction electrodes and cathode extraction electrodes are provided on sides opposite to first to sixth laser beam emission directions, on the top surfaces of first to sixth packages above semiconductor laser element mounting positions. In consequence, it is possible to electrically connect the first to sixth semiconductor laser modules in series easily using metal wires etc. Accordingly, it is possible to easily configure electrical wiring in light source module 1.

Subsequently, an optical configuration and functions of light source module 1 such as FAC lenses will be described with reference to FIG. 1.

FAC lenses and SAC lenses are sequentially disposed in a laser beam emission direction (e.g., first direction D1) of each of semiconductor laser modules 100, In other words, FAC lenses and SAC lenses are disposed in light source module 1 according to the number of semiconductor laser modules 100.

Examples of a FAC lens include second optical element 320 disposed in the laser beam emission direction of first semiconductor laser module 101, and fourth optical element 340 disposed in the laser beam emission direction of second semiconductor laser module 102. The first laser beam having passed through first optical element 310 is incident on second optical element 320, and the second laser beam having passed through third optical element 330 is incident on fourth optical element 340.

A FAC lens is a lens including a convex cylindrical face. A FAC lens is, as an example, a plano-convex cylindrical lens that comprises glass with antireflection coating films on the faces thereof includes a flat face on a laser beam incident side and has a convex shape on a laser beam emission side.

Second optical element 320 includes a projecting curved face along a power axis, that is, a convex cylindrical face. Second optical element 320 has a non-power axis orthogonal to the power axis. Fourth optical element 340 includes a projecting curved face along a power axis, that is, a convex cylindrical face. Fourth optical element 340 has a non-power axis orthogonal to the power axis.

Second optical element 320 is disposed so that the power axis is parallel to second optical axis F1 of the first laser beam, and the non-power axis is parallel to third optical axis S1, Likewise, fourth optical element 340 is disposed so that the power axis is parallel to fifth optical axis F2 of the second laser beam, and the non-power axis is parallel to sixth optical axis S2.

In other words, second optical element 320 and fourth optical element 340 are each disposed so as to be a lens having power along the fast axis of a laser beam. FAC lenses each collimate a component of an incident laser beam in a fast axis direction.

Examples of a SAC lens include fifth optical element 350 disposed in the laser beam emission direction of first semiconductor laser module 101, and sixth optical element 360 disposed in the laser beam emission direction of second semiconductor laser module 102, In other words, in the present embodiment, second optical element 320 is disposed between first optical element 310 and fifth optical element 350, and fourth optical element 340 is disposed between third optical element 330 and sixth optical element 360.

A SAC lens is a lens including a convex cylindrical face. A SAC lens is, as an example, a plano-convex cylindrical lens that comprises glass with antireflection coating films on the faces thereof.

Fifth optical element 350 includes a projecting curved face along a power axis, that is, a convex cylindrical face, Fifth optical element 350 has a non-power axis orthogonal to the power axis. Sixth optical element 360 includes a projecting curved face along a power axis, that is, a convex cylindrical face. Sixth optical element 360 has a non-power axis orthogonal to the power axis.

Fifth optical element 350 is disposed so that the power axis is parallel to third optical axis S1 of the first laser beam, and the non-power axis is parallel to second optical axis F1. Likewise, sixth optical element 360 is disposed so that the power axis is parallel to sixth optical axis S2 of the second laser beam, and the non-power axis is parallel to fifth optical axis F2, To put it another way, fifth optical element 350 and sixth optical element 360 are each a lens having power along the slow axis of a laser beam. SAC lenses each collimate a component of an incident laser beam in a slow axis direction.

According to the above-described configuration, the laser beams having been emitted from semiconductor laser modules 100 and passed through the SAC lenses become emission laser beams by being collimated in the directions along the fast axis and the slow axis, and the emission laser beams travel.

Moreover, reflecting mirrors of seventh optical element 370 are each disposed in a corresponding one of the laser beam emission directions of semiconductor laser modules 100 (e.g., first direction D1 of first semiconductor laser module 100).

Seventh optical elements 370 is an optical component on which first laser beam L11 having passed through fifth optical element 350 or second laser beam L21 having passed through sixth optical element 360 is incident. The reflecting mirrors of seventh optical element 370 reflect the respective laser beams collimated by the above-described FAC lenses and SAC lenses, and deflect the directions of the respective laser beams by 90°. The laser beams reflected by seventh optical element 370 are spatially combined so that the fast axes become the same optical axis, and reach twelfth optical element 380 fixed to base 6.

Twelfth optical element 380 is an optical component on which the first laser beam having passed through second optical element 320 and fifth optical element 350 and the second laser beam having passed through fourth optical element 340 and sixth optical element 360 are incident. In addition, twelfth optical element 380 is also an optical component on which the first laser beam and the second laser beam having passed through seventh optical elements 370 are incident. In the present embodiment, twelfth optical element 380 is a condenser lens that condenses the incident first laser beam and second laser beam (i.e., laser beams of respective semiconductor laser modules 100). Parallel laser beams whose fast axes are caused to be the same optical axis by seventh optical element 370 are incident on twelfth optical element 380. Moreover, the first laser beam and the second laser beam that are condensed by twelfth optical element 380 are incident on an end face portion of optical fiber 4 that is an example of an object. By providing such twelfth optical element 380, it is possible to efficiently condense the first laser beam and the second laser beam to the end face portion of optical fiber 4, which is the object.

Optical fiber 4 is provided to penetrate through side wall 3. The laser beams of respective semiconductor laser modules 100 condensed by seventh optical element 370 are coupled to optical fiber 4.

It should be noted that the FAC lenses that are in the same shape, the SAC lenses that are in the same shape, and seventh optical element 370 including the reflecting mirrors that are in the same shape can be used for semiconductor laser modules 100.

### [Behavior of Laser Beam]

Next, laser beams emitted from semiconductor laser modules 100 will be described. Although the following description is based on first semiconductor laser module 101 as an example, the same behavior of laser beams applies to other semiconductor laser modules 100.

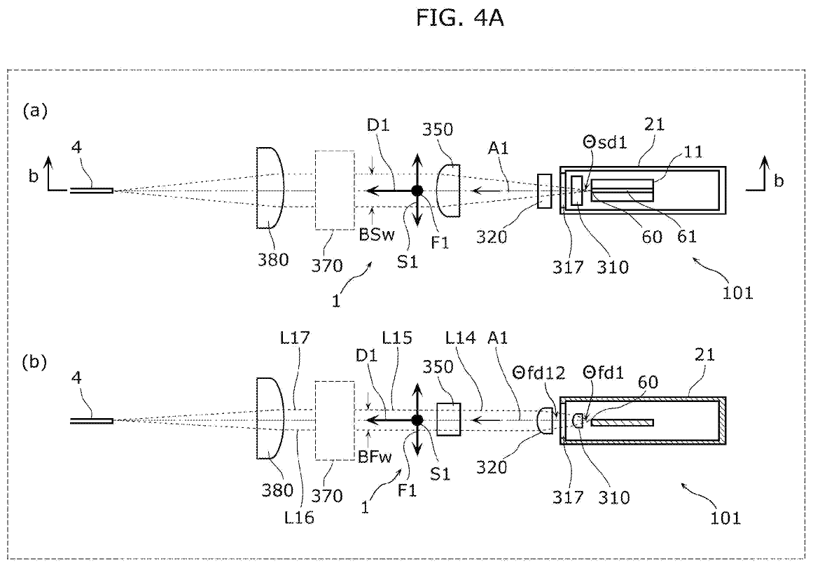

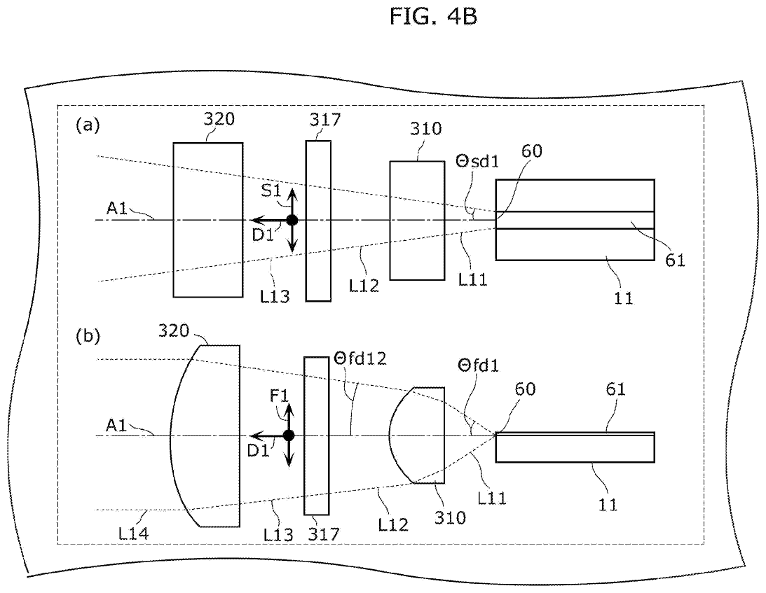

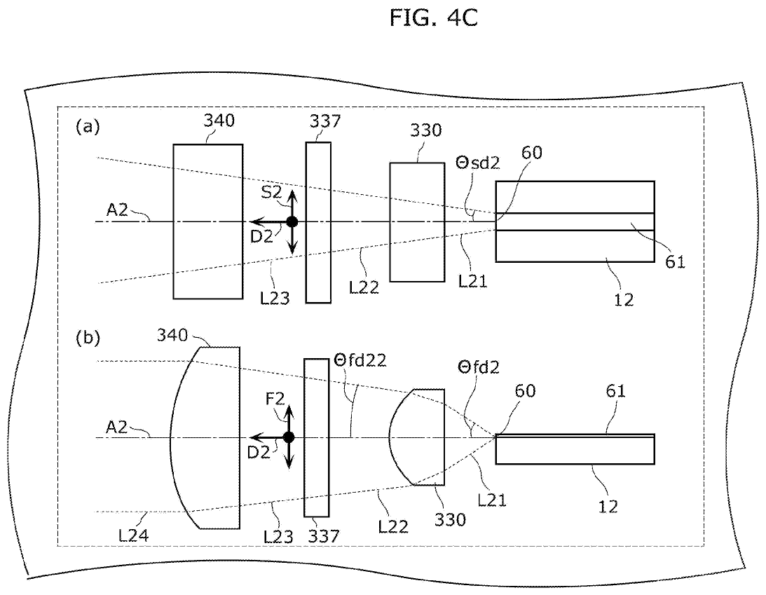

FIG. 4A is a schematic diagram illustrating an optical system of first semiconductor laser module 101. Specifically, (a) in FIG. 4A is a plan view, and (b) in FIG. 4A is a cross-sectional view of a cross section along line b-b shown in (a) in FIG. 4A. Here, in FIG. 4A, first package 21 and lid 110 are schematically illustrated as first package 21, and first semiconductor laser element 11 is hermetically sealed by first package 21 and light-transmissive window 317. Moreover, for the purpose of illustration, first semiconductor laser module 101 is shown as including what is called a junction-up configuration such that optical waveguide 61 is a top surface.

FIG. 4B is an enlarged view of the optical system in the vicinity of first semiconductor laser module 101 shown in FIG. 4A. (a) in FIG. 4B is an enlarged view of (a) in FIG. 4A, and (b) in FIG. 4B is an enlarged view of (b) in FIG. 4A.

It should be noted that although (b) in FIG. 4A and (b) in FIG. 4B are each the cross-sectional view, for ease of understanding the behavior of the first laser beam, first optical element 310, light-transmissive window 317, fifth optical element 350, and seventh optical element 370 are not hatched, Hatching may be omitted in the same manner in the subsequent figures.

As shown in FIG. 4A, first laser beam L11 emitted from luminous point 60 of optical waveguide 61 included in first semiconductor laser element 11 has a predetermined divergence angle. At this time, an emission angle dependence of a light intensity of first laser beam L11 shows that a light intensity in the vicinity of an emission angle of 0° is highest, that is, has an approximately unimodal distribution. Moreover, in FIG. 4A, the broken lines are shown in positions in which the light intensity of the first laser beam has a value of 1 (e²) of a peak value, and the divergence of the first laser beam is represented.

In the present embodiment, a divergence angle of a laser beam is an angle between optical axis A1 and a laser beam whose light intensity is a value of 1 (e²) of a peak value. Here, a divergence angle of a laser beam along the fast axis is denoted by θfd, and a divergence angle of the laser beam along the slow axis is denoted by θsd.

In the present embodiment, first laser beam L11 prior to reaching first optical element 310 has first divergence angle θfd1 along second optical axis F1 and second divergence angle θsd1 along third optical axis S1. Additionally, first laser beams L12 and L13 having passed through first optical element 310 and light-transmissive window 317 have third divergence angle θfd12 along second optical axis F1.

The divergence angles are further described in detail with reference to FIG. 4B, (a) in FIG. 4B is an enlarged view of a portion around luminous point 60 of first semiconductor laser element 11 shown in (a) in FIG. 4A, and (b) in FIG. 4B is an enlarged view of the portion around luminous point 60 of first semiconductor laser element 11 shown in (b) in FIG. 4A.

First, the behavior of the first laser beam will be described.

First divergence angle θfd1 and second divergence angle θsd1 satisfy 90°>θfd1>θsd1>0°. Specifically, first divergence angle θfd1 is in a range from 18° to 27°, and second divergence angle θsd1 is in a range from 3° to 10°, Third divergence angle θfd12 that is a divergence angle of first laser beams L12 and L13 having passed through first optical element 310 in a direction along second optical axis F1 decreases from first divergence angle θfd1. Specifically, third divergence angle θfd12 is in a range from 9° to 20°.

The second laser beam produces the same effects. Here, the second laser beam emitted by a second semiconductor laser element in second semiconductor laser module 102 will be described with reference to FIG. 4C. FIG. 4C is an enlarged view of an optical system in the vicinity of second semiconductor laser module 102. More specifically, (a) in FIG. 4C is equivalent to (a) in FIG. 4B, and (b) in FIG. 4C is equivalent to (b) in FIG. 4B.

Fourth divergence angle θfd2 of second laser beam L21 emitted from second semiconductor laser element 102 along fifth optical axis F2, and fifth divergence angle θsd2 of second laser beam L21 along sixth optical axis S2 satisfy 90°>θfd2>θsd2>0°, Specifically, fourth divergence angle θfd2 is in a range from 18° to 27°, and fifth divergence angle θsd2 is in a range from 3° to 10°. Sixth divergence angle θfd22 that is a divergence angle of second laser beams L22 and L23 having passed through third optical element 330 in a direction along third optical axis F2 decreases from fourth divergence angle θfd2. Specifically, sixth divergence angle θfd22 is in a range from 9° to 20°.

The first laser beam will be further described below.

First laser beam L13 having passed through first optical element 310 is incident on second optical element 320. Then, a component of first laser beam L14 along second optical axis F1, which has passed through second optical element 320, is collimated, A component of first laser beam L15 along third optical axis S1, which has passed through fifth optical element 350, is collimated.

Similarly, second laser beam L23 having passed through third optical element 330 is incident on fourth optical element 340. Then, a component of second laser beam L24 along fifth optical axis F2, which has passed through fourth optical element 340, is collimated. A component of the second laser beam along sixth optical axis S2, which has passed through sixth optical element 360, is collimated.

At this time, a light intensity distribution of first laser beam L15 exiting fifth optical element 350 and propagating is optically designed so that, if the width of a distribution in which a light intensity has a value of 1/(e²) of a peak value is defined as a beam width, beam width BFw along second optical axis F1 is less than beam width BSw along third optical axis S1.

First laser beam L17 collimated along both second optical axis F1 and third optical axis S1 reaches twelfth optical element 380, is condensed, and reaches the end face portion of optical fiber 4.

As stated above, first optical element 310 is provided dose to first semiconductor laser element 11 inside first package 21. As a result, the divergence angle of the first laser beam decreases from first divergence angle θfd1 to third divergence angle θfd12 before the beam width of the first laser beam greatly increases along second optical axis F1. For this reason, it is possible to decrease the beam width of first laser beam L14 along second optical axis F1 at the time when first laser beam L14 is incident on second optical element 320. Accordingly, it is possible to downsize second optical element 320. Additionally, since it is possible to decrease beam width BFw of first laser beam L15, which has passed through fifth optical element 350, along second optical axis F1, it is possible to arrange laser beams from other semiconductor laser modules 100 in the direction along second optical axis F1. Accordingly, it is possible to downsize twelfth optical element 380. In other words, it is possible to downsize the optical system of light source module 1.

Moreover, if semiconductor laser modules 100 are disposed in light source module 1, positions and orientations of semiconductor laser elements are different from each other at the time of mounting the semiconductor laser elements on semiconductor laser modules 100, and positions and orientations of semiconductor laser modules 100 are different from each other at the time of mounting semiconductor laser modules 100 on light source module 1. Consequently, positions and directions of laser beams emitted from respective semiconductor laser modules 100 vary within a mounting accuracy range. For this reason, in order to condense each laser beam to a predetermined position, it is necessary to adjust condensing positions for the respective laser beams individually. Since the FAC lenses such as second optical element 320 are located outside first package 21 etc., it is easy to adjust the positions of the FAC lenses individually. Accordingly, first laser beam L17 is efficiently condensed to a predetermined place of the end face portion of optical fiber 4, which is the object.

In addition, the SAC lenses such as fifth optical element 350 are also located outside first package 21 etc. In consequence, it is easy to adjust the positions of the SAC lenses. Accordingly, first laser beam L17 is efficiently condensed to the predetermined place of the end face portion of optical fiber 4, which is the object.

It should be noted that among semiconductor laser modifies 100, second to sixth semiconductor laser modules have the same configuration as first semiconductor laser module 101 and produce the same advantageous effects as first semiconductor laser module 101.

### [Method of Manufacturing Semiconductor Laser Module]

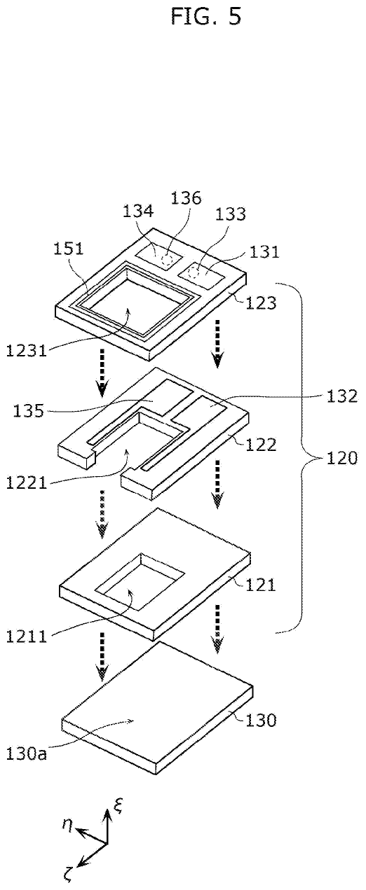

An example of a method of manufacturing semiconductor laser modules 100 will be described with reference to FIG. 2, FIG. 5, and FIG. 6, Although the following description is based on first semiconductor laser module 101 as an example, other semiconductor laser modifies 100 are manufactured by the same method.

FIG. 5 and FIG. 6 are each a schematic diagram illustrating steps of a method of manufacturing first semiconductor laser module 101. It should be noted that hereinafter placement directions etc. may be indicated by dashed arrows in the figures illustrating the manufacturing method.

First semiconductor laser module 101 is manufactured in the following order as shown in FIG. 5 and FIG. 6.

First, as shown in FIG. 5, bottom 130 and frame body 120 are stacked, and first package 21 is then formed by firmly fixing bottom 130 and frame body 120. More specifically, frame body 120 is formed by stacking first frame portion 121, second frame portion 122, and third frame portion 123.

It should be noted that first frame portion 121 is a ceramic plate in which quadrilateral opening 1211 is formed.

Moreover, second frame portion 121 is a ceramic plate in which opening 1221 that opens outward in first direction D1 is formed. Opening 1221 includes an opening portion in the same shape as opening 1211, and a notch formed toward first direction D1. It should be noted that the notch is opening 170 of first package 21. Anode electrode 132 and cathode electrode 135 are disposed on second frame portion 122. More specifically, by means of deposition, anode electrode 132 including patterned metal wiring is disposed on one end of opening 1221 in the η direction, and cathode electrode 135 including patterned metal wiring is disposed on the other end of opening 1221 in the η direction.

Furthermore, by means of deposition, anode extraction electrode 131 and cathode extraction electrode 134 each including patterned metal wiring are disposed on third frame portion 123 with space therebetween in the η direction. Third frame portion 123 is a ceramic plate in which quadrilateral opening 1231 is formed. The width of opening 1231 in the η direction is greater than the width of opening 1221 in the η direction, and the width of opening 1231 in the ζ direction is equal to the width of opening 1221 in the ζ direction. At the time of stacking, second frame portion 122 is stacked on first frame portion 121 so that opening 1211 and opening 1221 overlap each other precisely. In addition, at the time of stacking, third frame portion 123 is stacked on second frame portion 122 so that anode electrode 132 and cathode electrode 135 are exposed in opening 1231. Additionally, bottom 130 and frame body 120 are stacked so that the side surfaces of bottom 130, first frame portion 121, second frame portion 122, and third frame portion 123 in first direction D1 correspond to each other. According to the above-described configuration, opening 1201 that includes openings 1211, 1221, and 1231 and forms a connection from the top surface of first package 21 to bottom 130 and from which the surface of bottom 130 is exposed is formed in frame body 120.

Moreover, via electrodes 133 and 136 are formed in third frame portion 123 so that via electrodes 133 and 136 penetrate from the top surface to the bottom surface of third frame portion 123. Via electrodes 133 and 136 electrically connect anode extraction electrode 131 and cathode extraction electrode 134 to anode electrode 132 and cathode electrode 135, respectively.

After bottom 130, first frame portion 121, second frame portion 122, and third frame portion 123 are formed of, for example, a ceramic green sheet, first frame portion 121, second frame portion 122, and third frame portion 123 are stacked above bottom 130, and firmly fixed to bottom 130 by heat sintering. Subsequently, an Au film is formed on bottom 130 or an exposed surface of each electrode by electroless plating. In addition, second preliminary bonding film 152 is formed around opening 170 by a vacuum evaporation method etc.

In the manner described above, first package 21 in which opening 170, opening 1201, and semiconductor laser element mounting surface 130a are formed is manufactured.

Next, as shown in FIG. 6, components such as first semiconductor laser element 11 are mounted on first package 21.

First, first semiconductor laser element 11 is mounted above submount 50. At this time, first semiconductor laser element 11 is disposed on second bonding material 142 of submount 50, and is fixed thereto by being pressed while being heated.

Next, first semiconductor laser element 11 is electrically connected to second metal film 138 of submount 50 by metal wire 190.

In the meantime, light-transmissive window 317 is fixed to opening 170 of first package 21. At this time, second preliminary bonding film 152 and fourth bonding material 144 are formed in a portion around light-transmissive window 317, and light-transmissive window 317 is fixed by being pressed while heating first package 21.

Then, submount 50 on which first semiconductor laser element 11 is mounted is mounted on semiconductor laser element mounting surface 130a of bottom 130 exposed to opening 1201, via fifth bonding material 145.

After that, first optical element 310 is fixed using first supporting component 161 so that first optical element 310 has a predetermined height and distance relative to first semiconductor laser element 11. It should be noted that, at this time, in light source module 1 according to the present embodiment, a FAC lens and a SAC lens disposed outside first semiconductor laser module 101 adjust optical axis A1. As a result, in the present step, it is not necessary to use a highly precise positioning and fixation technique such as active alignment of first optical element 310. Specifically, first optical element 310 is fixed in a predetermined position of first supporting component 161 using optical contact, laser welding, or solder fixation. At this time, a metal film not shown and third bonding material 143 are formed on a semiconductor laser element side of first supporting component 161. Next, first supporting component 161 is attached to metal film 50F of submount 50 by positioning while heating first package 21 on which submount 50 is mounted, and is fixed to submount 50 by cooling. According to the above-described configuration, it is possible to easily manufacture first semiconductor laser module 101 in which first optical element 310 is disposed.

Moreover, as shown in FIG. 2, anode electrode 132 and cathode electrode 135, which are provided to frame body 120, are electrically connected to submount 50 by metal wires 191 and 192, respectively.

Then, lid 110 is disposed above first semiconductor laser element 11. First bonding material 141 along first preliminary bonding film 151 formed around opening 1201 of first package 21 is formed in a periphery of lid 110. Opening 1201 in an upper portion of first package 21 is covered with lid 110 by heating first package 21 to a predetermined temperature, disposing lid 110 in a predetermined position, and further pressing lid 110. According to such a configuration and a manufacturing method, first semiconductor laser element 11 is hermetically sealed in first package 21.

As this time, as shown in FIG. 3, all the optical components such as first semiconductor laser element 11, first optical element 310, and light-transmissive window 317 are fixed with bonding materials comprising an inorganic material.

Second bonding material 142, fourth bonding material 144, and fifth bonding material 145 that are used in the first half of the manufacturing method comprise AuSn solder having a high melting point, for example, a melting point in a range from 270° C. to 300° C. Third bonding material 143 used to fix first optical element 310 in the following step comprises SnSb solder having a lower melting point, for example, a melting point in a range from 220° C. to 250° C. First bonding material 141 for sealing first package 21 with lid 110 comprises SnAgCu solder having a much lower melting point, for example, a melting point in a range from 210° C. to 220° C. The above-described configuration makes it possible to inhibit changes in positions of the components fixed in the previous step during the next heating and fixation step.

### [Method of Adjusting Positions of FAC Lenses and SAC Lenses]

Next, a method of adjusting positions of FAC lenses and SAC lenses will be described with reference to the method of manufacturing light source module 1.

First, a manufacturing method by which first semiconductor laser module 101 etc. is disposed in case 2 will be described. As shown in FIG. 1, first semiconductor laser module 101 is fixed to one step of multistep base 5 with solder etc. Next, in case 2, optical fiber 4 is fixed in a predetermined position of side wall 3, twelfth optical element 380 is fixed to base 6, and seventh optical element 370, which is one reflecting mirror, is fixed to one step of multistep base 5.

Then, positions of second optical element 320 and fifth optical element 350 are adjusted and fixed relative to first semiconductor laser module 101.

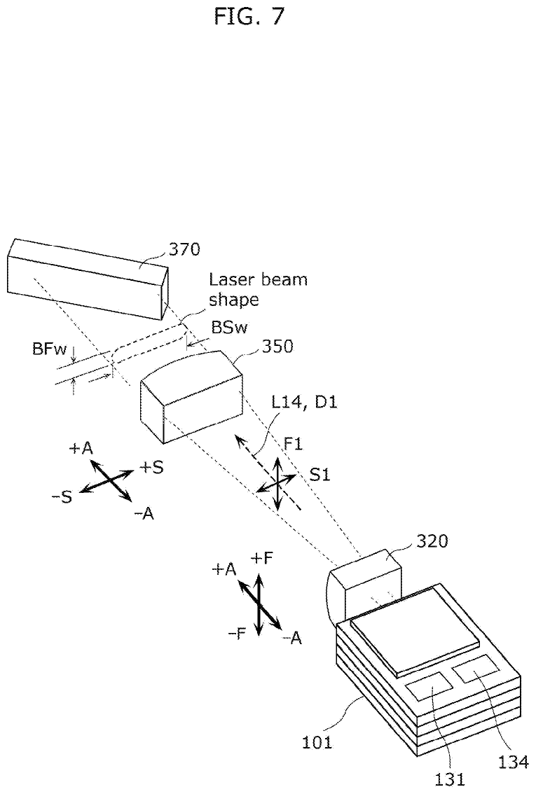

A method of adjusting the positions of second optical element 320 and fifth optical element 350 will be described with reference to FIG. 7.

FIG. 7 is a perspective view for illustrating the method of adjusting the positions of second optical element 320 and fifth optical element 350.

First, ultraviolet curing resin (not shown) is applied at predetermined positions of one step of multistep base 5, and second optical element 320 and fifth optical element 350 are disposed on the ultraviolet curing resin. Next, first semiconductor laser module 101 is caused to operate to emit a first laser beam having a predetermined amount of light. At this time, part of the first laser beam passes through second optical element 320 and fifth optical element 350, and is condensed to the end face portion of optical fiber 4 by seventh optical element 370, which is one reflecting mirror, and twelfth optical element 380.

At this time, the positions of second optical element 320 and fifth optical element 350 are adjusted while a light intensity of the first laser beam exiting the other end face portion of optical fiber 4 is monitored. Specifically, the position of second optical element 320 is slightly moved in a direction parallel to optical axis A1 (direction +A or direction −A) or a direction parallel to second optical axis F1 (direction +F or direction −F), and the position of fifth optical element 350 is slightly moved in a direction parallel to optical axis A1 (direction +A or direction −A) or a direction parallel to third optical axis S1 (direction +S or direction −S). At this time, the positions of second optical element 320 and fifth optical element 350 are adjusted so that the light intensity of the first laser beam exiting the other end of the end face portion of optical fiber 4 becomes maximum, that is, what is called an active alignment is performed. After that, second optical element 320 and fifth optical element 350 are fixed to the one step of multistep base 5 by the ultraviolet curing resin being irradiated with ultraviolet rays. FIG. 7 shows a shape of the first laser beam at that moment.

It should be noted that although first semiconductor laser module 101 has been described above, the following case occurs if semiconductor laser modules 100 are disposed as shown in FIG. 1.

First, semiconductor laser modules 100 are fixed to the respective steps of multistep base 5 with solder etc. so that semiconductor laser modules 100 can be arranged. Next, semiconductor laser modules 100 are electrically connected in series by anode extraction electrodes (e.g., anode extraction electrode 1312) and respective cathode extraction electrodes (e.g., cathode extraction electrode 134) of semiconductor laser modifies 100 being connected with respective metal wires (e.g., metal wire 193).

Then, positions of seventh optical elements 370, which are reflecting mirrors, twelfth optical elements 380, and optical fiber 4, etc. are adjusted and fixed with ultraviolet curing resin or solder, etc.

At this point of time, an emission position and an emission direction of a laser beam emitted from each of semiconductor laser modules 100 do not coincide with a predetermined emission position and a predetermined emission direction in a slow axis direction and a fast axis direction.

After that, a FAC lens (e.g., second optical element 320 or fourth optical element 340) and a SAC lens (e.g., fifth optical element 350 or sixth optical element 360) are disposed for each of semiconductor laser modules 100. The positions of the FAC lenses and the SAC lenses are adjusted and then fixed while a light intensity of a laser beam exiting the other end of optical fiber 4 is monitored. As a result, the laser beam of each of semiconductor laser modules 100 is efficiently condensed to a predetermined place of the end face portion of optical fiber 4.

### [Design Examples of FA Lens and FAC Lens]

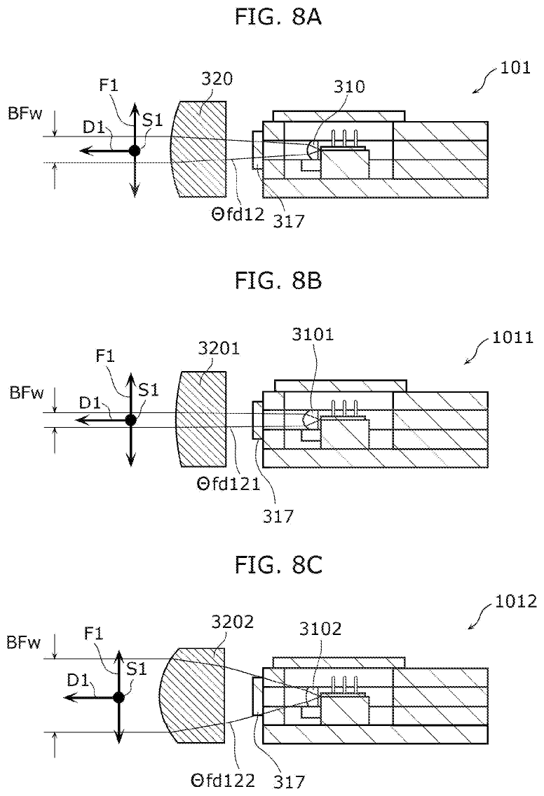

Here, examples of an FA lens and FAC lenses that are better in the present embodiment will be described with reference to FIG. 8A to FIG. BC. It should be noted that the following description is based on first optical element 310 that is an example of the FA lens, and second optical element 320 that is an example of the FAC lenses.

FIG. 8A is a cross-sectional view of first semiconductor laser module 101 and its surroundings. FIG. 8B is a cross-sectional view of first semiconductor laser module 1011 and its surroundings according to the first example of Embodiment 1, FIG. 8C is a cross-sectional view of first semiconductor laser module 1012 and its surroundings according to the second example of Embodiment 1.

FIG. 8A shows first semiconductor laser module 101 that is better designed. Specifically, third divergence angle θfd12 has a value within an appropriate range (at least 9 degrees and at most 20 degrees).

In first semiconductor laser module 1011 shown in FIG. 8B, first optical element 3101 having power along second optical axis F1 greater than that of first optical element 310 is provided. As a result, it is possible to decrease beam width BFw of a first laser beam in the direction along second optical axis F1, the first laser beam being collimated by second optical element 3201.

However, third divergence angle θfd121 is much smaller than divergence angle θfd12 of first semiconductor laser module 101, In this case, a lens having a very great focal length is required as second optical element 3201. For this reason, a range for moving second optical element 3201 for adjusting collimation and a traveling direction of the first laser beam having third divergence angle θfd121 considerably broadens, which makes the adjustment difficult.

In first semiconductor laser module 1012 shown in FIG. 8C, first optical element 3102 having power along second optical axis F1 greater than that of first optical element 310 is provided. In consequence, third divergence angle θfd122 is larger than third divergence angle θfd12 of first semiconductor laser module 101. In this case, since a focal length of second optical element 3202 decreases, it is possible to narrow a range for moving the position of second optical element 3202.

However, since third divergence angle θfd122 of the first laser beam is large even if second optical element 3202 is disposed closer to first semiconductor laser module 101, beam width BFw of the first laser beam in the direction along second optical axis F1 collimated by second optical element 3202 increases. As a result, an optical system of a light source module according to the second example increases in size.

Moreover, with regard to focal length f2 of FAC lenses of second optical element 320 and focal length f3 of SAC lenses of fifth optical element 350, a relation therebetween may satisfy f2<f3. It is possible to decrease beam width BFw in the direction along second optical axis F1 with a decrease in f2, and to inhibit an increase in the size of the optical system in light source module 1.

### Comparative Examples

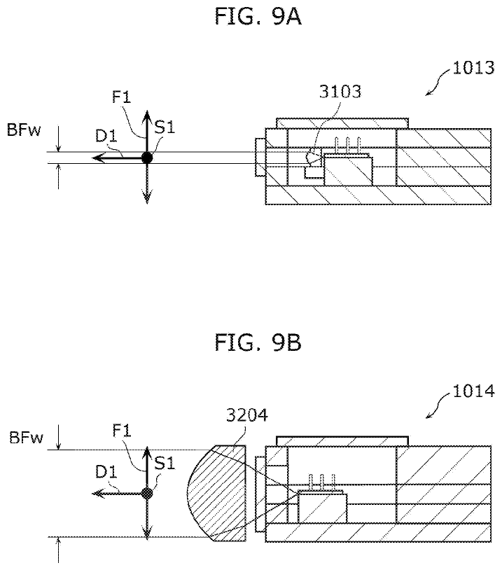

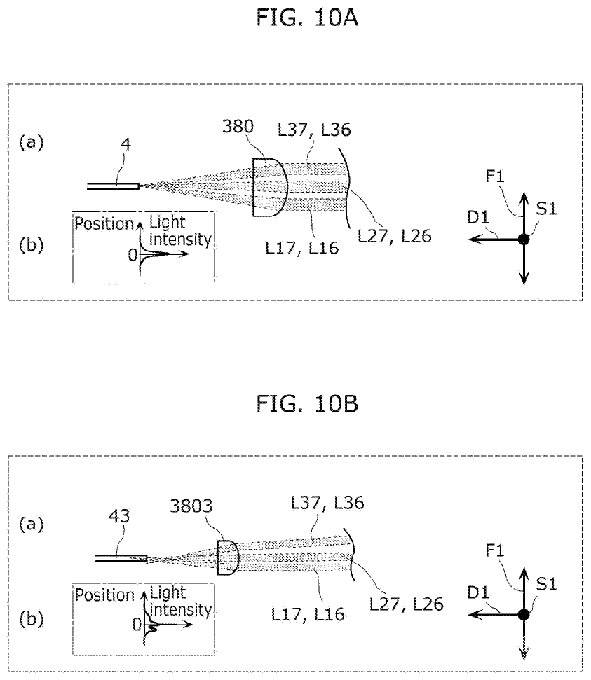

Hereinafter, the superiority of light source module 1 will be described with reference to FIG. 9A to FIG. 10B.

FIG. 9A is a cross-sectional view of first semiconductor laser module 1013 and its surroundings according to Comparative Example 1. In first semiconductor laser module 1013 according to Comparative Example 1, first optical element 3103 is a lens having power to collimate, along second optical axis F1, a first laser beam emitted from first semiconductor laser element 11. An optical element having power along second optical axis F1 is not disposed outside first semiconductor laser module 1013.

FIG. 9B is a cross-sectional view of first semiconductor laser module 1014 and its surroundings according to Comparative Example 2, In first semiconductor laser module 1014 according to Comparative Example 2, a lens having power to collimate, along second optical axis F1, a first laser beam emitted from first semiconductor laser element 11 is not disposed inside a first package. Second optical element 3204 having power along second optical axis F1 is disposed in the vicinity of light-transmissive window 317 outside first semiconductor laser module 1013,

FIG. 10A is a schematic diagram illustrating the periphery of optical fiber 4 of light source module 1 according to Embodiment 1, FIG. 10B is a schematic diagram illustrating the periphery of optical fiber 43 pf a light source module according to Comparative Example 1.

Hereinafter, the behavior of laser beams dose to twelfth optical elements 380 and 3803, and laser beam coupling efficiency in the end face portions of optical fibers 4 and 43 each of which is an object will be described. (a) in FIG. 10A and (a) in FIG. 10B are each a schematic diagram illustrating the periphery of a corresponding one of optical fibers 4 and 43, and (b) in FIG. 10A and (b) in FIG. 10B are each a light intensity distribution chart for laser beams along second optical axis F1 that are incident on a corresponding one of optical fibers 4 and 43.

It should be noted that, for simplicity, the following description is based on laser beams each emitted from a corresponding one of first semiconductor laser module 101, second semiconductor laser module 102, and a third semiconductor laser module among semiconductor laser modules 100.

Here, in FIG. 10A, laser beams emitted from first semiconductor laser module 101, second semiconductor laser module 102, and the third semiconductor laser module and reaching twelfth optical element 380 are defined as first laser beam L16, second laser beam L26, and third laser beam L36, respectively. In addition, laser beams passing through twelfth optical element 380 are defined as first laser beam L17, second laser beam L27, and third laser beam L37. In FIG. 10B, laser beams emitted from first semiconductor laser module 101, second semiconductor laser module 102, and the third semiconductor laser module and reaching twelfth optical element 3803 are defined as first laser beam L16, second laser beam L26, and third laser beam L36, respectively. In addition, laser beams passing through twelfth optical element 3803 are defined as first laser beam L17, second laser beam L27, and third laser beam L37. It should be noted that, in FIG. 10A and FIG. 10B, first laser beams L16 and L17, second laser beams L26 and L27, and third laser beams L36 and L37 are dotted.

As shown in FIG. 10A, in the present embodiment, the laser beams emitted from respective semiconductor laser modules 100 are collimated by the FAC lenses (e.g., second optical element 320 and fourth optical element 340) and the SAC lenses (e.g., fifth optical element 350 and sixth optical element 360), and are incident on twelfth optical element 380. It should be noted that, at this time, with regard to the first laser beam and the second laser beam, first diction D1 coincides with second direction D2.

As stated above, the positions of the FAC lenses and the SAC lenses are easily adjusted.

Accordingly, the laser beams emitted from respective semiconductor laser modules 100, that is, first laser beam L17, second laser beam L27, and third laser beam L37 become laser beams each of which has a fast axis overlapping the same optical axis and which are parallel to each other and are spatially combined. Such laser beams are then incident on twelfth optical element 380. It should be noted that, at this time, first laser beam L17, second laser beam L27, and third laser beam L37 each have a slow axis not overlapping the same optical axis. The laser beams incident on twelfth optical element 380 are efficiently condensed to a predetermined place of the end face portion of optical fiber 4, As shown by the light intensity distribution chart for optical fiber 4 shown in (b) in FIG. 10A, a combined light distribution that is unimodal and has a high peak intensity and a small width is obtained. In other words, the laser beams emitted from respective semiconductor laser modules 100 are incident on the end face portion of optical fiber 4 with high coupling efficiency.

In contrast, the light source module according to Comparative Example 1 has the same configuration as light source module 1 except mainly for a point that second optical element 320 is not disposed, and a point that first optical element 3103 collimates the first laser beam in the fast axis direction.

In the light source module according to Comparative Example 1 shown in FIG. 108, laser beams emitted from respective semiconductor laser modules are collimated in the fast axis direction by FAC lenses (e.g., first optical element 3103) in the vicinity of semiconductor laser elements. In this case, it is possible to decrease a beam width of the first laser beam along the fast axis. However, first optical element 3103 capable of adjusting a traveling direction of each of the laser beams emitted from the respective semiconductor laser modules is hermetically sealed in a first package. For this reason, it is difficult to adjust the traveling directions of the laser beams by adjusting the position of first optical element 3103. Moreover, an optical element equivalent to second optical element 320 is not disposed outside first semiconductor laser module 1013. As a result, it is difficult to adjust the traveling direction of the first laser beam with regard to the fast axis direction after an optical system of the light source module according to Comparative Example 1 is constructed when the light source module is manufactured. In this case, the positions of the FAC lenses such as first optical element 3103 are not precisely adjusted relative to optical axis A1 from the semiconductor laser elements to an object. Consequently, in Comparative Example 1, it is difficult to condense the laser beams emitted from the respective semiconductor laser modules to a predetermined position. Accordingly, it is difficult to cause all of first laser beam L17, second laser beam L27, and third laser beam L37 according to Comparative Example 1 to be efficiently incident on an end face portion of optical fiber 43.

For example, before first laser beam L17 and second laser beam L27 are incident on twelfth optical element 3803 shown in FIG. 10B, the traveling direction of first laser beam L17 and the traveling direction of second laser beam L27 are slightly inclined relative to the parallel state. In consequence, first laser beam L17 reaches a position away from the predetermined position in the end face portion of optical fiber 43. Moreover, collimated beam characteristics of third laser beam L37 are slightly different from those of second laser beam L27. Consequently, as shown by the light intensity distribution chart shown in (b) in FIG. 10B, a light distribution that is broad and has peaks is obtained. Accordingly, in Comparative Example 1, the light source module has low coupling efficiency in the end face portion of optical fiber 43.

Furthermore, the light source module according to Comparative Example 2 has the same configuration as light source module 1 except for a point that first optical element 310 is not disposed inside a semiconductor laser module, and second optical element 3204 is disposed in the vicinity of light-transmissive window 317.

In this case, it is possible to adjust the position of second optical element 3204. However, since the first laser beam has a large divergence angle in the fast axis direction as shown in FIG. 9B, a beam width of the first laser beam in the fast axis direction has already increased at the time of being incident on second optical element 3204. Accordingly, beam width BFw in the fast axis direction increases. If laser beams having such a large beam width are spatially coupled, it is necessary to use an optical element larger than twelfth optical element 380 according to the present embodiment or to decrease the number of laser beams to be coupled. For example, if an optical element equal in size to twelfth optical element 380 according to Embodiment 1 is used, the number of laser beams to be coupled decreases.

### [Advantageous Effects etc.]

As stated above, light source module 1 according to the present embodiment includes: first semiconductor laser module 101 including first semiconductor laser element 11 hermetically sealed and first optical element 310; second optical element 320; second semiconductor laser module 102 including second semiconductor laser element 12 hermetically sealed and third optical element 330; and fourth optical element 340. A first laser beam having passed through second optical element 320 and a second laser beam having passed through fourth optical element 340 are combined. A traveling direction of the first laser beam along a first optical axis is defined as first direction D1, the first optical axis being optical axis A1 from first semiconductor laser element 11 to second optical element 320. The first laser light has second optical axis F1 perpendicular to first direction D1, and third optical axis S1 perpendicular to first direction D1 and second optical axis F1. First optical element 310 has power along second optical axis F1 greater than power along third optical axis S1. First laser beam L11 prior to reaching first optical element 310 has first divergence angle θfd1 and second divergence angle θsd1, first divergence angle θfd1 being a divergence angle in a direction along second optical axis F1, second divergence angle θsd1 being a divergence angle in a direction along third optical axis S1. First divergence angle θfd1 and second divergence angle θsd1 satisfy 90°>θfd1>θsd1>0°. Third divergence angle θfd12 decreases from first divergence angle θfd1, third divergence angle θfd12 being a divergence angle of first laser beam L12 exiting first optical element 310 in the direction along second optical axis F1. A component of first laser beam L14 in the direction along second optical axis F1 is collimated, first laser beam L14 exiting second optical element 320. A traveling direction of the second laser beam along a fourth optical axis is defined as second direction D2, the fourth optical axis being optical axis A2 from second semiconductor laser element 12 to fourth optical element 340. The second laser beam has fifth optical axis F2 perpendicular to second direction D2, and sixth optical axis S2 perpendicular to second direction D2 and fifth optical axis F2. Third optical element 330 has power along fifth optical axis F2 greater than power along sixth optical axis S2. Second laser beam L21 prior to reaching third optical element 330 has fourth divergence angle θfd2 and fifth divergence angle θsd2, fourth divergence angle θfd2 being a divergence angle in a direction along fifth optical axis F1, fifth divergence angle θsd2 being a divergence angle in a direction along sixth optical axis S2. Fourth divergence angle θfd2 and fifth divergence angle θsd2 satisfy 90°>θfd2>θsd2>0. Sixth divergence angle θfd22 decreases from fourth divergence angle θfd2, sixth divergence angle θfd22 being a divergence angle of second laser beam L22 exiting third optical element 330 in the direction along fifth optical axis F2. A component of second laser beam L24 in the direction along fifth optical axis F2 is collimated, second laser beam+24 exiting fourth optical element 340.

In this manner, first semiconductor laser element 11 is protected from impurities such as organic substance. Accordingly, it is possible to inhibit the deterioration of first semiconductor laser element 11 caused by impurities such as organic substance attaching to the luminous point of first semiconductor laser element 11 while first semiconductor laser element 11 is in operation. The same applies to second semiconductor laser element 12.

In addition, for example, the divergence angle of the first laser beam decreases from first divergence angle θfd1 to third divergence angle θfd12 before the beam width of the first laser beam greatly increases along second optical axis F1. For this reason, it is possible to decrease the beam width of first laser beam L14 along second optical axis F1 at the time when first laser beam L14 is incident on second optical element 320. Accordingly, it is possible to downsize second optical element 320. In other words, it is possible to downsize the optical system of light source module 1. The same applies to second semiconductor laser element 12.

Additionally, as stated above, the positions of the FAC lenses are easily adjusted. As a result, for example, the first laser beam and the second laser beam having exited the FAC lenses pass through twelfth optical element 380 and are efficiently condensed to the predetermined place of the end face portion of optical fiber 4. To put it another way, the laser beams emitted from respective semiconductor laser modules 100 can be incident on an object (the end face portion of optical fiber 4) with high coupling efficiency.

To summarize the above, it is possible to achieve compact light source module 1 that inhibits the deterioration of first and second semiconductor laser elements 11 and 12 and has the high laser beam coupling efficiency in the object.

Moreover, for example, in light source module 1 according to the present embodiment, with regard to the first laser beam and the second laser beam combined, first direction D1 coincides with second direction D2, and second optical axis F1 coincides with fifth optical axis F2.

In this manner, the laser beams emitted from respective semiconductor laser modules 100, that is, the first laser beam and the second laser beam travel as laser beams each of which has the fast axis overlapping the same optical axis and which are parallel to each other and are spatially combined. Accordingly, the first laser beam and the second laser beam can be incident on the object (the end face portion of optical fiber 4) with higher coupling efficiency.

Furthermore, for example, in light source module 1 according to the present embodiment, first semiconductor laser module 101 includes: light-transmissive window 317 through which the first laser beam passes to an outside of first semiconductor laser module 101; first package 21 including plate-shaped bottom 130 and frame body 120 in a center of which opening 1201 (a first opening) is provided; and lid 110, First semiconductor laser element 11 is disposed in opening 1201. Lid 110 covers an upper portion of opening 1201. First semiconductor laser element 11 is hermetically sealed by light-transmissive window 317, first package 21, and lid 110.

In this manner, first semiconductor laser element 11 is protected from impurities such as organic substance from the outside of first package 21 while being supplied with electric power from the outside of first package 21. Accordingly, it is possible to inhibit the deterioration of first semiconductor laser element 11 caused by impurities such as organic substance attaching to the luminous point of first semiconductor laser element 11 while first semiconductor laser element 11 is in operation. It should be noted that the same applies to second semiconductor laser element 12.

Moreover, for example, in light source module 1 according to the present embodiment, opening 170 (a second opening) that spatially connects opening 1201 and the outside of first semiconductor laser module 101 is provided to frame body 120, and light-transmissive window 317 covers opening 170.

In this manner, first semiconductor laser element 11 is capable of emitting the first laser beam toward light-transmissive window 317 covering opening 170 (the second opening).

Furthermore, for example, in light source module 1 according to the present embodiment, frame body 120 includes anode electrode 132 and cathode electrode 135 that electrically connect opening 1201 and the outside of first semiconductor laser module 101. At least a portion of frame body 120 includes an insulator. Anode electrode 132, cathode electrode 135, and bottom 130 are electrically insulated from each other.

Providing anode electrode 132 and cathode electrode 135 in frame body 120 increases a degree of freedom for design of first semiconductor laser module 101.

Moreover, for example, in light source module 1 according to the present embodiment, frame body 120 includes: anode extraction electrode 131 that connects anode electrode 132 and the outside of first semiconductor laser module 101; and cathode extraction electrode 134 that connects cathode electrode 135 and the outside of first semiconductor laser module 101, Anode extraction electrode 131 and cathode extraction electrode 134 are disposed on a top surface of frame body 120.

In this manner, since anode extraction electrode 131 and cathode extraction electrode 134 are provided to the above place, the degree of freedom for design of first semiconductor laser module 101 increases.

Furthermore, for example, in light source module 1 according to the present embodiment, anode extraction electrode 131 and cathode extraction electrode 134 are disposed across opening 1201 from light-transmissive window 317.

In this manner, since anode extraction electrode 131 and cathode extraction electrode 134 are provided to the above place, the degree of freedom for design of first semiconductor laser module 101 increases.

Moreover, for example, in light source module 1 according to the present embodiment, first semiconductor laser module 101 and second semiconductor laser module 102 are disposed next to each other in the direction along third optical axis S1.

In this manner, a degree of freedom for design of arrangement of first semiconductor laser module 101 and second semiconductor laser module 102 increases.

Furthermore, for example, in light source module 1 according to the present embodiment, cathode extraction electrode 134 of first semiconductor laser module 101 and anode extraction electrode 1312 of second semiconductor laser module 102 are electrically connected by metal wire 193.

In this manner, it is possible to electrically connect adjacent semiconductor laser modules 100 in series easily in light source module 1.

Moreover, for example, in light source module 1 according to the present embodiment, at least a portion of first optical element 310 and at least a portion of third optical element 330 are each fixed by a bonding material comprising an inorganic material.

In this manner, impurities such as organic substance are not easily released around first semiconductor laser element 11. Accordingly, it is possible to inhibit the deterioration of first semiconductor laser element 11 caused by the attachment of impurities such as organic substance. The same applies to second semiconductor laser element 12.

Furthermore, for example, in light source module 1 according to the present embodiment, second optical element 320 is a lens that has a power axis and a non-power axis in a direction perpendicular to the power axis, and includes a convex cylindrical face along the power axis, the power axis being parallel to second optical axis F1. The fourth optical element is a lens that has a power axis and a non-power axis in a direction perpendicular to the power axis, and includes a convex cylindrical face along the power axis, the power axis being parallel to fifth optical axis F2.

In this manner, second optical element 320 and fourth optical element 340 (FAC lenses) are each capable of easily collimating a component of an incident laser beam in the fast axis direction.

Moreover, for example, light source module 1 according to the present embodiment includes fifth optical element 350 and sixth optical element 360. A component of first laser beam L15 along third optical axis S1, which has passed through fifth optical element 350, is collimated. A component of second laser beam L25 along sixth optical axis S2, which has passed through sixth optical element 360, is collimated. First laser beam L15 having passed through fifth optical element 350 and second laser beam L25 having passed through sixth optical element 360 are incident on an object (an end face portion of optical fiber 4).

In this manner, since fifth optical element 350 is located outside first package 21, it is easy to adjust the position of fifth optical element 350. Accordingly, the first laser beam is efficiently condensed to the predetermined place of the end face portion of optical fiber 4, which is the object. In addition, since the same applies to the second laser beam, the first laser beam and the second laser beam can be incident on the object (the end face portion of optical fiber 4) with higher coupling efficiency.

Furthermore, for example, in light source module 1 according to the present embodiment, a beam width of first laser beam L14 along second optical axis F1, which has passed through second optical element 320, is less than a beam width of first laser beam L15 along third optical axis S1, which has passed through fifth optical element 350. A beam width of second laser beam L24 along fifth optical axis F2, which has passed through fourth optical element 340, is less than a beam width of second laser beam L25 along sixth optical axis S2, which has passed through sixth optical element 360.

In this manner, since it is possible to decrease beam width BFw of first laser beam L15, which has passed through fifth optical element 350, along second optical axis F1, it is possible to arrange laser beams from other semiconductor laser modifies 100 in the direction along second optical axis F1, Accordingly, it is possible to downsize an optical component (e.g., twelfth optical element 380) on which first laser beam L15 having passed through fifth optical element 350 is incident. The same applies to the second laser beam. In other words, it is possible to downsize the optical system of light source nodule 1.

Moreover, for example, in light source module 1 according to the present embodiment, first optical element 310 includes a lens that has a power axis and a non-power axis in a direction perpendicular to the power axis, and includes a convex or concave cylindrical face along the power axis. The power axis is parallel to second optical axis F1. Third optical dement 330 includes a lens that has a power axis and a non-power axis in a direction perpendicular to the power axis, and incudes a convex or concave cylindrical face along the power axis. The power axis is parallel to fifth optical axis F2.

In this manner, first optical element 310 is capable of reducing a divergence angle along second optical axis F1. The same applies to third optical dement 330.

Furthermore, for example, light source module 1 according to the present embodiment includes seventh optical dement 370 on which first laser beam L15 having passed through fifth optical element 350 and second laser beam L25 having passed through sixth optical element 360 are incident.

In this manner, it is possible to control the first laser beam and the second laser beam. Accordingly, it becomes easy to combine the first laser beam and the second laser beam, and the first laser beam and the second laser beam are incident on the object (the end face portion of optical fiber 4) with higher coupling efficiency.

Moreover, for example, in light source module 1 according to the present embodiment, fifth optical element 350 is a lens that has a power axis and a non-power axis in a direction perpendicular to the power axis, and includes a convex cylindrical face along the power axis. The power axis is parallel to third optical axis S1. Sixth optical element 360 is a lens that has a power axis and a non-power axis in a direction perpendicular to the power axis, and incudes a convex cylindrical face along the power axis. The power axis is parallel to sixth optical axis S2.

In this manner, fifth optical element 350 and sixth optical element 360 (SAC lenses) are each capable of easily collimating a component of an incident laser beam in the slow axis direction.

Furthermore, in light source module 1 according to the present embodiment, second optical element 320 is disposed between first optical element 310 and fifth optical element 350, and fourth optical element 340 is disposed between third optical element 330 and sixth optical element 360.

In this manner, since it is possible to further decrease the beam width of each of the first laser beam and the second laser beam along the fast axis, it is possible to downsize the optical system of light source module 1. Accordingly, it is possible to achieve compact light source module 1.

Moreover, for example, in light source module 1 according to the present embodiment, seventh optical element 370 includes reflecting mirrors.

In this manner, it is possible to reflect the laser beams collimated by the FAC lenses and the SAC lenses, and deflect the directions of the laser beams by, for example, 90°.

Furthermore, for example, in light source module 1 according to the present embodiment, after exiting seventh optical element 370, the first laser beam and second laser beam become mutually parallel laser beams, second optical axis F1 and fifth optical axis F2 overlap with each other, and third optical axis S1 and sixth optical axis S2 do not overlap with each other.

Since the first laser beam and the second laser beam become parallel beams, and second optical axis F1 overlaps fifth optical axis F2, the first laser beam and the second laser beam can be incident on the object (the end face portion of optical fiber 4) with higher coupling efficiency.

Moreover, for example, light source module 1 according to the present embodiment includes twelfth optical element 380 on which first laser beam L17 and second laser beam L27 having passed through seventh optical element 370 are incident. The first laser beam and the second laser beam having passed through twelfth optical element 380 are incident on the object (the end face portion of optical fiber 4).

Providing such twelfth optical element 380 allows the first laser beam and the second laser beam to be incident on the object (the end face portion of optical fiber 4) with higher coupling efficiency.

Furthermore, for example, in light source module 1 according to the present embodiment, the object is the end face portion of optical fiber 4.

In this manner, since it is possible to downsize the object, it is possible to achieve compact light source module 1.

Moreover, for example, in light source module 1 according to the present embodiment, first semiconductor laser element 12 is a nitride-based semiconductor laser element, and second semiconductor laser element 12 is a nitride-based semiconductor laser element.

Generally speaking, a nitride semiconductor laser element easily deteriorates due to the attachment of impurities such as organic substance. However; the above-described configuration allows light source module 1 including nitride semiconductor laser elements as first semiconductor laser element 11 and second semiconductor laser element 12 to inhibit the deterioration of first semiconductor laser element 11 and second semiconductor laser element 11.

### Embodiment 2

Next, Embodiment 2 will be described. The following mainly describes differences from Embodiment 1, and omits or simplifies description of common points.

### [Configuration]

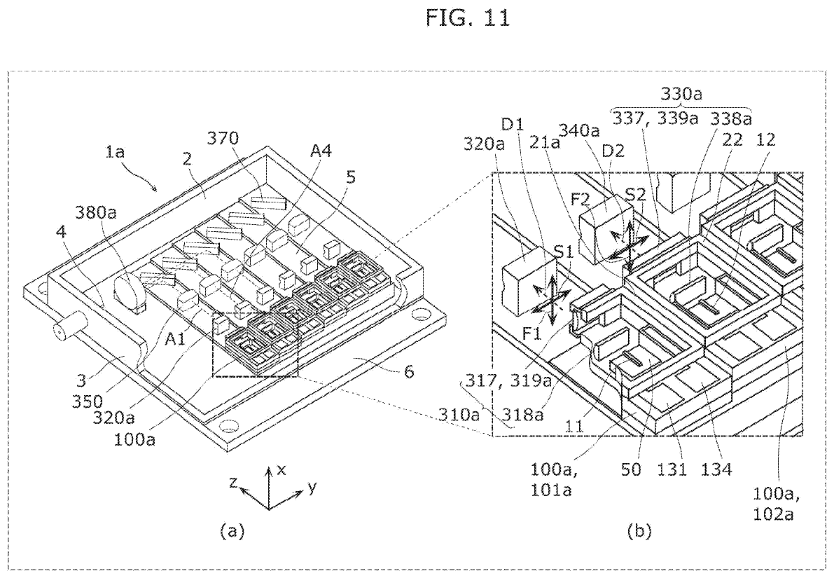

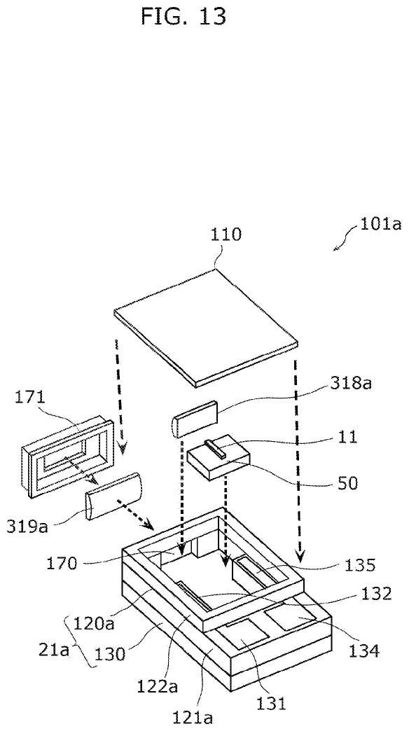

First, configurations of a light source module and a semiconductor laser module according to Embodiment 2 will be described with reference to FIG. 11 and FIG. 13.

FIG. 11 is a perspective view of a configuration of light source module 1a according to Embodiment 2, More specifically, (a) in FIG. 11 is a perspective view of an entire configuration of light source module 1a. (b) in FIG. 11 is an enlarged perspective view of semiconductor laser module 100a. In FIG. 11, a portion of side wall 3 is not shown for purposes of illustration, FIG. 13 is an exploded perspective view of a configuration of first semiconductor laser module 101a included in light source module 1a.

Light source module 1a has the same configuration as light source module 1 according to Embodiment 1 except mainly for the following two points, Specifically, the two points are a configuration of semiconductor laser module 100a that is mounted on light source module 1a, and a configuration of a FAC lens that collimates a component of a laser beam, which is emitted from semiconductor laser module 100a, along a fast axis.

In the present embodiment, as with Embodiment 1, six semiconductor laser modules 100a are provided. For purpose of identification, these semiconductor laser modules may be referred to as first to sixth semiconductor laser modules, and may further be referred to as first semiconductor laser module 101a and second semiconductor laser module 102a. It should be noted that, among semiconductor laser modules 100a, the second to sixth semiconductor laser modules have the same configuration as first semiconductor laser module 101a, The following description is based on first semiconductor laser module 101a.

Specifically, first optical element 310a of first semiconductor laser module 101a includes eighth optical element 318a and ninth optical element 319a. Third optical element 330a of second semiconductor laser module 102a includes tenth optical element 338a and eleventh optical element 339a. In the present embodiment, ninth optical element 319a and light-transmissive window 317 of first semiconductor laser module 101a are integrally formed. In other words, ninth optical element 319a serves as a light-transmissive window through which a first laser beam passes to the outside of first semiconductor laser module 101a. Moreover, eleventh optical element 339a and light-transmissive window 337 of second semiconductor laser module 102a are integrally formed. In other words, eleventh optical element 339a serves as a light-transmissive window through which a second laser beam passes to the outside of second semiconductor laser module 102a. Furthermore, a laser beam emitted from each of first semiconductor laser module 101a and second semiconductor laser module 102a is emission light having a divergence angle in a fast axis direction that is a negative value, that is, a convergent laser beam.

With respect to the fast axis direction, second optical element 320a and fourth optical element 340a each collimate the laser beam converging in the fast axis direction.

The following provides further details.

Although first package 21a of semiconductor laser module 100a includes bottom 130 and frame body 120a, frame body 120a is different from Embodiment 1. Frame body 120a includes first frame portion 121a and second frame portion 122a. Frame portion 121a comprises an insulating material, and includes an opening that spatially connects the outside and inside of first semiconductor laser module 101a. This opening includes a notch in first direction D1. A metal film included in each of anode electrode 132 and anode extraction electrode 131, and a metal film included in each of cathode electrode 135 and cathode extraction electrode 134 are formed on the top surface of first frame portion 121a. Frame portion 122a is attached to a metal film side of first frame portion 121a so that anode electrode 132 and cathode electrode 135 are disposed inside second frame portion 122a, and anode extraction electrode 131 and cathode extraction electrode 134 are disposed outside second frame portion 122a. This structure allows first package 21a to eliminate the need for an electrode that connects different frame portions (e.g., second frame portion 122 and third frame portion 123 in Embodiment 1), such as a via electrode. Moreover, as a result of being sandwiched between bottom 130 and second frame portion 122a, the notch of first frame portion 121a forms opening 170 in the side surface. The above-described configuration makes it possible to configure first package 21a more easily than first package 21.

Eighth optical element 318a and ninth optical element 319a, which are included in first optical element 310a that is an FA lens, are each a lens including a convex cylindrical face. As an example, eighth optical element 318a and ninth optical element 319a are each a plano-convex cylindrical lens that comprises inorganic glass, includes a flat face on one side and a convex face on the opposite side, and has an incident face and an exit face on each of which an antireflection coating film is formed. At this time, eighth optical element 318a and ninth optical element 319a are disposed inside first semiconductor laser module 101a so that the convex face of eighth optical element 318a is on a laser beam emission side, and the convex face of ninth optical element 319a is on a laser beam incident side. Eighth optical element 318a and ninth optical element 319a are disposed so that a power axis of eighth optical element 318a and ninth optical element 319a is parallel to second optical axis F1 of the first laser beam, and a non-power axis of eighth optical element 318a and ninth optical element 319a is parallel to third optical axis S1. Eighth and ninth optical elements 318a and 319a each include a projecting curved face along the power axis, that is, a convex cylindrical face, Third optical element 330a similarly includes tenth optical element 338a and eleventh optical element 339a each of which is a lens including a convex cylindrical face and is disposed in second semiconductor laser module 102a.

Ninth optical element 319a and eleventh optical element 339 are integrally formed with the light-transmissive windows of first semiconductor laser module 101a and second semiconductor laser module 102a, respectively. Moreover, after being attached to frame 171 using low-melting-point glass etc., ninth optical element 319a covers opening 170 of first package 21a of first semiconductor laser module 101a. Furthermore, lid 110 is attached to cover an opening of second frame portion 122a of first package 21a. At this time, frame 171 and lid 119 may comprise an opaque material such as a ceramic or a metal. Accordingly, it is possible to hermetically seal first semiconductor laser element 11 more easily with ninth optical element 319a, frame 171, and lid 110. Second optical element 320a and fourth optical element 340a, which are FAC lenses, are each a lens including a concave cylindrical face. As an example, second optical element 320a and fourth optical element 340a are each a planoconcave cylindrical lens that comprises inorganic glass, includes a flat face on one side and a concave face on the opposite side, and has an incident face and an exit face on each of which an antireflection coating film is formed. Second optical element 320a is disposed so that a power axis is parallel to second optical axis F1 of the first laser beam, and a non-power axis is parallel to third optical axis S1. Second and fourth optical elements 320a and 340a each include a recessed curved face along the power axis, that is, a concave cylindrical face. Additionally, as with Embodiment 1, twelfth optical element 380a is a condenser lens.

### [Behavior of Laser Beam]

Next, laser beams emitted from semiconductor laser modules 100a will be described. Although the following description is based on first semiconductor laser module 101a as an example, the same behavior of laser beams applies to other semiconductor laser modules 100a.

In the present embodiment, a laser beam having passed through an FA lens (e.g., first optical element 310a) has divergence angle θfd in a fast axis direction that is a negative value, that is, is a convergent laser beam. Accordingly, the laser beam in the fast axis direction converges at convergence angle θfc represented by θft=−θcd.

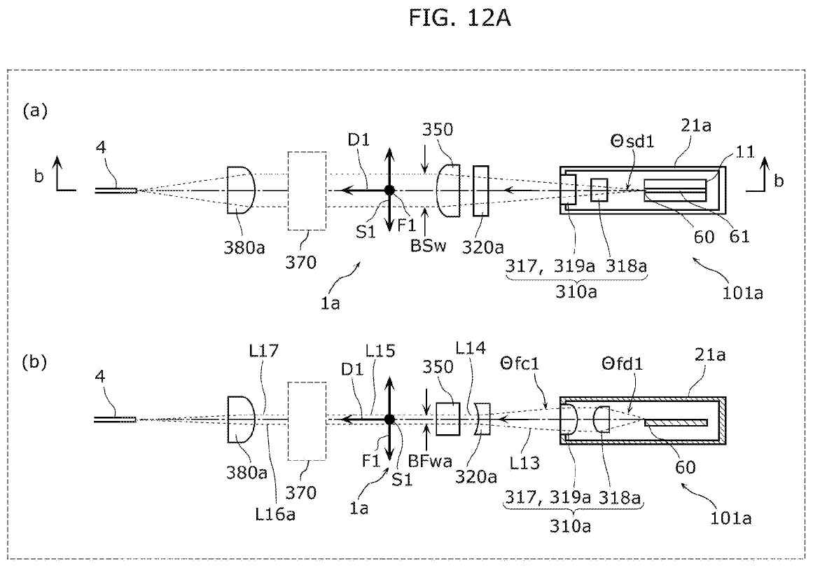

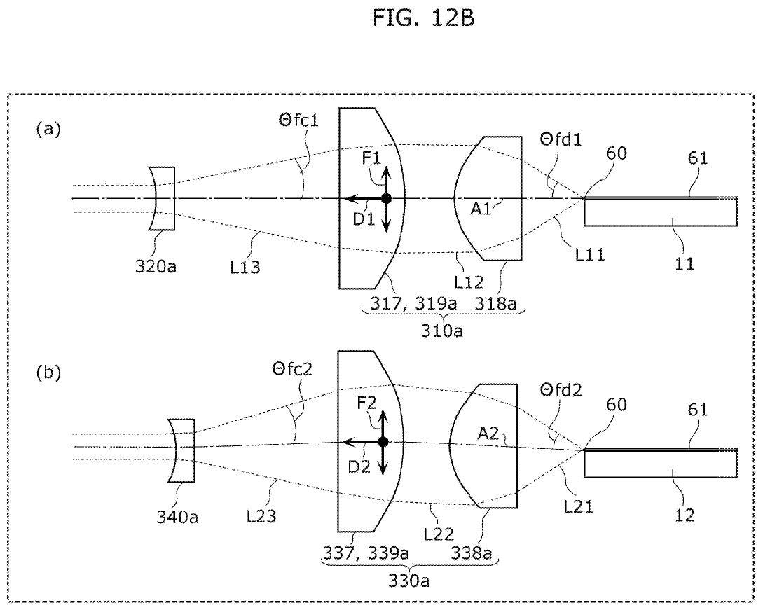

FIG. 12A is a schematic diagram illustrating an optical system of first semiconductor laser module 101a. Specifically, (a) in FIG. 12A is a plan view, and (b) in FIG. 12A is a cross-sectional view of a cross section along line b-b shown in (a) in FIG. 12A.

FIG. 12B is a schematic diagram illustrating convergence angles according to Embodiment 2, As with a divergence angle, a convergence angle of the first laser beam is the angle between optical axis A1 and a broken line where a light intensity is a value of 1/(e²) of a peak value. (a) in FIG. 12B shows first semiconductor laser element 11, and (b) in FIG. 12B shows second semiconductor laser element 12.

First laser beam L11 prior to reaching first optical element 310a is emitted from a luminous point of first semiconductor laser element 11 as a laser beam that has first divergence angle θfd1 in a direction along second optical axis F1, and second divergence angle θsd1 in a direction along third optical axis S1. At this time, first divergence angle θfd1 and second divergence angle θsd1 have the same values as in Embodiment 1, Third divergence angle θfd12 decreases to a negative value in the direction along second optical axis F1 by first laser beam L11 passing through first optical element 310a, and first laser beam L11 becomes a laser beam that converges at first convergence angle θfc1 represented by θfc1=−θfd12>0, and travels. On the other hand, since first optical element 310a has no power in a direction along third optical axis S1 of first laser beam L11, first laser beam L11 travels while spreading at second divergence angle θsd1 that is the same as prior to being incident.

At this time, first optical element 310a includes two lenses, eighth optical element 318a and ninth optical element 319a, each of which has power. For this reason, it is easy to significantly reduce third divergence angle θfd12 using the two lenses having less power. At this time, in order to make lens design easy, the divergence angle of first laser beam L11 in the direction along second optical axis F1 is set to be such that eighth optical element 318a and ninth optical element 319a collimate and converge first laser beam L11, respectively.

Next, first laser beam L13 is collimated by passing through second optical element 320a, For this reason, it is possible to cause first laser beam L14 having passed through second optical element 320a to be a laser beam having narrow beam width BFwa in the fast axis direction. Specifically, for example, the first laser beam according to the present embodiment is a laser beam having a narrow beam width in the fast axis direction, compared to Embodiment 1.

Moreover, a divergence angle and a convergence angle are designed to satisfy θfd1>θfc1>0 in the present embodiment. In other words, a divergence angle of the first laser beam emitted from first semiconductor laser element 11 and a convergence angle (divergence angle) of a laser beam having passed through first optical element 310a are designed so that an absolute value of the divergence angle is less than an absolute value of the convergence angle.

In this way, even when the positions of second optical element 320a and fifth optical element 350 are adjusted, a decrease in absolute value of first convergence angle θfc1 makes it difficult for a condensing position of the first laser beam to vary sensitively. To put it another way, it is possible to reduce the sensitivity to the adjustment of the positions of second optical element 320a and fifth optical element 350. In short, the positions of second optical element 320a and fifth optical element 350 are easily adjusted.

As stated above, second optical element 320a is a lens including a concave cylindrical face. For this reason, after the first laser beam exiting ninth optical element 319a is incident on second optical element 320a in a state in which the first laser beam converges in the direction along second optical axis F1 it is possible to collimate a component of the first laser beam, which has passed through second optical element 320a, in the direction along second optical axis F1. As a result, if the first laser exiting ninth optical element 319a is a laser beam having components that converge along second optical axis F1, it is possible to use a lens having a great focal length as first optical element 310a (eighth optical element 318a and ninth optical element 319a) or reduce a distance between second optical element 320a and first package 21a. Accordingly, it is possible to achieve compact light source module 1.

In addition, the first laser beam is incident on seventh optical element 370.

### [Method of Manufacturing Semiconductor Laser Module and Light Source Module]

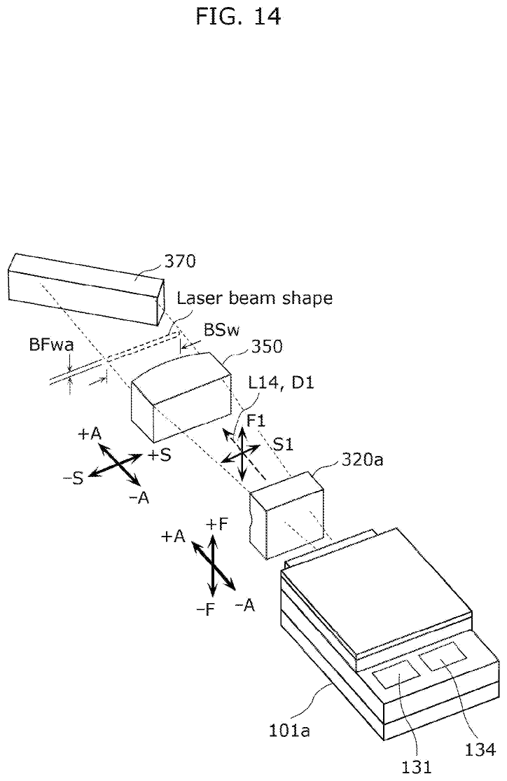

A method of manufacturing semiconductor laser module 100a and light source module 1a will be described with reference to FIG. 11, FIG. 13, and FIG. 14, FIG. 14 is a perspective view for illustrating a method of adjusting positions of second optical element 320a and fifth optical element 350. Although the following description is based on first semiconductor laser module 101a as an example, other semiconductor laser modules 100a are manufactured by the same method. Moreover, a description overlapping the description of the method of manufacturing first semiconductor laser module 101 according to Embodiment 1 will be omitted. Furthermore, the same applies to a description of metal wires in first semiconductor laser module 101a.

First, submount 50 on which first semiconductor laser element 11 is mounted is fixed to a predetermined position on a semiconductor laser element mounting surface in an opening of first package 21a. Next, eighth optical element 318a is fixed in the same manner. Then, ninth optical element 319a is fixed to frame 17 with low-melting-point inorganic glass etc., frame 17 comprising a metal or a ceramic and being in a frame-like shape. After that, frame 171 to which ninth optical element 319a is attached is fixed to opening 170 of first package 21a. Finally, first semiconductor laser module 101a is manufactured by connecting first semiconductor laser element 11 and wirings of first package 21a with metal wires not shown and then fixing lid 110 to second frame portion 122a for hermetic sealing. At this time, as with Embodiment 1, frame 171 and lid 110 are sealed with preliminary bonding films and bonding materials formed on first package 21a.

As shown in FIG. 11, first semiconductor laser module 101a is attached to light source module 1a, and supplying electric power to the semiconductor laser element is made possible by electrically connecting anode extraction electrode 131 and cathode extraction electrode 134 with metal wires not shown. As shown in FIG. 14, as with Embodiment 1, second optical element 320a and fifth optical element 350 are fixed by positioning. At this time, although second optical element 320a is the lens including the concave cylindrical face, a positioning method is the same as Embodiment 1.

### Superiority Over Embodiment 1

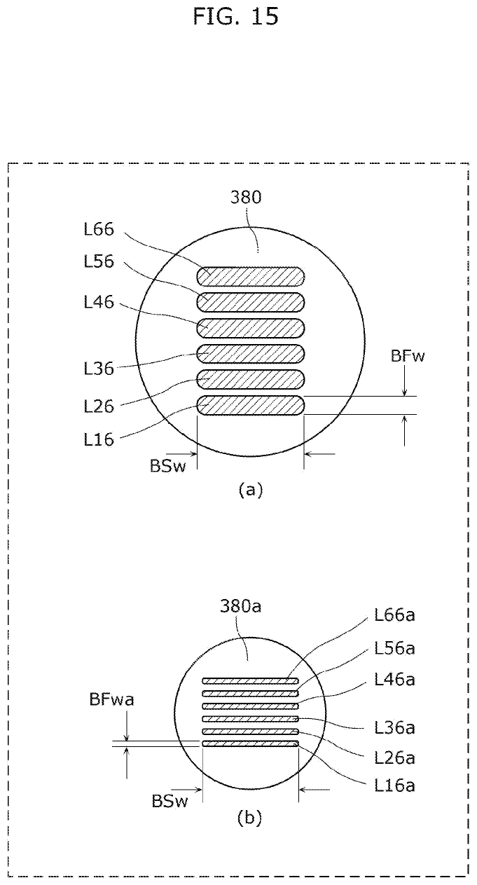

Here, superiority of light source module 1a according to the present embodiment will be described with reference to FIG. 7, FIG. 14, and FIG. 15.

FIG. 15 is a diagram illustrating incident light amount distributions of laser beams prior to reaching twelfth optical elements 380 and 380a after exiting seventh optical elements 370 and 370a according to Embodiments 1 and 2. More specifically, (a) in FIG. 15 is a diagram illustrating an incident light amount distribution in Embodiment 1 as shown by the optical system in FIG. 7, and (b) in FIG. 15 is a diagram illustrating an incident light amount distribution in Embodiment 2 as shown in FIG. 14.

Here, as shown in (a) in FIG. 15, of laser beams incident on twelfth optical element 380 according to Embodiment 1, laser beams emitted from the respective first to sixth semiconductor laser modules are defined as first to sixth laser beams L16, L26, L36, L46, L56, and L66, Likewise, as shown in (b) in FIG. 15, of laser beams incident on twelfth optical element 380a according to Embodiment 2, laser beams emitted from the respective first to sixth semiconductor laser modules are defined as first to sixth laser beams L16a, L26a, L36a, L46a, L56a, and L66a. At this time, the optical systems relating to a direction of a laser beam along the slow axis have the same design.

As stated above, the first laser beam emitted from first semiconductor laser module 101a according to the present embodiment becomes a laser beam having beam width BFwa in the fast axis direction narrower than beam width BFw of Embodiment 1, and the laser beam travels to twelfth optical element 380a. As a result, the same applies to the laser beams emitted from respective semiconductor laser modules 100a.

For this reason, as shown in (b) in FIG. 15, by reducing, for example, the height of the steps of multistep base 5 on which semiconductor laser modules 100a are disposed, it is possible to combine first to sixth laser beams L16a, L26a, L36a, L46a, L56a, and L66a more highly densely in the fast axis direction. Accordingly, as shown by a comparison between (a) and (b) in FIG. 15, it is possible to use small twelfth optical element 380a in the present embodiment, compared to Embodiment 1. Additionally, even if such twelfth optical element 380a is used, it is possible to couple laser beams efficiently. In consequence, light source module 1a that is small especially in the height direction (the direction along second optical axis F1) is achieved.

### [Advantageous Effects Etc.]

As stated above, in light source module 1a according to the present embodiment, at least a portion of first optical element 310a (here ninth optical element 319a) and light-transmissive window are integrally formed.

In this manner, it is possible to decrease the number of components constituting first semiconductor laser module 101b.

Moreover, for example, in light source module 1a according to the present embodiment, a component of the first laser beam, which has passed through first optical element 310a, along second optical axis F1 converges toward second optical element 320a. A component of the second laser beam, which has passed through third optical element 330a, along fifth optical axis F2 converges toward fourth optical element 340a.

In this manner, even when the positions of second optical element 320a and fifth optical element 350 are adjusted, the convergence of the first laser beam having passed through first optical element 310a makes it difficult for a condensing position of the first laser beam to vary sensitively. In short, the positions of second optical element 320a and fifth optical element 350 are easily adjusted. The same applies to the second laser beam. Accordingly, the laser beams emitted from respective semiconductor laser modules 100a can be incident on an object (the end face portion of optical fiber 4) with higher coupling efficiency.

Furthermore, for example, in light source module 1a according to the present embodiment, in the first laser beam passing through first optical element 310a, third divergence angle θfd12, which is a divergence angle in the direction along second optical axis F1, satisfies θfc1=−θfd12>0, where first convergence angle is θfc1. In the second laser beam having passed through third optical element 330a, sixth divergence angle θfd22, which is a divergence angle in the direction along fifth optical axis F2, satisfies θfc2=−θfd22>0, where second convergence angle is θfc2. First divergence angle θfd1, first convergence angle θfc1, fourth divergence angle θfd2, and second convergence angle θfc2 satisfy θfd1>θfc1>0 and θfd2>θfc2>0.

In this manner, even when the positions of second optical element 320a and fifth optical element 350 are adjusted, a sufficient decrease in first convergence angle θfc1 makes it further difficult for a condensing position of the first laser beam to vary sensitively. In other words, the positions of second optical element 320a and fifth optical element 350 are more easily adjusted. The same applies to the second laser beam. Accordingly, the laser beams emitted from respective semiconductor laser modules 100a can be incident on an object (the end face portion of optical fiber 4) with higher coupling efficiency.

Moreover, for example, in light source module 1a according to the present embodiment, second optical element 320a is a lens that has a power axis and a non-power axis in a direction perpendicular to the power axis, and includes a concave cylindrical face along the power axis. The power axis is parallel to second optical axis F1. Fourth optical element 340a is a lens that has a power axis and a non-power axis in a direction perpendicular to the power axis, and incudes a concave cylindrical face along the power axis. The power axis is parallel to fifth optical axis F2.

In this manner, after the first laser beam having exited first optical element 310a (here ninth optical element 319a) is incident on second optical element 320a in a state in which the first laser beam converges in the direction along second optical axis F1, it is possible to collimate a component of the first laser beam, which has passed through second optical element 320a, in the direction along second optical axis F1. The same applies to the second laser beam. Accordingly, it is possible to achieve compact light source module 1a.

Furthermore, for example, in light source module 1a according to the present embodiment, first optical element 310a includes eighth optical element 318a and ninth optical element 319a. Third optical element 330a includes tenth optical element 338a and eleventh optical element 339a.

In this manner, for example, combining eighth optical element 318a and ninth optical element 319a each of which is a lens having a small curvature produces the same advantageous effect as a case in which one convex lens having a large curvature is used.

Moreover, for example, in light source module 1a according to the present embodiment, eighth optical element 318a is a lens that has a power axis and a non-power axis in a direction perpendicular to the power axis, and includes a convex cylindrical face along the power axis. The power axis is parallel to second optical axis F1. Ninth optical element 319a is a lens that has a power axis and a non-power axis in a direction perpendicular to the power axis, and incudes a convex cylindrical face along the power axis. The power axis is parallel to second optical axis F1. Tenth optical element 338a is a lens that has a power axis and a non-power axis in a direction perpendicular to the power axis, and incudes a convex cylindrical face along the power axis. The power axis is parallel to third optical axis S1, Eleventh optical element 339a is a lens that has a power axis and a non-power axis in a direction perpendicular to the power axis, and incudes a convex cylindrical face along the power axis. The power axis is parallel to third optical axis S1.

In this manner, first optical element 310a includes two lenses, eighth optical element 318a and ninth optical element 319a, each of which has power. For this reason, it is easy to significantly reduce third divergence angle θfd12 using the two lenses having less power. The same applies to third optical element 330a.

Hereinafter, Variations 1 to 10 of Embodiment 2 will be described. The following mainly describes differences from Embodiment 2, and omits or simplifies description of common points.

### Variation 1 of Embodiment 2

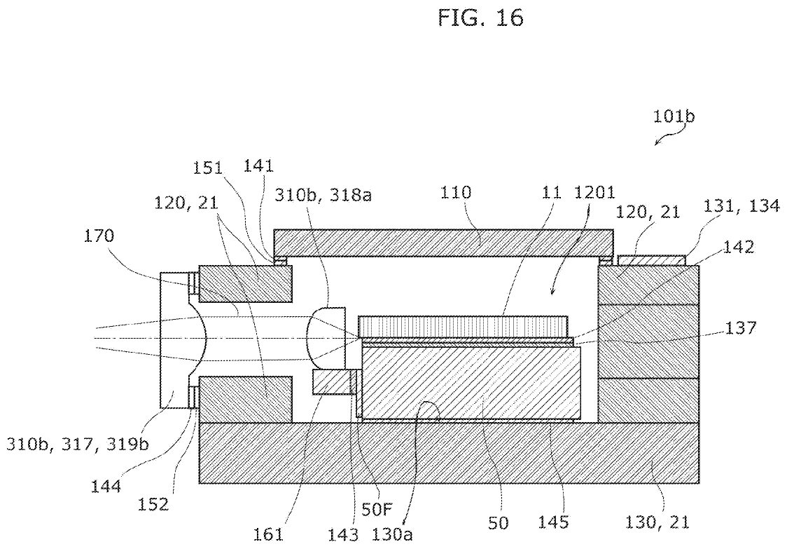

FIG. 16 is a cross-sectional view of a configuration of first semiconductor laser module 101b included in a light source module according to Variation 1 of Embodiment 2.

The light source module according to Variation 1 of Embodiment 2 has the same configuration as light source module 1a according to Embodiment 2 except mainly for the following one point. Specifically, the one point is a point that ninth optical element 319b that is part of first optical element 310b is integral with frame 171 described in Embodiment 2.

In this manner, it is possible to decrease the number of components constituting first semiconductor laser module 101b.

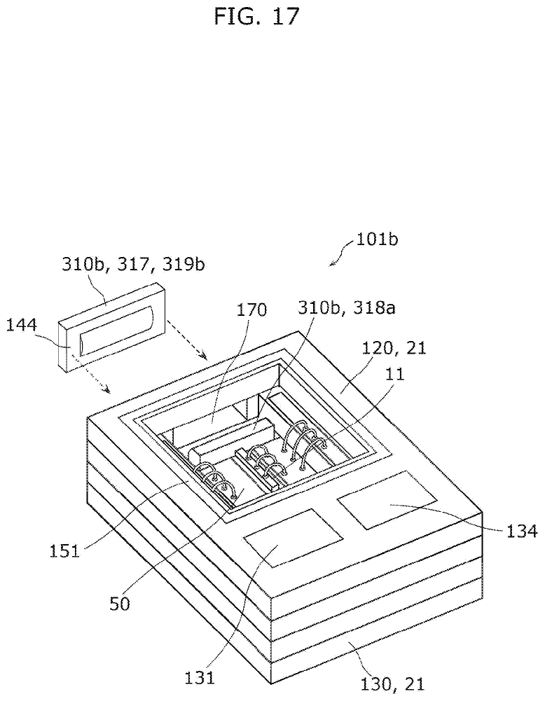

FIG. 17 is a schematic diagram illustrating the configuration of first semiconductor laser module 101b and a method of manufacturing the same according to Variation 1 of Embodiment 2.

The present variation describes a case in which an equivalent of first package 21 according to Embodiment 1 is used. Although ninth optical element 319b is a plano-convex cylindrical lens, a convex portion is formed only in the center of ninth optical element 319b, and a flat region is formed in a peripheral portion of ninth optical element 319b. A base metal film not shown and fourth bonding material 144 that is, for example, AuSn solder are formed in the peripheral portion of ninth optical element 319b. Then, ninth optical element 319b can be easily fixed to opening 170 of frame body 120 by being pressed and heated.

### Variation 2 of Embodiment 2

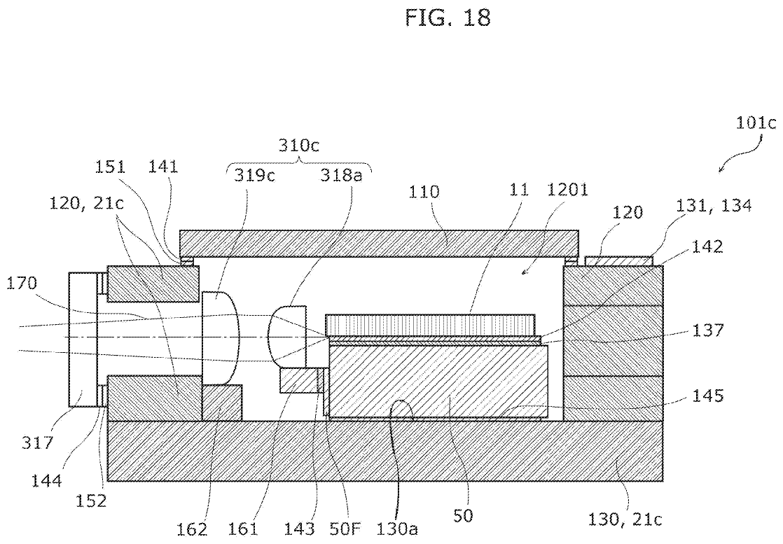

FIG. 18 is a cross-sectional view of a configuration of first semiconductor laser module 101c included in a light source module according to Variation 2 of Embodiment 2.

The light source module according to Variation 2 of Embodiment 2 has the same configuration as light source module 1a according to Embodiment 2 except mainly for the following two points. Specifically, the two points are a point that ninth optical element 319c that is part of first optical element 310c is hermetically sealed in first package 21c, and a point that light-transmissive window 317 is provided to seal opening 170.

Ninth optical element 319c is provided above second supporting component 162, As with ninth optical element 319a according to Embodiment 2, ninth optical element 319c is a lens including a convex cylindrical face, and is disposed so that a power axis is parallel to second optical axis F1. Second supporting component 162 is provided above bottom 130, and is used to adjust the position of ninth optical element 319c relative to a first laser beam. Light-transmissive window 317 has the same configuration as light-transmissive window 317 according to Embodiment 1.

In this manner, a degree of freedom for design of an optical system included in first semiconductor laser module 101c increases,

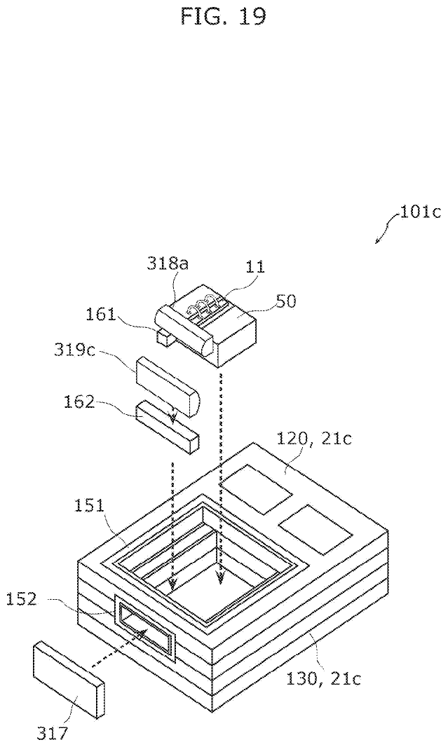

FIG. 19 is a schematic diagram illustrating a method of manufacturing first semiconductor laser module 101c according to Variation 2 of Embodiment 2.

In the present variation, after eight optical element 318a is fixed, ninth optical element 319c is fixed using second supporting component 162 so that ninth optical element 319c has a predetermined height and distance relative to first semiconductor laser element 11, Then, light-transmissive window 317 is fixed to opening 170 of frame body 120.

### Variation 3 of Embodiment 2

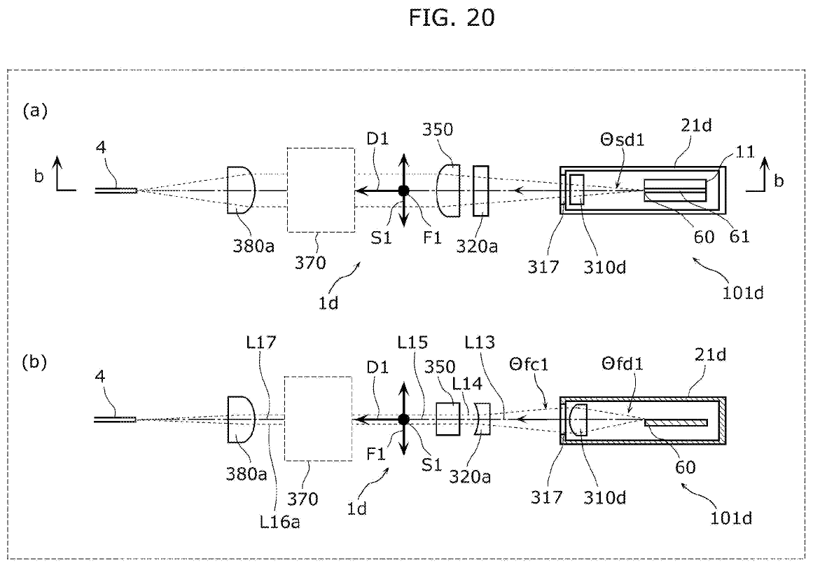

FIG. 20 is a schematic diagram illustrating an optical system of first semiconductor laser module 101d included in light source module 1d according to Variation 3 of Embodiment 2. Specifically, (a) in FIG. 20 is a plan view, and (b) in FIG. 20 is a cross-sectional view of a cross section along line b-b shown in (a) in FIG. 20.

Light source module 1d according to Variation 3 of Embodiment 2 has the same configuration as the light source module according to Variation 2 of Embodiment 2 except mainly for the following one point. Specifically, the one point is a point that first optical element 310d obtained by integrating eighth optical element 318a and ninth optical element 319c according to Variation 2 of Embodiment 2 is provided.

In this manner, it is possible to decrease the number of components constituting first semiconductor laser module 101d.

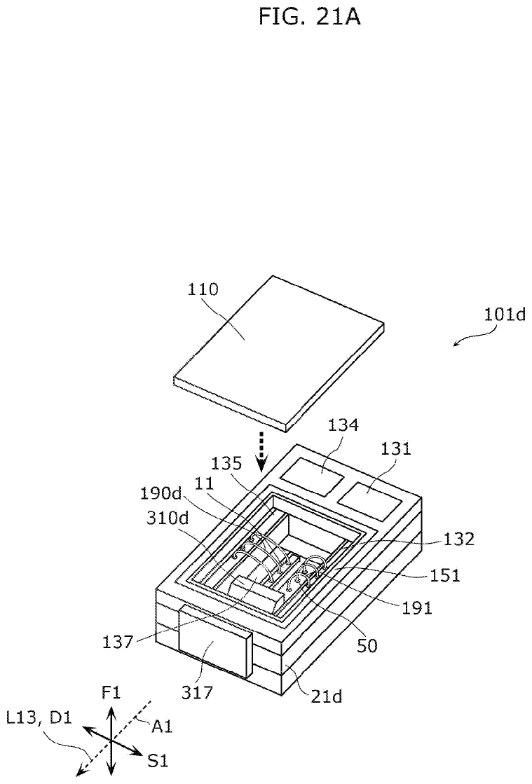

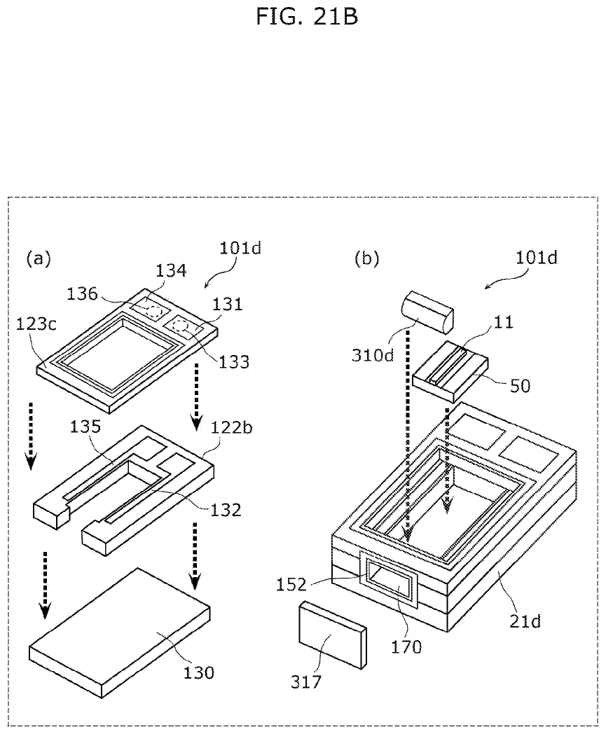

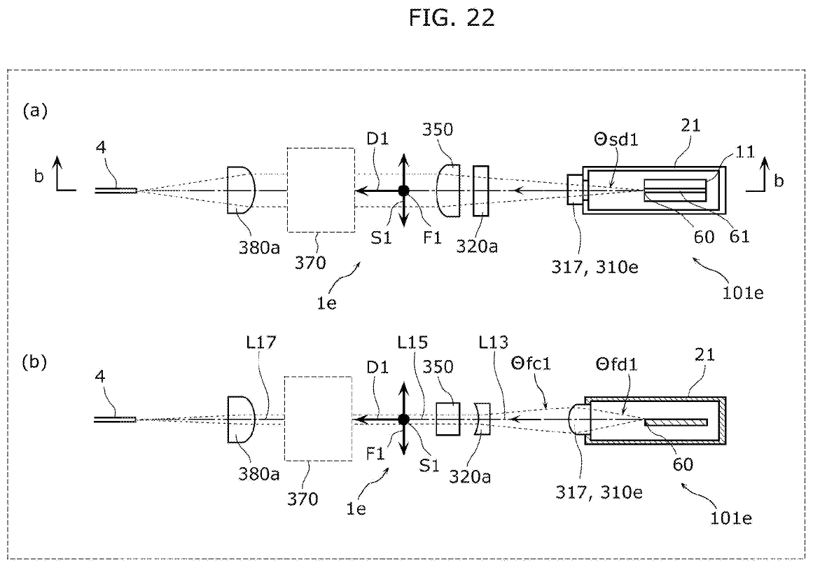

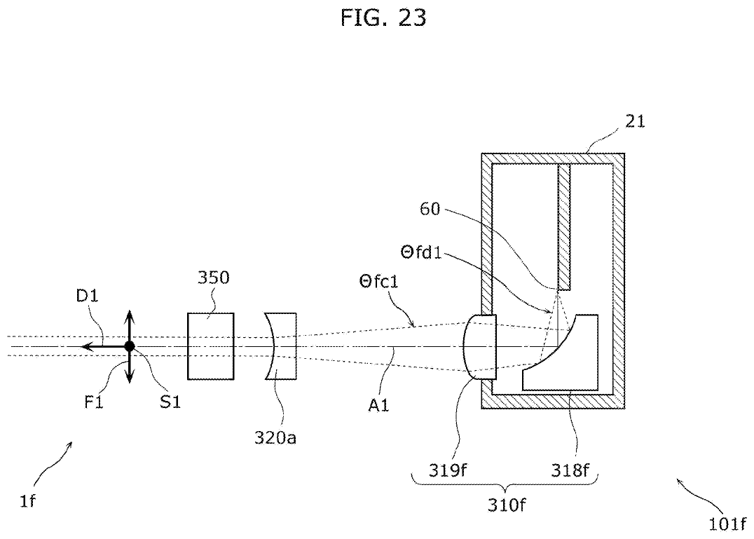

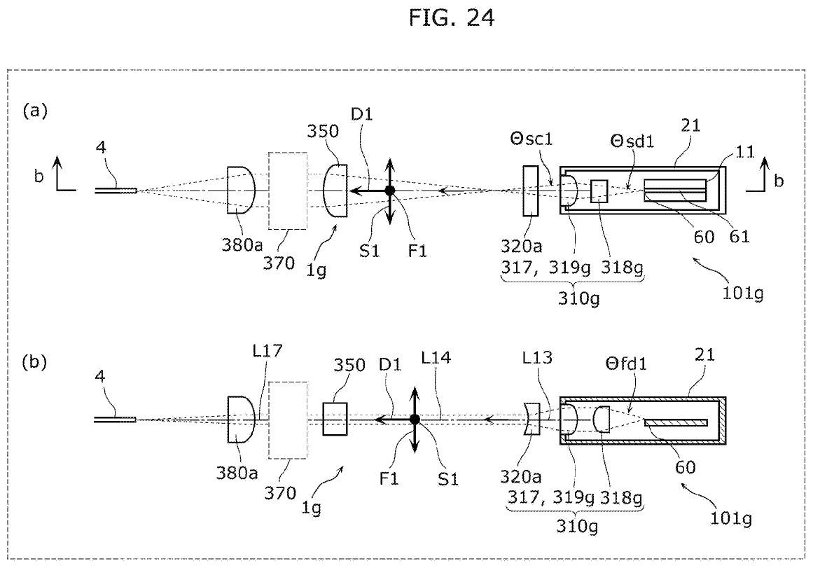

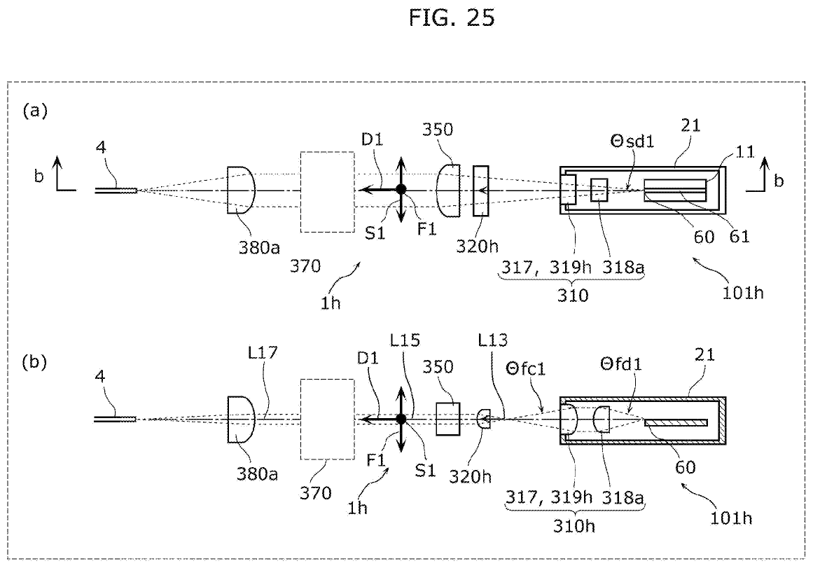

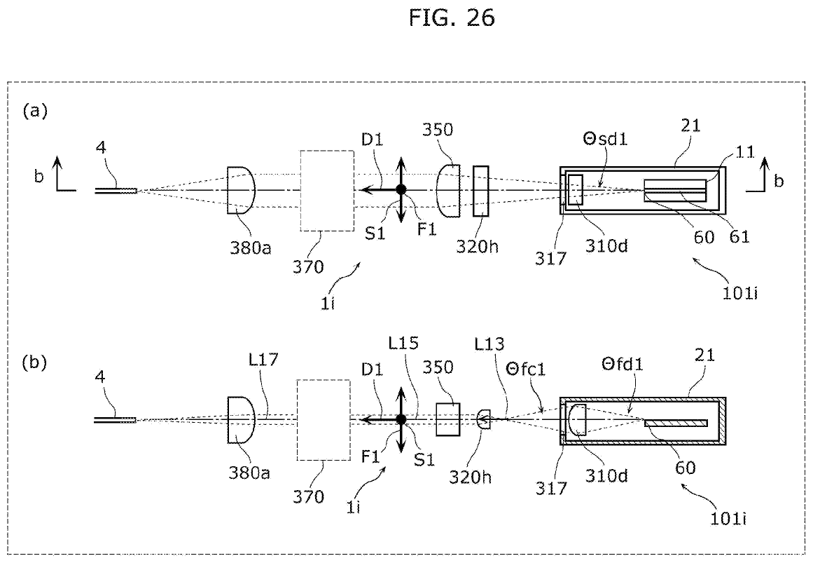

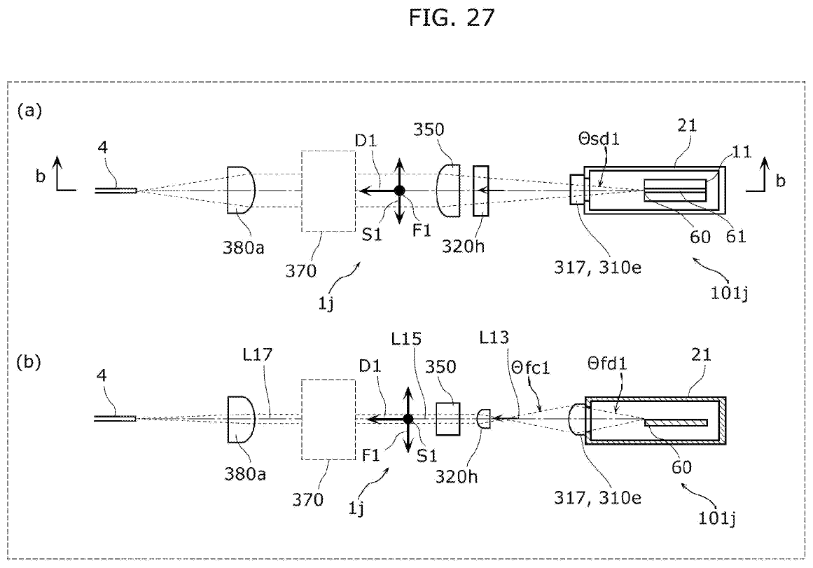

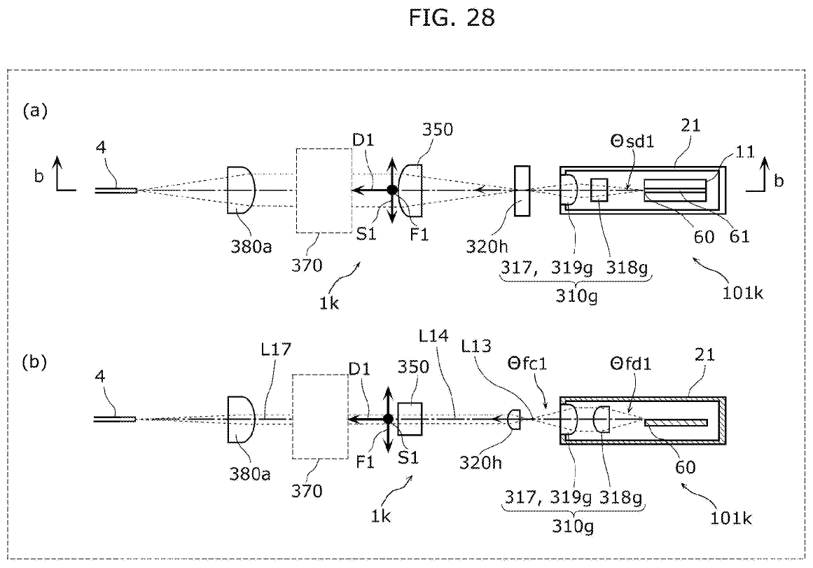

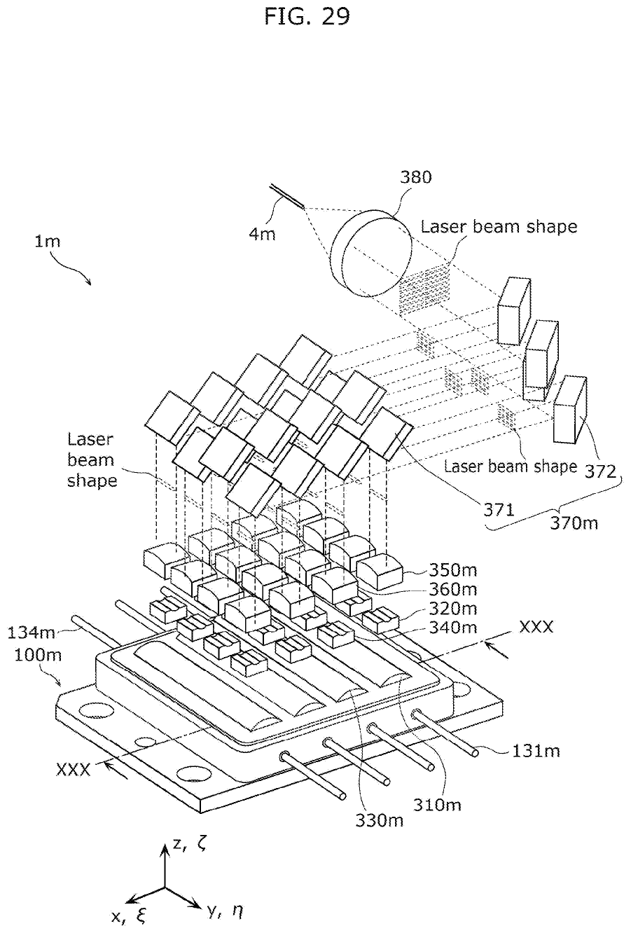

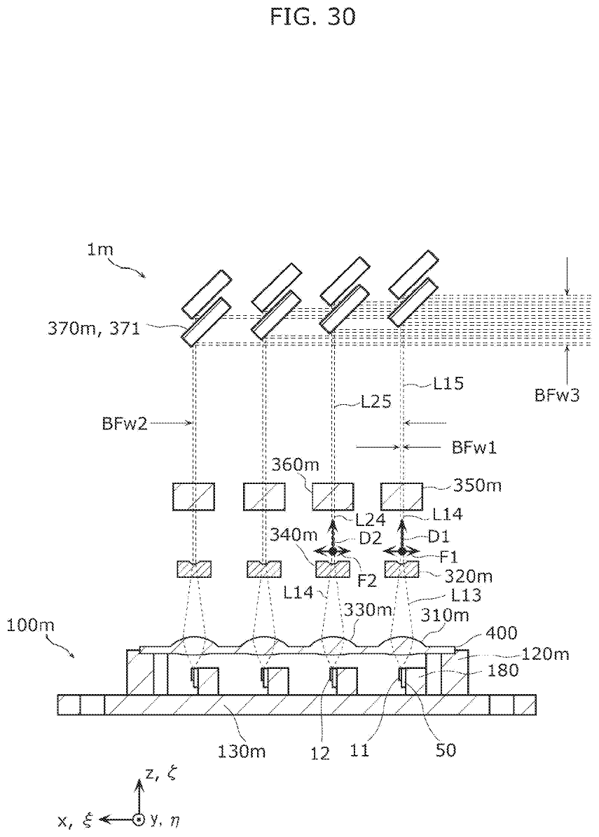

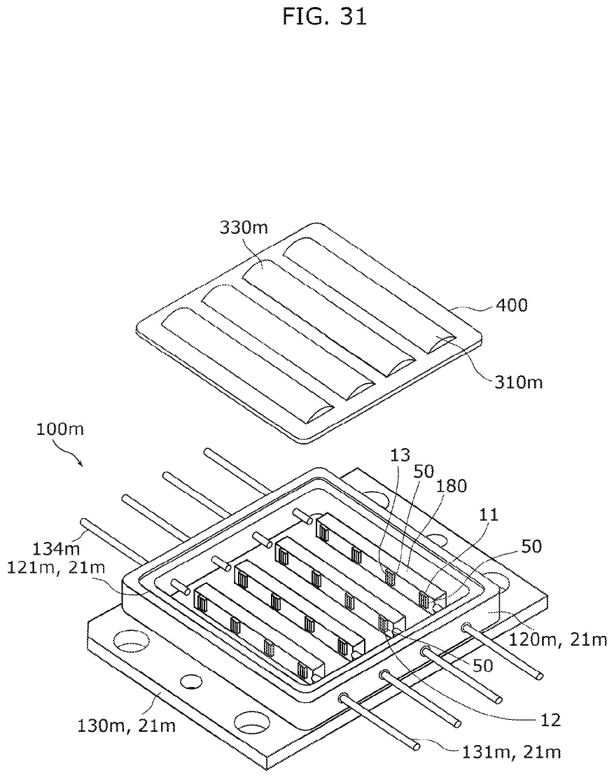

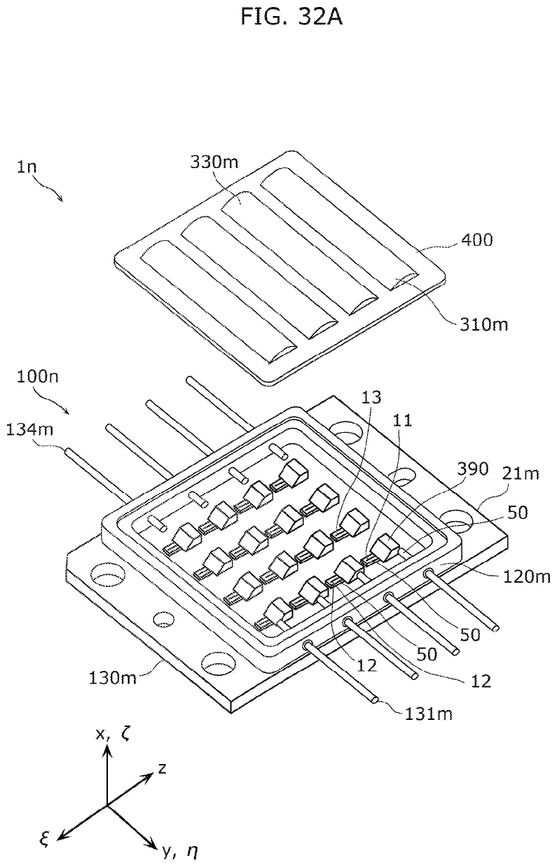

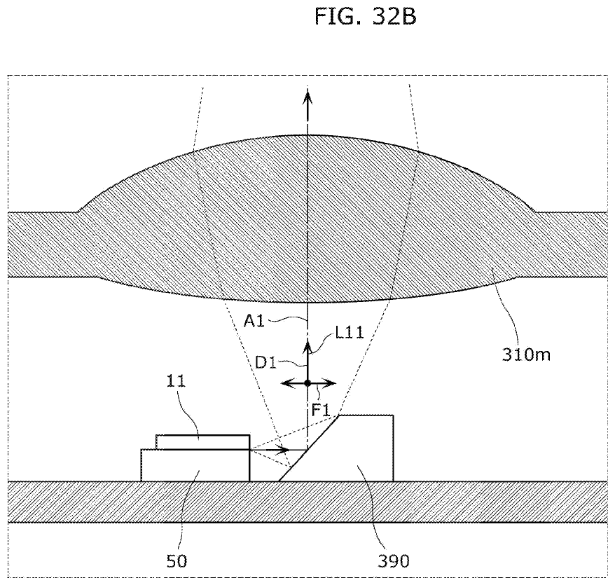

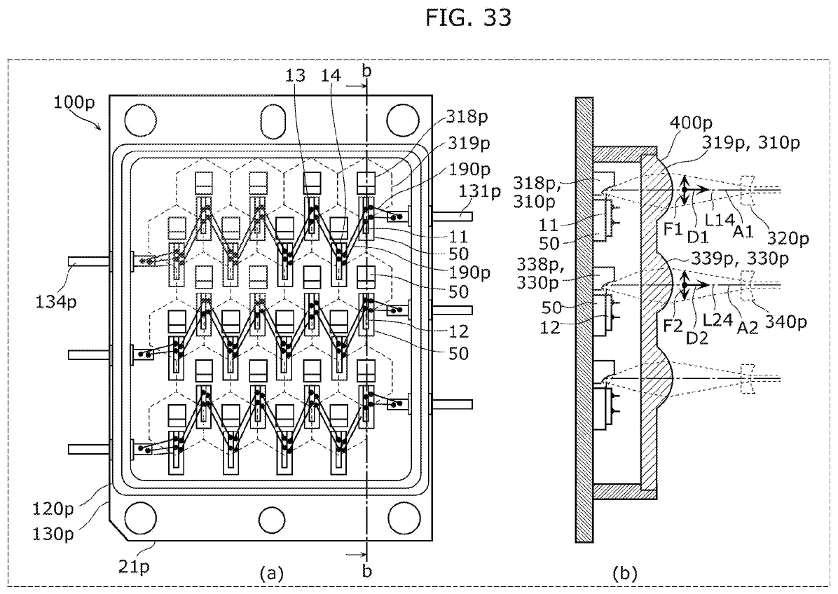

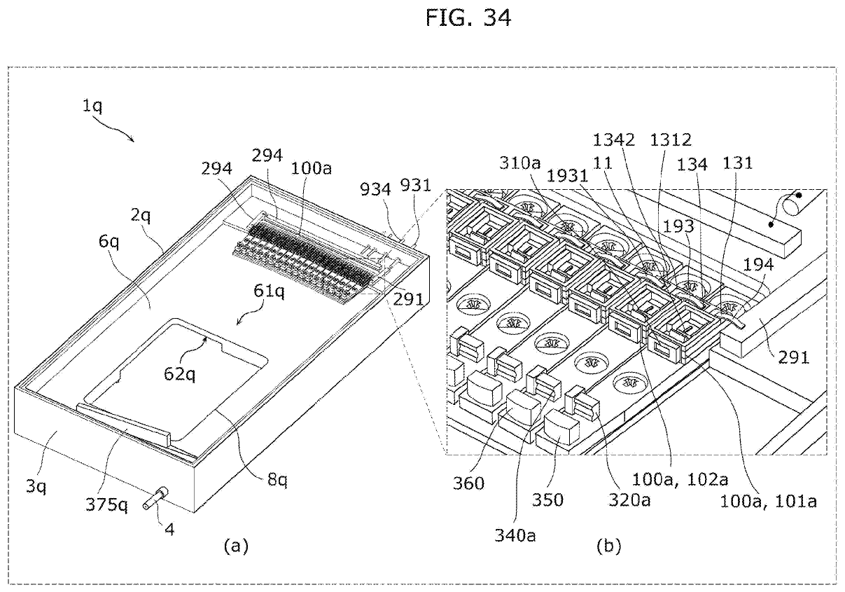

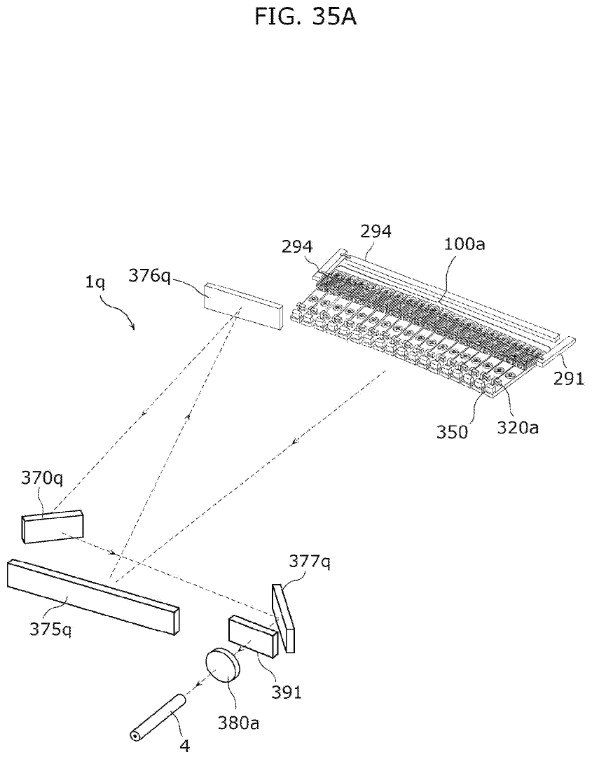

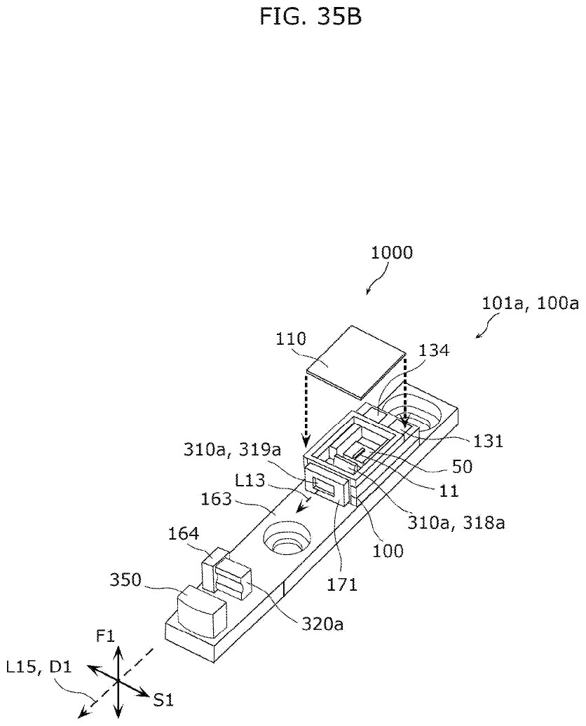

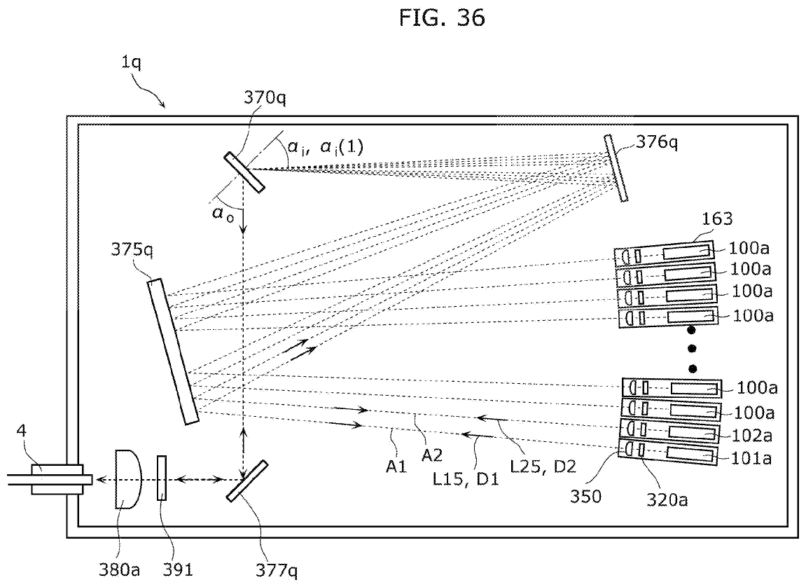

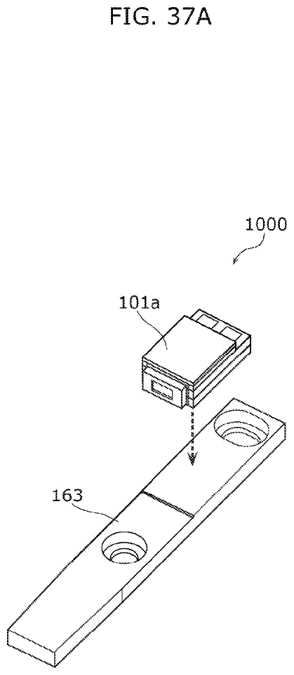

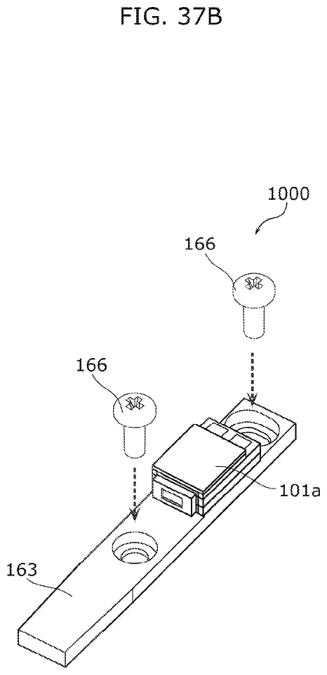

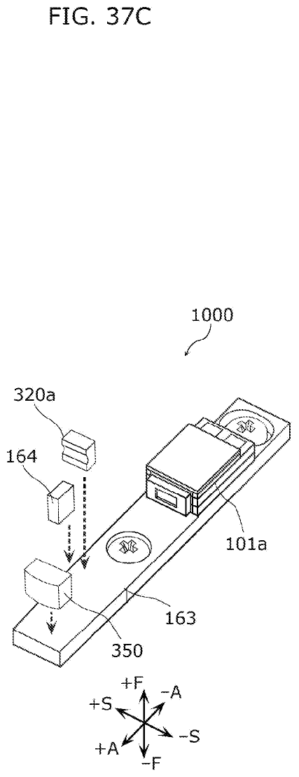

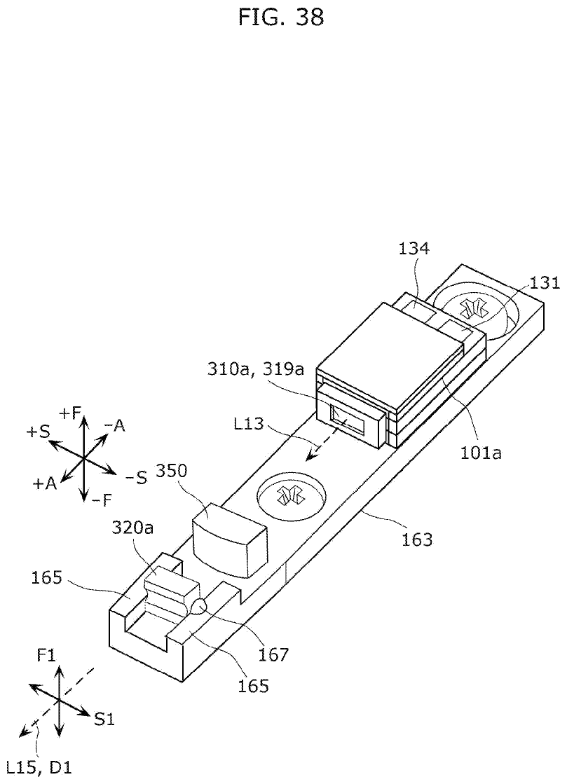

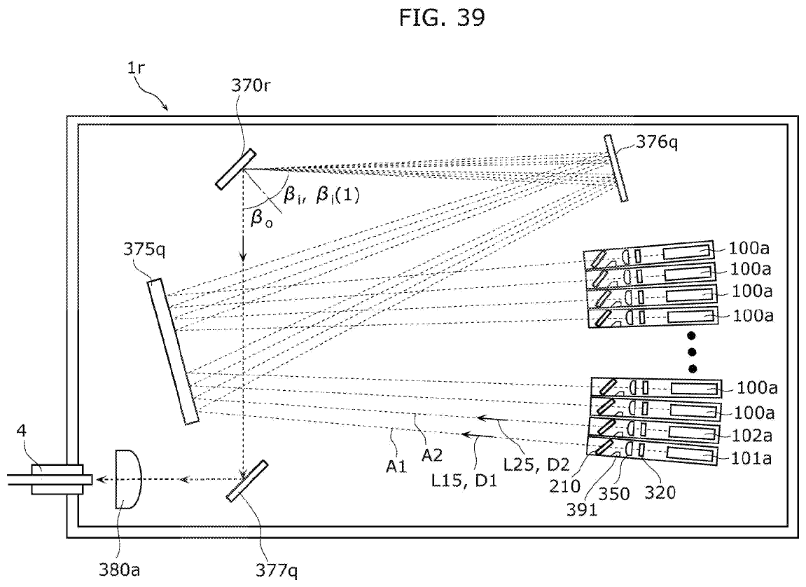

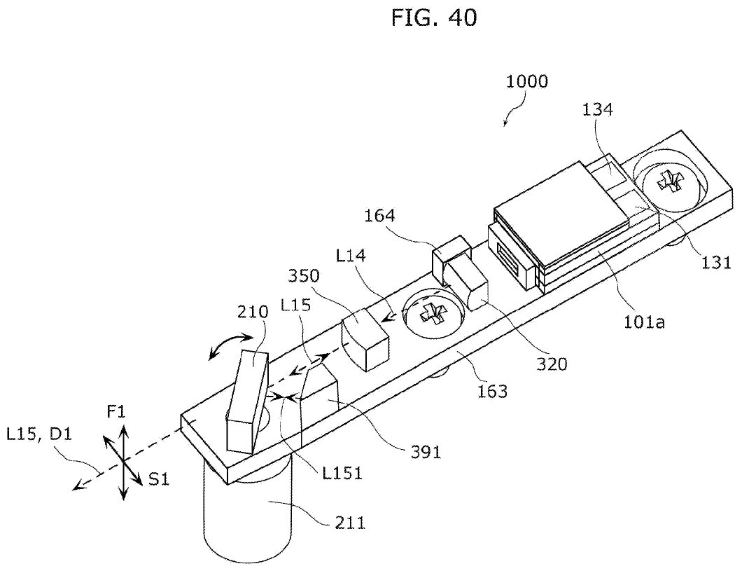

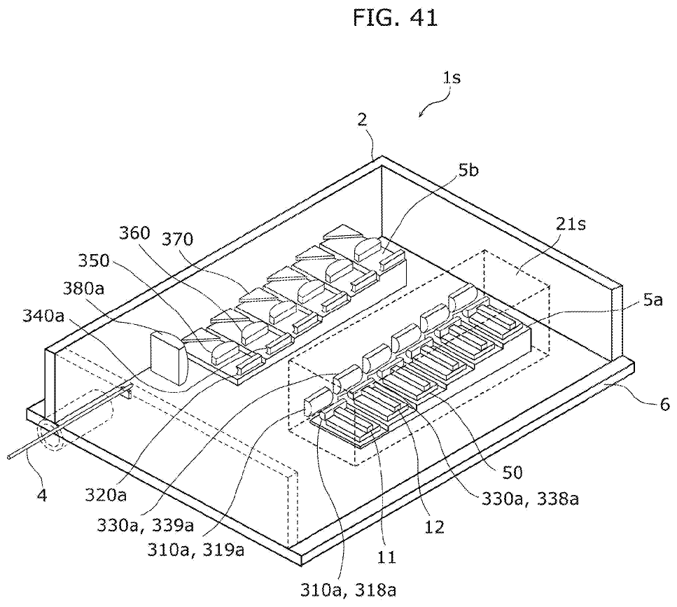

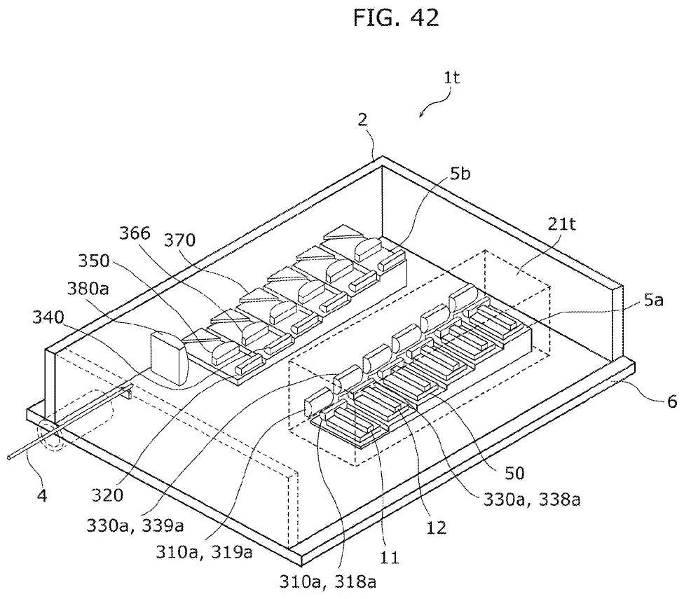

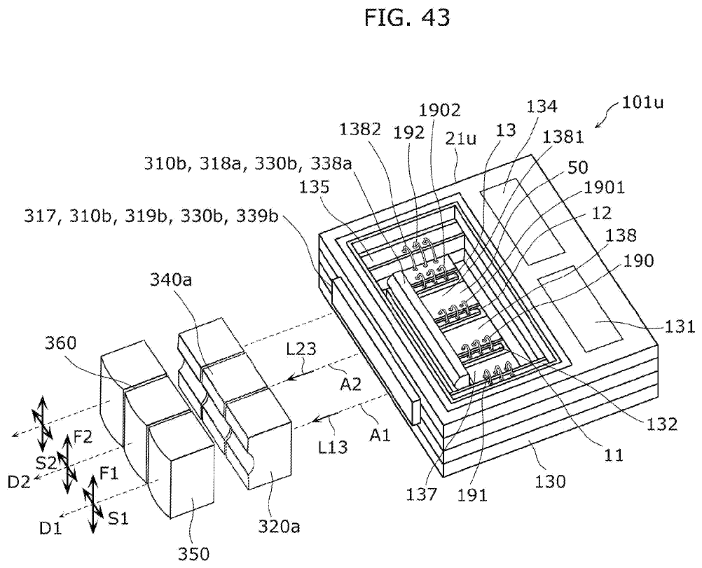

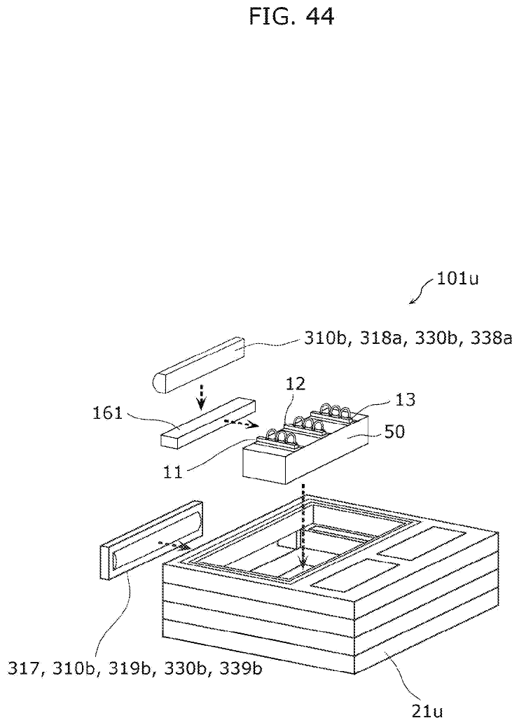

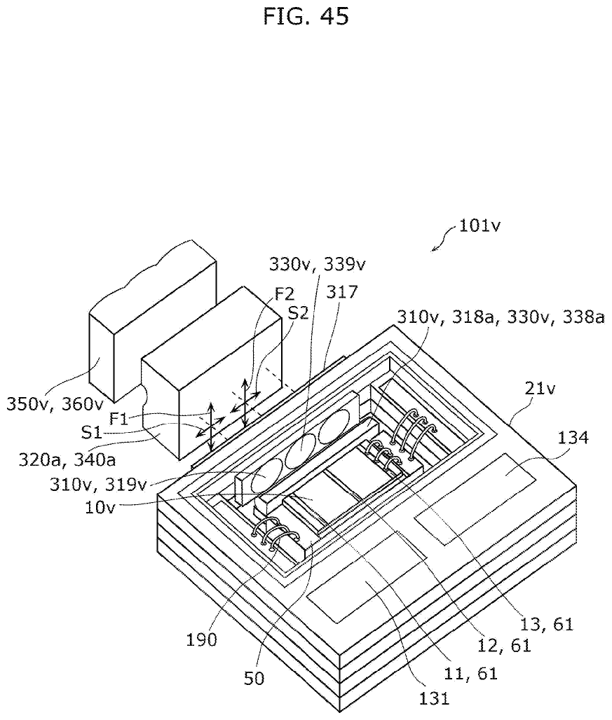

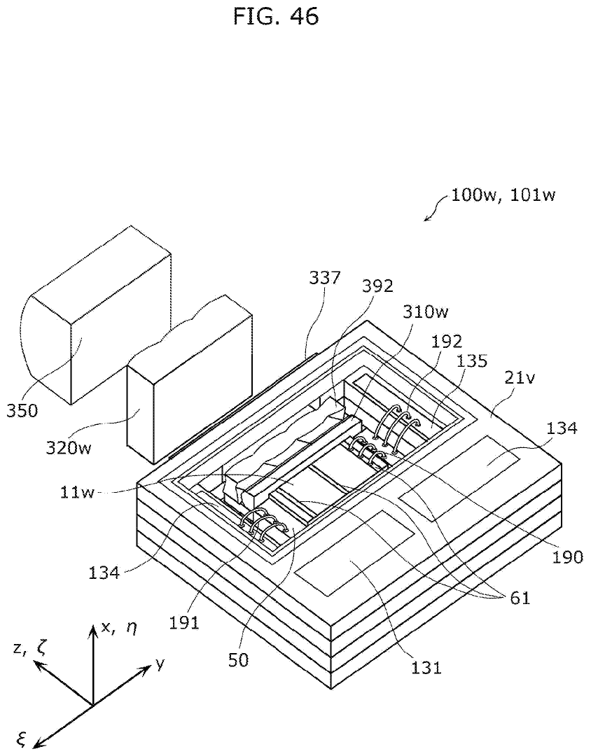

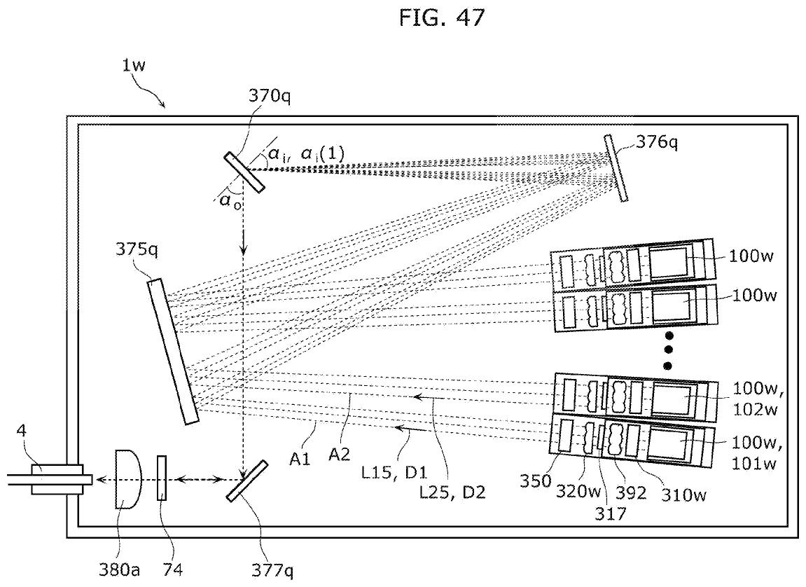

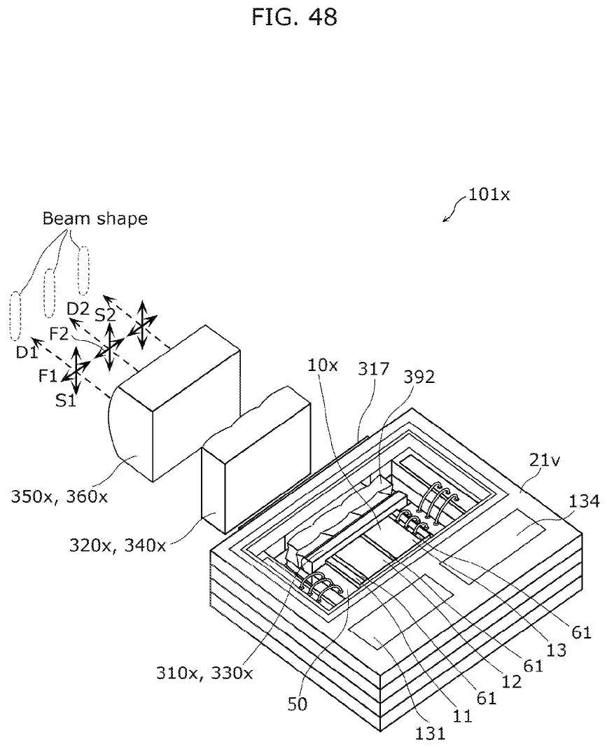

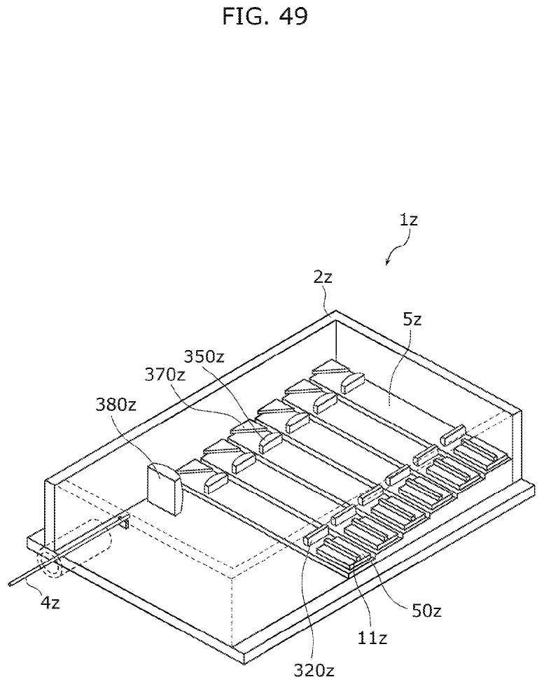

FIG. 21A is a schematic diagram illustrating one example of a method of manufacturing first semiconductor laser module 101d according to Variation 3 of Embodiment 2. FIG. 21B is a schematic diagram illustrating another example of the method of manufacturing first semiconductor laser module 101d according to Variation 3 of Embodiment 2. More specifically, (a) in FIG. 21B shows a step of manufacturing frame body 120 and bottom 130, and (b) in FIG. 21B shows a step of manufacturing first semiconductor laser module 101d.

First metal film 137 and second bonding material 142 are formed on the surface of submount 50, but a second metal film is not formed thereon, Instead, metal wire 190d connected to a substrate side of first semiconductor laser element 11 is directly connected to cathode electrode 135 of first package 21d.

First package 21d differs from first package 21 in structure. Specifically, first package 21d has a structure in which first frame portion 121a and bottom 130 in first package 21 are integral. In first package 21d, opening 170 is provided in a portion surrounded by bottom 130, second frame portion 122b, and third frame portion 123c.

### Variation 4 of Embodiment 2

FIG. 22 is a schematic diagram illustrating an optical system of first semiconductor laser module 101e included in light source module 1e according to Variation 4 of Embodiment 2. Specifically, (a) in FIG. 22 is a plan view, and (b) in FIG. 22 is a cross-sectional view of a cross section along line b-b shown in (a) in FIG. 22.

Light source module 1e has the same configuration as light source module 1a according to Embodiment 2 except mainly for the following one point. Specifically, the one point is a point that first optical element 310e obtained by integrating eighth optical element 318a and ninth optical element 319a according to Embodiment 2 is provided.

As shown in FIG. 22, first optical element 310e is a lens including a convex cylindrical face, and is disposed so that a power axis is parallel to second optical axis F1. Moreover, first optical element 310e and light-transmissive window 317 are integrally formed. Furthermore, part of first optical element 310e is hermetically sealed in first package 21. More specifically, the part of first optical element 310e is an incident face of first optical element 310e for the first laser beam.

### Variation 5 of Embodiment 2

FIG. 23 is a schematic diagram illustrating an optical system of first semiconductor laser module 101f included in light source module 1f according to Variation 5 of Embodiment 2.

Light source module 1f has the same configuration as light source module 1a according to Embodiment 2 except mainly for the following two points. Specifically, the two points are a point that eighth optical element 318f that is part of first optical element 310f includes a concave mirror face, and a point that ninth optical element 319f that is part of first optical element 310f includes a convex face facing outward of first package 21.

In the present variation, eighth optical element 318f includes a reflective concave mirror face. In addition, the concave mirror face is, for example, a paraboloidal face, Eighth optical element 318f is disposed to face luminous point 60 of first semiconductor laser element 11. Eighth optical element 318f deflects by 90° a direction of a laser beam emitted from luminous point 60 at first divergence angle θfd1 in the fast axis direction, and at the same time reduces a divergence angle of a laser beam in the fast axis direction reflected by eighth optical element 318f. The laser beam reflected by eighth optical element 318f is incident on ninth optical element 319f.

As a result, a relation between the orientation of bottom 130 of first semiconductor laser module 101f and the direction of the laser beam emitted from first semiconductor laser module 101f is different from, for example, a relation between the orientation of bottom 130 of first bottom 101 according to Embodiment 1 and the direction of the laser beam emitted from first semiconductor laser module 101. In other words, a degree of freedom for design of arrangement of semiconductor laser modifies such as first semiconductor laser module 101f increases.

### Variation 6 of Embodiment 2

FIG. 24 is a schematic diagram illustrating an optical system of first semiconductor laser module 101g included in light source module 1g according to Variation 6 of Embodiment 2. Specifically, (a) in FIG. 24 is a plan view, and (b) in FIG. 24 is a cross-sectional view of a cross section along line b-b shown in (a) in FIG. 24.

Light source module 1g has the same configuration as light source module 1a according to Embodiment 2 except mainly for the following one point. Specifically, the one point is a point that ninth optical element 319g that is part of first optical element 310g is a rotationally symmetric convex lens.

As shown in FIG. 24, a first laser beam having passed through ninth optical element 319g converges at first convergence angle θfc1 in the direction along second optical axis F1. Moreover, the first laser beam having passed through ninth optical element 319g converges at convergence angle θsc1 in a direction along third optical axis S1 and is brought into focus, and then spreads at divergence angle θsc1 and is incident on fifth optical element 350.

In this case, since ninth optical element 319g is the convex lens having power also in the direction along third optical axis S1, it is possible to increase a distance between fifth optical element 350 and ninth optical element 319g included in a window of first package 21. Accordingly, it is easy to design the position of fifth optical element 350.

### Variation 7 of Embodiment 2

FIG. 25 is a schematic diagram illustrating an optical system of first semiconductor laser module 101h included in light source module 1h according to Variation 7 of Embodiment 2. Specifically, (a) in FIG. 25 is a plan view, and (b) in FIG. 25 is a cross-sectional view of a cross section along line b-b shown in (a) in FIG. 25.

Light source module 1h has the same configuration as light source module 1a according to Embodiment 2 except mainly for the following one point. Specifically, the one point is a point that second optical element 320h is a lens including a convex cylindrical face having power in a direction along second optical axis F1.

As shown in FIG. 25, a first laser beam having passed through ninth optical element 319h converges at convergence angle θfc1 in the direction along second optical axis F1 and is brought into focus, and then spreads at divergence angle θfc1 and is incident on second optical element 320h. In this case, since second optical element 320h is the lens including the convex cylindrical face having power in the direction along second optical axis F1, it is possible to increase a distance between second optical element 320h and ninth optical element 319h included in a window of first package 21, Accordingly, it is easy to design the position of second optical element 320h.

Additionally, by disposing second optical element 320h in the vicinity of the convergent position of the first laser beam, it is possible to decrease beam width BFw of the first laser beam in a fast axis direction.

### Variation 8 of Embodiment 2

FIG. 26 is a schematic diagram illustrating an optical system of first semiconductor laser module 101i included in light source module 1i according to Variation 8 of Embodiment 2. Specifically, (a) in FIG. 26 is a plan view, and (b) in FIG. 26 is a cross-sectional view of a cross section along line b-b shown in (a) in FIG. 26.

Light source module 1i has a configuration obtained by replacing second optical element 320a of light source module 1d according to Variation 3 of Embodiment 2 with second optical element 320h according to Variation 7 of Embodiment 2.

### Variation 9 of Embodiment 2

FIG. 27 is a schematic diagram illustrating an optical system of first semiconductor laser module 101j included in light source module 1j according to Variation 9 of Embodiment 2. Specifically, (a) in FIG. 27 is a plan view, and (b) in FIG. 27 is a cross-sectional view of a cross section along line b-b shown in (a) in FIG. 27.

Light source module 1j has a configuration obtained by replacing second optical element 320a of light source module 1e according to Variation 4 of Embodiment 2 with second optical element 320h according to Variation 7 of Embodiment 2.

### Variation 10 of Embodiment 2

FIG. 28 is a schematic diagram illustrating an optical system of first semiconductor laser module 101k included in light source module 1k according to Variation 10 of Embodiment 2. Specifically, (a) in FIG. 28 is a plan view, and (b) in FIG. 28 is a cross-sectional view of a cross section along line b-b shown in (a) in FIG. 28.

Light source module 1k has a configuration obtained by replacing second optical element 320a of light source module 1g according to Variation 6 of Embodiment 2 with second optical element 320h according to Variation 7 of Embodiment 2.

### Embodiment 3

Next, Embodiment 3 will be described. Embodiment 3 differs from Embodiments 1 and 2 in using a semiconductor laser module in which semiconductor laser elements are two-dimensionally arranged. The following mainly describes differences from Embodiment 2, and omits or simplifies description of common points.

FIG. 29 is a perspective view of an optical system of light source module 1m according to Embodiment 3. FIG. 30 is a cross-sectional view of a cross section of the optical system of light source module 1m, taken along line XXX-XXX shown in FIG. 29. FIG. 31 is a perspective view of a configuration of light source module 100m included in light source module 1m.

As shown in FIG. 29 to FIG. 31, light source module 1m includes one semiconductor laser module 100m, FAC lenses, SAC lenses, seventh optical element 370m, twelfth optical element 380m, and optical fiber 4m. The FAC lenses include, for example, second optical element 320m and fourth optical element 340m. The SAC lenses include, for example, fifth optical element 350m and sixth optical element 360m. Seventh optical element 370m includes first reflecting mirrors 371 and second reflecting mirrors 372.

Semiconductor laser module 100m includes first package 21m, semiconductor laser elements (e.g., first semiconductor laser elements 11 and second semiconductor laser elements 12), submounts 50, and lens array optical element 400. Lens array optical element 400 is obtained by integrating first optical element 310m and third optical element 330m.

First package 21m includes bottom 130m, frame body 120m, and posts 180. Bottom 130m is, for example, a plate-shaped component comprising a material having a high heat conductivity such as Cu. Frame body 120 is a frame-shaped component in the center of which an opening is provided, comprises, for example, kovar, and is fixed to bottom 130m with, for example, silver solder. Anode extraction electrodes 131m that are lead pins are formed on one side wall of frame body 120m. Cathode extraction electrodes 134m that are lead pins are formed on the side wall of frame body 120m opposite the one side wall of frame body 120m on which anode extraction electrodes 131m are formed. Anode extraction electrodes 131m and cathode extraction electrodes 134m are provided to penetrate through frame body 120m, and are fixed to frame body 120m via insulating rings comprising, for example, insulative inorganic glass.

Posts 180 are each a cuboid component comprising a material having a high heat conductivity such as Cu. Posts 180 are arranged at predetermined intervals in a short axis direction (x direction), on the surface of bottom 130m (a z-axis positive direction side). Posts 180 are fixed to bottom 130m with, for example, silver solder.

Frame body 120m is disposed perpendicular to bottom 130m. In addition, frame body 120m is disposed to surround posts 180. The semiconductor laser elements are mounted so that the semiconductor laser elements are arranged on each of the side surfaces of posts 180 in its long axis direction (y direction) via respective submounts 50. In other words, the semiconductor laser elements are two-dimensionally arranged in an opening of frame body 120m. More specifically, the semiconductor laser elements are arranged in a matrix in the opening of frame body 120m. Although sixteen semiconductor laser elements are arranged in a 4×4 matrix in the present embodiment, the present disclosure is not limited to this example. Each semiconductor laser element and each submount 50 are fixed using an inorganic material such as AuSn solder. Moreover, semiconductor laser elements mounted on one post 180 are electrically connected in series by metal wires not shown, and are further connected to anode extraction electrode 131m and cathode extraction electrode 134m. It should be noted that, for purpose of identification, semiconductor laser elements may be referred to as, for example, first semiconductor laser element 11, second semiconductor laser element 12, and third semiconductor laser element 13.

First semiconductor laser element 11, second semiconductor laser element 12, and third semiconductor laser element 13 are, respectively, for example, nitride-based semiconductor laser elements that emit a first laser beam, a second laser beam, and a third laser beam. The first laser beam, the second laser beam, and the third laser beam are emitted in a direction (ζ-axis positive direction, z direction) from bottom 130m to frame body 120m. A slow axis (third optical axis S1, sixth optical axis S2, etc.) of each of the first laser beam, the second laser beam, and the third laser beam is the long axis direction (y direction) of post 180, and a fast axis (second optical axis F1, fifth optical axis F2, etc.) of each of the first laser beam, the second laser beam, and the third laser beam is the direction (x direction) in which posts 180 are arranged. Although second semiconductor laser element 12 is disposed on a side surface of different post 180 from first semiconductor laser element 11, second semiconductor laser element 12 is located next to first semiconductor laser element 11 in the direction along second optical axis F1. Third semiconductor laser element 13 is disposed on the same side surface of post 180 as first semiconductor laser element 11, and is located next to first semiconductor laser element 11 in the direction along third optical axis S1.

Lens array optical element 400 is an optical component on which the first laser beam, the second laser beam, and the third laser beam emitted from first semiconductor laser element 11, second semiconductor laser element 12, and third semiconductor laser element 13 are incident. Lens array optical element 400 has biconvex cylindrical lens structures serving as FA lenses. In the present embodiment, as shown in FIG. 29 to FIG. 31, the biconvex cylindrical lens structures extend in the same shape in the long axis direction of post 180, that is, the direction along third optical axis S1. The biconvex cylindrical lens structures include, as one biconvex cylindrical lens structure, first optical element 310m on which the first laser beam and the third laser beam are incident, and, as one biconvex cylindrical lens structure, third optical element 330m on which the second laser beam is incident. These biconvex cylindrical lens structures are located next to each other in the x direction.

Moreover, lens array optical element 400 is a component that covers the opening of frame body 120m located on a z-axis positive direction side of frame body 120m. In other words, in the present embodiment, lens array optical element 400 is also an optical element obtained by integrally forming a lid and a light-transmissive window. Lens array optical element 400 includes, on the periphery, a flat edge portion on which no biconvex cylindrical lens structures are formed; and are fixed to flat step portion 121m inside frame body 120m with a solder material etc. As a result, the semiconductor laser elements are hermetically sealed in first package 21m by frame body 120m, lens array optical element 400, and bottom 130m. Such a configuration makes it possible to hermetically seal first semiconductor laser element 11 using lens array optical element 400. To put it another way, it is possible to reduce the number of components constituting light source module 1m.

In a laser beam emission direction of semiconductor laser module 100m, the FAC lenses on which laser beams (e.g., first laser beam L13) are incident are arranged in a 4×4 matrix in the direction along second optical axis F1 (ξ direction, x direction) and the direction along third optical axis S1 (η direction, y direction) so as to correspond to the laser beams. Each of the FAC lenses has the same configuration as second optical element 320a according to Embodiment 2, In other words, first laser beam L13 is incident on second optical element 320m. Second laser beam L23 is incident on fourth optical element 340m.

Moreover, similarly, the SAC lenses on which laser beams (e.g., first laser beam L14) having exited the FAC lenses are incident are arranged in a 4×4 matrix in the direction along second optical axis F1 (ξ direction) and the direction along third optical axis S1 (η direction), Each of the SAC lenses has the same configuration as fifth optical element 350 according to Embodiment 2. In other words, first laser beam L14 is incident on fifth optical element 350m. Second laser beam L24 is incident on sixth optical element 360m.

The FAC lenses and the SAC lenses are each adjusted to an optimal position relative to a corresponding one of laser beams emitted from semiconductor laser module 100m, and are fixed with an ultraviolet curable adhesive etc. The FAC lenses and the SAC lenses cause laser beams (e.g., first laser beam L15 and second laser beam L25) emitted from laser elements to be laser beams that are collimated light beams having a narrow beam width in the direction along second optical axis F1 and being parallel to each other; and cause the laser beams to travel to seventh optical element 370m.

In FIG. 30, a beam width of first laser beam L15 having passed through fifth optical element 350m, which is a SAC lens, in the direction along second optical axis F1 (fast axis) is denoted by BFw1, Likewise, an entire beam width of laser beams having passed through SAC lenses in the direction along second optical axis F1 (fast axis) is denoted by BFw2. Entire beam width BFw2 of the laser beams having exited the SAC lenses is great depending on the intervals between the semiconductor laser elements at this point.

The laser beams having passed through the SAC lenses are reflected by first reflecting mirrors 371, and further reflected by second reflecting mirrors 372. Sixteen first reflecting mirrors 371 in total correspond to the laser beams and are arranged in a 4×4 matrix. Reflecting faces of first reflecting mirrors 371 are inclined at 45° relative to first direction D1 of the first laser beam.

In order of first reflecting mirrors 371 in a direction from first semiconductor laser element 11 to second semiconductor laser element 12, the respective reflecting faces of first reflecting mirrors 371 are disposed so as to approach semiconductor laser module 100m at intervals of approximately beam width BFw1. In consequence, laser beams (e.g., first laser beam L15 and second laser beam L25) emitted from first semiconductor laser dement 11 and a semiconductor laser element (e.g., second semiconductor laser element 12) located next to first semiconductor laser element 11 in the direction along second optical axis F1 have overlapping fast axes, become laser beams combined to have a beam width approximately equivalent to a beam width of one laser beam, and travel in a direction to second reflecting mirrors 372 (x-axis negative direction).

FIG. 30 further shows first reflecting mirrors 371 each corresponding to a different one of laser beams emitted from third semiconductor laser element 13 and semiconductor laser dements arranged in the direction along second optical axis F1 from third semiconductor laser dement 13.

First reflecting mirrors 371 corresponding to third semiconductor laser element 13 and the semiconductor laser elements arranged in the direction along second optical axis F1 from third semiconductor laser dement 13 are located farther from semiconductor laser module 100m than first reflecting mirror 371 corresponding to first semiconductor laser dement 11 is.

Similarly, the respective reflecting faces of first reflecting mirrors 371 corresponding to the semiconductor laser dements arranged in order in a direction along second optical axis F1 from third semiconductor laser dement 13 are disposed so as to approach semiconductor laser module 100m at intervals of approximately beam width BFw1.

First reflecting mirror 371 corresponding to a semiconductor laser element farthest from third semiconductor laser element 13 and the reflecting mirror corresponding to first semiconductor laser element 11 are disposed at intervals of approximately beam width BFw1 in first direction D1. According to this configuration, laser beams emitted from third semiconductor laser element 13 and the semiconductor laser elements arranged in the direction along second optical axis F1 from third semiconductor laser element 13 have overlapping fast axes, become laser beams combined to have a beam width approximately equivalent to a beam width of one laser beam, and travel in a direction to second reflecting mirrors 372 (x-axis negative direction).

Hereinafter, first, out of the sixteen semiconductor laser elements, eight semiconductor laser elements will be described. In FIG. 30, third semiconductor laser element 13 and a semiconductor laser element next to third semiconductor laser element 13 in the direction along second optical axis F1 overlap first semiconductor laser element 11 and second semiconductor laser element 12, respectively, and respective laser beams emitted from these semiconductor laser elements appear to overlap the first and second laser beams, but they are displaced in the direction along third optical axis S1, After laser beams emitted from first semiconductor laser element 11 and the semiconductor laser element located next to first semiconductor laser element 11 in the direction along second optical axis F1, and laser beams emitted from third semiconductor laser element 13 and the semiconductor laser element located next to third semiconductor laser element 13 in the direction along second optical axis F1 are reflected by first reflecting mirrors 371, the laser beams are arranged at intervals of approximately beam width BFw1 in the direction along second optical axis F1 (z direction) as viewed from the direction along third optical axis S1 (y direction). In this way, it is possible to sufficiently decrease entire beam width BFw3 of laser beams (eight laser beams in the present embodiment) in the direction along second optical axis F1 (fast axis) emitted from semiconductor laser elements, by the laser beams being reflected by first reflecting mirrors 371, compared to beam width BFw2 prior to incidence.

Out of the sixteen semiconductor laser elements, the remaining eight semiconductor laser elements have the same configuration as the above-described eight semiconductor laser elements. The eight semiconductor laser elements and the remaining eight semiconductor laser elements form two rows.

Moreover, as shown in FIG. 29, laser beams reflected by first reflecting mirrors 371 are reflected by second reflecting mirrors 372. At this time, laser beams emitted from semiconductor laser elements arranged in the direction along second optical axis F1 are reflected by same second reflecting mirror 372. In addition, second reflecting mirror 372 that reflects laser beams emitted from first semiconductor laser element 11 and semiconductor laser elements arranged in the direction along second optical axis F1 from first semiconductor laser element 11 includes a reflecting face that coincides with, in the direction along third optical axis S1, a reflecting face of second reflecting mirror 372 that reflects laser beams emitted from third semiconductor laser element 13 and semiconductor laser elements arranged in the direction along second optical axis F1 from third semiconductor laser element 13. As a result, the laser beams emitted from first semiconductor laser element 11 and the semiconductor laser elements arranged in the direction along second optical axis F1 from first semiconductor laser element 11 coincide with, in the direction along second optical axis F1 (fast axis), the laser beams emitted from third semiconductor laser element 13 and the semiconductor laser elements arranged in the direction along second optical axis F1 from third semiconductor laser element 13. Accordingly, laser beams emitted from semiconductor laser module 100m become a laser beam group in a 2×8 matrix after being reflected by second reflecting mirrors 372, and the laser beam group travels to twelfth optical element 380m. In consequence, an entire beam width of the laser beams in the direction along third optical axis S1 (slow axis) decreases.

The laser beams reflected by second reflecting mirrors 372 reach twelfth optical element 380m. Laser beams condensed by twelfth optical element 380m are incident on optical fiber 4m. It should be noted that twelfth optical element 380m is equivalent to twelfth optical element 380a according to Embodiment 2.

Light source module 1m according to the present embodiment is capable of causing the optical system to spatially combine and send out the laser beams emitted from the respective semiconductor laser elements included in one semiconductor laser module 100m.

Specifically, in semiconductor laser module 100m, an optical element integrated with FA lenses is fixed by positioning with respect to the sixteen semiconductor laser elements. Accordingly, in relation to a variation in position of each of semiconductor laser elements, the corresponding one of FA lenses is not adjusted to a corresponding optimal position. In light source module 1m, however, FAC lenses and SAC lenses corresponding to the individual semiconductor laser elements are provided apart from the optical element integrated with the FA lenses. As a result, since positions of the FAC lenses and the SAC lenses are each adjusted for a corresponding one of the laser beams emitted from semiconductor laser module 100m, it is possible to emit collimated laser beams that are parallel to each other. For this reason, it is possible to easily and spatially combine laser beams using seventh optical element 370m. In addition, divergence angles of components of laser beams, which are emitted from semiconductor laser module 100m, in a fast axis direction are smaller than divergence angles of laser beams emitted from the semiconductor laser elements. Accordingly, it is possible to easily adjust the positions of the FAC lenses.

Moreover, the configuration according to the present embodiment makes it possible to decrease an entire beam width of laser beams both in the direction along second optical axis F1 and the direction along third optical axis S1, Consequently, the laser beams can be incident on an object (the end face portion of optical fiber 4m) with high coupling efficiency.

Furthermore, semiconductor laser module 100m according to the present embodiment is said to be obtained by integrating the first semiconductor laser module and the second semiconductor laser module.

Hereinafter, Variations 1 and 2 of Embodiment 3 will be described. The following mainly describes differences from Embodiment 3, and omits or simplifies description of common points.

### Variation 1 of Embodiment 3

FIG. 32A is a perspective view of a configuration of one semiconductor laser module 100n included in light source module 1n according to Variation 1 of Embodiment 3. FIG. 32B is a schematic cross-sectional view of a configuration of the surroundings of first semiconductor laser element 11 included in one semiconductor laser module 100n according to Variation 1 of Embodiment 3.

Semiconductor laser source module 100n has the same configuration as light source module 1m according to Embodiment 3 except mainly for the following three points. Specifically, the three points are a point that posts 180 are not provided, a point that semiconductor laser elements are directly disposed on bottom 130m via submounts 50, and a point that thirteenth optical elements 390 are provided to correspond to respective laser beam emission sides of the semiconductor laser elements.

Thirteenth optical elements 390 are located to correspond to the respective semiconductor laser elements. As an example, thirteenth optical element 390 is an optical component between first semiconductor laser element 11 and first optical element 310m.

Thirteenth optical element 390 is an upward-reflecting mirror element including a reflecting face inclined at 45° relative to a laser beam emission direction of the semiconductor laser element. Although the reflecting face is a flat mirror in the present embodiment, as with eighth optical element 318f according to Variation 5 of Embodiment 2, the reflecting face may include a reflective concave mirror face. The concave mirror face is, for example, a paraboloidal face.

Thirteenth optical elements 390 deflect laser beams emitted by the respective semiconductor laser elements in a direction parallel to the surface of bottom 130m (z direction) by 90° in a direction from bottom 130m to frame body 120m (ζ direction, x direction). For this reason, first direction D1 of the first laser beam is deflected by 90°.

In the present variation, since thirteenth optical elements 390 are provided, it is possible to dispose the semiconductor laser elements on bottom 130m via submounts 50. Accordingly, Joule heat generated in the semiconductor laser elements is efficiently transferred to bottom 130m and efficiently exhausted.

Moreover, it is possible to replace semiconductor laser module 100m included in light source module 1m according to Embodiment 3 with semiconductor laser module 100n. By disposing semiconductor laser module 100n so that first direction D1 (ζ direction), the direction along second optical axis F1 (ξ direction), and the direction along third optical axis S1 (η direction) of the first laser beam emitted from semiconductor laser module 100n coincide with first direction D1 (ζ direction), the direction along second optical axis F1 (ξ direction), and the direction along third optical axis S1 (η direction) of the first laser beam emitted from light source module 1m, respectively, laser beams emitted from semiconductor laser module 100n in the direction from bottom 130m to frame body 120m (direction) show the same behavior as those emitted from light source module 1m. In other words, the present variation produces the same advantageous effects as Embodiment 3, Specifically, even if all the positions, that determine the optical axes of the laser beams, of the luminous points of the semiconductor laser elements, of the reflecting faces of thirteenth optical elements 390, and of the biconvex cylindrical lens structures in lens array optical element 400 are not simultaneously adjusted and fixed with high precision when semiconductor laser module 100n is manufactured, it is possible to adjust the traveling and collimated beam characteristics of the laser beams with high precision by positioning the FAC lenses and the SAC lenses. Accordingly, it is possible to cause the laser beams to be incident on the object (the end face portion of the optical fiber) with high coupling efficiency.

### Variation 2 of Embodiment 3

FIG. 33 is a diagram illustrating a configuration of one semiconductor laser module 100p included in a light source module according to Variation 2 of Embodiment 3, More specifically, (a) in FIG. 33 is a view of semiconductor laser module 100p as viewed from lens array optical element 400p side, and (b) in FIG. 33 is a cross-sectional view of a cross section along line b-b shown in (a) in FIG. 33 and shows an optical system.

Semiconductor laser source module 100p has the same configuration as light source module 1n according to Variation 1 of Embodiment 3 except mainly for the following two points. Specifically, the two points are a point that semiconductor laser elements and lenses of lens array optical element 400p are arranged in a triangular lattice, and a point that the lens provided to lens array optical element 400p and the reflecting faces of thirteenth optical elements are in different shapes.

In the present variation, the semiconductor laser elements are arranged in a triangular lattice. More specifically, the semiconductor laser elements are arranged to correspond to the apexes of triangles in the triangular lattice. Moreover, eighth optical element 318p and tenth optical element 338p disposed on emission sides of semiconductor laser elements are each a reflecting mirror and include the same paraboloidal concave reflecting mirror face as eighth optical element 318f according to Variation 5 of Embodiment 2. Furthermore, ninth optical element 319p and eleventh optical element 339p formed in lens array optical element 400p each have the same plano-convex lens structure as ninth optical element 319f according to Variation 5 of Embodiment 2. Accordingly, first optical element 310p is composed of a combination of eighth optical element 318p and ninth optical element 319p. First optical element 310p is provided in a position corresponding to each of the semiconductor laser elements.

Optical axis A1 of eighth optical element 318p and ninth optical element 319p is provided to correspond to the apex of a triangle in the triangular lattice. As shown in (a) in FIG. 33, a boundary of each of ninth optical element 319p and eleventh optical element 339p forms a hexagonal shape in a plan view.

First package 21p of semiconductor laser module 100p includes bottom 130p and frame body 120p fixed on bottom 130p. Anode extraction electrodes 131p that are lead pins are formed on one side wall of frame body 120p. Cathode extraction electrodes 134p that are lead pins are formed on the side wall of frame body 120p opposite the one side wall of frame body 120p. Anode extraction electrodes 131p and cathode extraction electrodes 134p are disposed so that their lead pins are alternated. First semiconductor laser element 11 and second semiconductor laser element 12 are located on an anode extraction electrode 131p side in first package 21p, and are arranged in a direction in which the lead pins of anode extraction electrodes 131p are arranged.

First and second laser beams respectively emitted from first semiconductor laser element 11 and second semiconductor laser element 12 are emitted from semiconductor laser module 100p with fast axes (second optical axis F1 and fifth optical axis F2) being overlapped. Third semiconductor laser element 13 is located in a direction along third optical axis S1 with respect to first semiconductor laser element 11. Fourth semiconductor laser element 14 is disposed in an electrical connection between first semiconductor laser element 11 and third semiconductor laser element 13. As stated above, in the present variation, since the semiconductor laser elements are arranged in the triangular lattice, it is possible to increase a packaging density of the semiconductor laser elements.

It should be noted that the semiconductor laser elements are electrically connected in series with metal wires 190p. A first metal film and a second bonding material are provided on a semiconductor laser element side of submount 50. Respective metal wires 190p connect anode extraction electrode 131p, a first metal film of submount 50 holding first semiconductor laser element 11, the surface of first semiconductor laser element 11 on a substrate side, a first metal film of submount 50 holding fourth semiconductor laser element 14, the surface of fourth semiconductor laser element 14 on the substrate side, a first metal film of submount 50 holding third semiconductor laser element 13, and cathode extraction electrode 134p.

Moreover, it is possible to use semiconductor laser module 100p instead of semiconductor laser module 100m included in light source module 1m according to Embodiment 3.

### Embodiment 4

Next, Embodiment 4 will be described. Embodiment 4 differs from Embodiment 2 in that semiconductor laser modules are two-dimensionally arranged, and in that a seventh optical element includes a diffraction grating and combines laser beams using wavelength beam combining. The following mainly describes differences from Embodiment 2, and omits or simplifies description of common points.

### [Configuration]

First, a configuration of a light source module according to Embodiment 4 will be described with reference to FIG. 34 and FIG. 35A.

FIG. 34 is a perspective view of a configuration of light source module 1q. More specifically, (a) in FIG. 34 is a perspective view of an entire configuration of light source module 1q. (b) in FIG. 34 is an enlarged perspective view of semiconductor laser modules 100a etc. according to Embodiment 4.

FIG. 35A is a perspective view of an example of an optical system of light source module 1q. It should be noted that a representative behavior of a laser beam is indicated by a dashed arrow in FIG. 35A.

As shown in FIG. 34 and FIG. 35A, light source module 1q includes: case 2q; semiconductor laser modules 100a; FAC lenses (e.g., second optical element 320a and fourth optical element 340a); SAC lenses (e.g., fifth optical element 350 and sixth optical element 360); first reflecting mirror 375q; second reflecting mirror 376q; third reflecting mirror 377q; seventh optical element 370q that is a diffraction grating; fourteenth optical element 391 that is a reflecting mirror for external cavity; twelfth optical element 380a that is a condenser lens; and optical fiber 4. It should be noted that second reflecting mirror 376q, third reflecting mirror 377q, seventh optical element 370q, fourteenth optical element 391, and twelfth optical element 380a, which is the condenser lens, are omitted from FIG. 34.

It should be noted that in the present embodiment, the FAC lenses (e.g., second optical element 320a and fourth optical element 340a), the SAC lenses (e.g., fifth optical element 350 and sixth optical element 360), twelfth optical element 380a, which is the condenser lens, and optical fiber 4 have the same configurations as those described in Embodiment 2. Semiconductor laser modules 100a have the same configuration as that described in Embodiment 2 except for semiconductor laser elements. A semiconductor laser element (e.g., first semiconductor laser element 11) according to the present embodiment differs from the semiconductor laser element according to Embodiment 2 in that an antireflection coating film is formed as an end face coating film on an emission face of the former semiconductor laser element. As a result, the semiconductor laser element according to the present embodiment does not form a resonator between the emission face and a back end face.

In the present embodiment, for purpose of identification, semiconductor laser modules 100a may be referred to, for example, first semiconductor laser module 101a and second semiconductor laser module 102a.

It should be noted that laser beams emitted from respective semiconductor laser modules 100a have different wavelengths. In other words, a first laser beam emitted from first semiconductor laser module 101a has a wavelength different from a wavelength of a second laser beam emitted from second semiconductor laser module 102a, For example, the wavelength of the first laser beam is shorter than the wavelength of the second laser beam.

Unlike Embodiments 1 and 2, semiconductor laser modules 100a are arranged along a circular arc. On the other hand, semiconductor laser modules 100a are disposed on the same plane above a base, not on a base having different heights such as multistep base 5 according to Embodiment 1. For this reason, in the present embodiment, directions in which the first and second laser beams emitted from first and second semiconductor laser modifies 101a and 102a do not coincide with each other. To put it another way, first direction D1 does not coincide with second direction D2, and third optical axis S1 does not coincide with sixth optical axis S2. In contrast, first direction D1 and second direction D2 are in the same plane parallel to third optical axis S1 and sixth optical axis S2.

Case 2q is equivalent to case 2 according to Embodiment 1, Semiconductor laser modules 100a etc. are disposed in case 2q, and case 2q is sealed with a lid (not shown). Case 2q includes base 6q, side wall 3q, and two lids (not shown). Base 6q includes first surface 61q that is plate-shaped and a flat surface, and second surface 62q that is a flat surface on the opposite side of first surface 61q. Side wall 3q is disposed perpendicular to first surface 61q and second surface 62 on the periphery of base 6q so that side wall 3q surrounds the center of base 6q. Above and below side wall 3q, the respective two lids (not shown) are disposed with base 6q being therebetween. In other words, two spaces are formed in case 2q by base 6q, side wall 3q, and the two lids (not shown). In addition, base 6q includes opening 8q in the vicinity of the center. The two spaces of case 2q are spatially connected by opening 8q.

Moreover, electrical terminals such as anode lead pins 931 and cathode lead pins 934, which are lead pins, are formed on side wall 3q on a first surface 61q side of base 6q, and electrically connect the inside and outside. Furthermore, an optical fiber attachment terminal that holds optical fiber 4 is formed on side wall 3q on a second surface 62q side of base 6q, and allows a laser light to pass from the inside to the outside of case 2q.

In light source module 1g, constituent components are distributed to the respective above-described two spaces. Specifically, semiconductor laser modules 100a, the FAC lenses, the SAC lenses, first reflecting mirror 375q, and the electrical terminals are disposed in the space on the first surface 61q side.

In contrast, second reflecting mirror 376q, third reflecting mirror 377q, seventh optical element 370q, which is the diffraction grating, fourteenth optical element 391, twelfth optical element 380a, and optical fiber 4 are disposed in the space on the second surface 62q side of base 6q. Those components except for the electrical terminals and optical fiber 4 fixed to side wall 3q are fixed to base 6q in the respective spaces.

Moreover, anode wiring block 291 and cathode wiring block 294 that supply electric power to semiconductor laser modules 100a are fixed to base 6q in the vicinity of semiconductor laser modules 100a. Anode wiring block 291 and cathode wiring block 294 are each obtained by forming a metal film comprising Ni or Au etc. on the surface of an insulating block comprising alumina ceramic etc. The anode extraction electrode and cathode extraction electrode of each of eighteen semiconductor laser modules 100a arranged in the circular arc are electrically connected in series with the anode extraction electrodes and the anode extraction electrodes on both sides by metal wires etc. The anode extraction electrodes and cathode extraction electrodes of semiconductor laser modules 100a at both ends are electrically connected to anode wiring block 291 and cathode wiring block 294. Anode wiring block 291 and cathode wiring block 294 are electrically connected to anode lead pins 931 and cathode lead pins 934 of case 2q by metal wires, respectively. For example, anode extraction electrode 131 of first semiconductor laser module 101a is electrically connected to anode wiring block 291 by metal wire 194 such as am aluminum ribbon wire. Cathode extraction electrode 134 of first semiconductor laser module 101a is electrically connected to anode extraction electrode 1312 of adjacent second semiconductor laser module 102a by metal wire 193. Cathode extraction electrode 1342 of second semiconductor laser module 102a is electrically connected to the anode extraction electrode of the adjacent third semiconductor laser module by metal wire 1931. As stated above, in light source module 1q, it is possible to supply electric power to the semiconductor laser modules inside using anode lead pins 931 and cathode lead pins 934.

First to third reflecting mirrors 375q, 376q, and 377q reflect the laser beams emitted from respective semiconductor laser modules 100a using the reflecting faces. First to third reflecting mirrors 375q, 376q, and 377q are not a necessary constituent feature as a function of combining laser beams and causing the laser beams to exit optical fiber 4. However, first to third reflecting mirrors 375q, 376q, and 377q are disposed to reflect and deflect laser beams, change the traveling directions of laser beams, and downsize and thin light source module 1q.

In the present embodiment, seventh optical element 370q is the diffraction grating. The laser beams emitted from respective semiconductor laser modules 100a are incident on seventh optical element 370q, and seventh optical element 370q combines the laser beams using wavelength beam combining and sends out the laser beams as laser beams traveling along the same optical axis.

Fourteenth optical element 391 is a half mirror, reflects part of the laser beams emitted from respective semiconductor laser modules 100a, and allows the remaining part of the laser beams to pass. The laser beams reflected by fourteenth optical element 391 are fed back to the luminous points of the semiconductor laser elements of semiconductor laser modules 100a having emitted the laser beams. For example, part of the first laser beam incident on fourteenth optical element 391 exits fourteenth optical element 391, passes through fifth optical element 350 and second optical element 320a, and is incident on first semiconductor laser element 11. For this reason, fourteenth optical element 391 serves as a cavity mirror on an emission side of the semiconductor laser elements. It should be noted that in the present embodiment, fourteenth optical element 391 is disposed on an optical axis between seventh optical element 370q and twelfth optical element 380a.

Twelfth optical element 380a is a condenser lens that condenses laser beams having exited fourteenth optical element 391 to optical fiber 4.

Hereinafter, a configuration of first semiconductor laser module 101a that is one example of semiconductor laser modules 100a will be described with reference to FIG. 35B. It should be noted that, among semiconductor laser modules 100a, the other semiconductor laser modules have the same configuration as first semiconductor laser module 101a. It should be noted that in the present embodiment, semiconductor laser module 100a fixed to module supporting component 163 is also treated as semiconductor laser module unit 1000.

FIG. 35B is a perspective view of a configuration of the surroundings of first semiconductor laser module 101a, Module supporting component 163 is in a rectangular plate shape. Moreover, module supporting component 163 may comprise a material having a high heat conductivity to efficiently radiate heat generated in first semiconductor laser module 101a to case 2q, Module supporting component 163 includes, for example, a Cu plate the surface of which is plated with Ni or Au. Two openings for screwing are provided in the long axis direction of the rectangular plate shape of module supporting component 163. First semiconductor laser module 101a is fixed in a predetermined position of module supporting component 163 with a bonding material such as solder. By using semiconductor laser module unit 1000 including semiconductor laser module 100a fixed with such module supporting component 163, it is possible to easily, for example, screw semiconductor laser module unit 100 to a holding component such as a case.

Furthermore, second optical element 320a and fifth optical element 350 are provided in predetermined positions on one surface of module supporting component 163 on a laser beam emission side of semiconductor laser module 100a. At this time, second optical element 320a is supported by optical supporting component 164, and the position of second optical element 320a is fixed.

### [Behavior of Laser Beam]

Next, laser beams emitted from respective semiconductor laser modules 100a will be described with reference to FIG. 36.

FIG. 36 is a schematic diagram illustrating the optical system of light source module 1q. It should be noted that optical axes (e.g., optical axis A1 and optical axis A2) of respective laser beams are indicated by dashed arrows in FIG. 36.

As shown in FIG. 36, laser beams each having a predetermined wavelength are emitted from semiconductor laser modifies 100a arranged in the circular arc, and travel to first reflecting mirror 375q. First reflecting mirror 375q reflects laser beams collimated by the FAC lenses and the SAC lenses. Second reflecting mirror 376q reflects the laser beams reflected by first reflecting mirror 375q.

Seventh optical element 370q combines the laser beams reflected by second reflecting mirrors 376q and sends laser beams to third reflecting mirror 377q. Third reflecting mirror 377q reflects the laser beams sent from seventh optical element 370q. Fourteenth optical element 391 reflects part of the laser beams reflected by third reflecting mirror 377q, and allows the remaining part of the laser beams to pass. Twelfth optical element 380a condenses the laser beams sent from fourteenth optical element 391 to an incident end face of optical fiber 4. In other words, twelfth optical element 380a condenses the remaining part of the laser beams having passed through fourteenth optical element 391 to the incident end face of optical fiber 4. Optical fiber 4 guides the laser beams incident on the incident end face to the outside of light source module 1q.

The following describes the behavior of seventh optical element 370q, which is the diffraction grating, and the behavior of fourteenth optical element 391, which is the half mirror, in more detail.

First, fourteenth optical element 391 will be described. Laser beams that is part of the laser beams reflected by fourteenth optical element 391 return to respective semiconductor laser modules 100a via third reflecting mirror 377q, seventh optical element 370q, second reflecting mirror 376q, and first reflecting mirror 375q.

At this time, a resonator is formed between fourteenth optical element 391 and a back end face of each of semiconductor laser elements included in respective semiconductor laser modules 100a. To put it another way, in the present embodiment, the semiconductor laser elements included in respective semiconductor laser modules 100a are external cavity laser diodes (ECLDs).

The laser beams emitted from respective semiconductor laser modules 100a are incident on seventh optical element 370q at mutually different incident angles. For this reason, if exit angle αₒ of a laser beam that is a diffracted light beam exiting seventh optical element 370q and traveling to fourteenth optical element 391 is not set to a predetermined angle relative to incident angle αᵢ of a laser beam to seventh optical element 370q (e.g., incident angle αᵢ (1) in first semiconductor laser module 101a), an external cavity laser diode does not oscillate.

In contrast, exit angle αₒ is determined by incident angle αᵢ of each of laser beams and a diffraction grating pitch of the diffraction grating of seventh optical element 370q.

Accordingly, by setting to predetermined values the position and the laser beam emission direction of semiconductor laser module 100a, the position, the orientation, and the diffraction grating pitch of seventh optical element 370q, and the position and the orientation of fourteenth optical element 391 after a laser oscillation wavelength range of the semiconductor laser element constituting the external cavity laser diode, the external cavity laser diode oscillates.

Specifically, with regard to, for example, first semiconductor laser module 101a, an oscillation wavelength according to incident angle αᵢ (1) and exit angle α₀ of a laser beam of first semiconductor laser module 101a is determined by the above-described setting, and the laser beam exits fourteenth optical element 391 and travels to twelfth optical element 380a. It should be noted that a diffraction grating depth or a diffraction grating shape is optimized for the diffraction grating of seventh optical element 370q so that a ratio of the laser beam, which is the diffracted light beam exiting seventh optical element 370q and traveling to fourteenth optical element 391, is sufficiently higher than a ratio of diffracted light beams exiting in other directions.

If the positions and the oscillation wavelength ranges that satisfy the above-described conditions are determined for all semiconductor laser modules 100a in light source module 1q, semiconductor laser modules 100a serve as ECLDs for which respective oscillation wavelengths are determined, and laser beams having same exit angle αₒ and the same optical axis exit seventh optical element 370q.

To summarize the above, light source module 1q according to the present embodiment is capable of causing the optical system to perform wavelength beam combining on the laser beams emitted from respective semiconductor laser modules 100a, and send out the laser beams.

### [Method of Adjusting Positions of FAC Lenses and SAC Lenses]

Next, a method of manufacturing light source module 1q according to the present embodiment will be described with reference to FIG. 34 and FIG. 37A to FIG. 37C, with a focus on a method of adjusting positions of FAC lenses and SAC lenses. Hereinafter, second optical element 320a as an example of the FAC lenses and fifth optical element 350 as an example of the SAC lenses will be described,

FIG. 37A is a perspective view of a state in which first semiconductor laser module 101a according to Embodiment 4 is disposed. FIG. 37B is a perspective view of a state in which semiconductor laser module unit 1000 according to Embodiment 4 is fixed. FIG. 37C is a perspective view for illustrating a method of adjusting positions of second optical element 320a and fifth optical element 350 according to Embodiment 4.

First, as shown in FIG. 37, first semiconductor laser module 101a is fixed in a predetermined position on one surface of module supporting component 163 to manufacture semiconductor laser module unit 1000. At this time, for example, a SnAgCu solder sheet is inserted between module supporting component 163 and first semiconductor laser module 101a, and they are fixed by pressuring and heating.

Next, anode wiring block 291 and cathode wiring block 294 are fixed to base 6q. Then, semiconductor laser module units 1000 are fixed in predetermined positions of case 2q. At this time, screw holes are formed in predetermined positions of first surface 61q of base 6q, and as shown in FIG. 37B, it is possible to fix semiconductor laser module unit 1000 to base 6q with screws 166, As a result, it is possible to easily fix first semiconductor laser modules 101a to case 2q. After that, semiconductor laser modules 100a, anode wiring block 291, cathode wiring block 294, anode extraction electrodes 131, and cathode extraction electrodes 134 are electrically connected with metal wires.

Next, twelfth optical element 380a, fourteenth optical element 391, third reflecting mirror 377q, seventh optical element 370q, and second reflecting mirror 376q are fixed on the second surface 62q side of base 6q with an ultraviolet curable adhesive etc. First reflecting mirror 375q is fixed on the first surface 61q side of base 6q with an ultraviolet curable adhesive etc. Then, optical fiber 4 is attached to make it possible to monitor the amount of laser beams coupled to optical fiber 4 when semiconductor laser modules 100a emit laser beams.

After that, the FAC lenses and the SAC lenses are disposed in predetermined positions on module supporting component 163, and fixed while adjusting the positions of semiconductor laser modules 100a.

Specifically, as shown in FIG. 37C, first, optical supporting component 164 is fixed in a predetermined position on module supporting component 163, Next, second optical element 320a and fifth optical element 350 are disposed on one surface of module supporting component 163. At this time, an ultraviolet curable adhesive prior to curing is disposed between second optical element 320a and optical supporting component 164 and between fifth optical element 350 and module supporting component 163. A semiconductor laser element is caused to emit a laser beam by being supplied with electric power. While the amount of light exiting optical fiber 4 etc. is monitored, the position of second optical element 320a is slightly moved in a direction parallel to optical axis A1 (direction +A or direction −A) or a direction parallel to second optical axis F1 (direction +F or direction −F), and the position of fifth optical element 350 is slightly moved in the direction parallel to optical axis A1 (direction +A or direction −A) or a direction parallel to third optical axis S1 (+S, −S). Second optical element 320a, optical supporting component 164, and fifth optical element 350 are fixed in optimal positions by being irradiated with ultraviolet rays. In other words, as with Embodiment 1, active alignment is performed.

It should be noted that in the present embodiment, anode extraction electrodes 131 and cathode extraction electrodes 134 are formed in semiconductor laser modules 100a on a top surface side (i.e., a side on which the lid is disposed). Accordingly, it is possible to perform active alignment efficiently by causing individual semiconductor laser modules 100a to operate using a probe etc.

### [Advantageous Effects Etc.]

For example, in light source module 1q according to the present embodiment, seventh optical element 370q is a diffraction grating.

In this manner, it is possible to achieve light source module 1q capable of efficiently combining the laser beams emitted from respective semiconductor laser modules 100a.

As stated above, in light source module 1q according to the present embodiment, the first laser beam has a wavelength different from a wavelength of the second laser beam.

In this manner, light source module 1q according to the present embodiment is capable of causing the optical system to combine and send out the laser beams each having a different wavelength emitted from respective semiconductor laser modules 100a. In other words, light source module 1q capable of wavelength beam combining is achieved.

Moreover, for example, light source module 1q according to the present embodiment includes fourteenth optical element 391 on which the first laser beam having passed through second optical element 320a and fifth optical element 350 is incident, Part of the first laser beam incident on fourteenth optical element 391 exits fourteenth optical element 391, passes through fifth optical element 350 and second optical element 320a, and is incident on first semiconductor laser element 11.

In this manner, fourteenth optical element 391 serves as a cavity mirror on an emission side of the semiconductor laser elements. For this reason, it is possible to form a resonator between fourteenth optical element 391 and a back end face of each of semiconductor laser elements included in respective semiconductor laser modules 100a.

Furthermore, for example, in light source module 1q according to the present embodiment, fourteenth optical element 391 is disposed on an optical axis between seventh optical element 370q and twelfth optical element 380a.

In this manner, it is possible to perform oscillation more efficiently between fourteenth optical element 391 and the back end face of each of the semiconductor laser elements. Moreover, by disposing seventh optical element 370q between fourteenth optical element 391 and the back end face of each of the semiconductor laser elements, it is possible to make oscillation wavelengths of the respective semiconductor laser elements appropriate, and perform wavelength beam combining on each of laser beams incident on and exiting seventh optical element 370q. Accordingly, it is possible to cause seventh optical element 370q to perform wavelength beam combining efficiently.

Hereinafter, Variations 1 and 2 of Embodiment 4 will be described. The following mainly describes differences from Embodiment 4, and omits or simplifies description of common points.

### Variation 1 of Embodiment 4

FIG. 38 is a schematic diagram illustrating a configuration of the surroundings of first semiconductor laser module 101a according to Variation 1 of Embodiment 4.

A light source module according to Variation 1 of Embodiment 4 has the same configuration as light source module 1q according to Embodiment 4 except mainly for the following one point. Specifically, the one point is a point that fifth optical element 350 is disposed between second optical element 320a and ninth optical element 319a.

Second optical element 320a is fixed to two optical supporting portions 165 protruding from module supporting component 163, via adhesive 167. Second optical element 320a is sandwiched between two optical supporting portions 165 in the direction along third optical axis S1. This configuration allows second optical element 320a to slightly move in the direction along optical axis A1 (+A, −A) and the direction along second optical axis F1 (+F, −F) before adhesive 167 cures, To put it another way, it is easy to adjust the position of second optical element 320a in the direction along optical axis A1 and the direction along second optical axis F1.

Moreover, as with Embodiment 4, such a configuration makes it possible to achieve a light source module capable of wavelength beam combining in the present variation.

It should be noted that, as with Embodiment 4, second optical element 320a may be disposed between fifth optical element 350 and ninth optical element 319a, and optical supporting portions 165 may be disposed in accordance with second optical element 320a.

### Variation 2 of Embodiment 4

FIG. 39 is a schematic diagram illustrating an optical system of light source module 1r according to Variation 2 of Embodiment 4. FIG. 40 is a perspective view of a configuration of the surroundings of first semiconductor laser module 101a according to Variation 2 of Embodiment 4.

Light source module 1r has the same configuration as light source module 1q according to Embodiment 4 except mainly for the following three points. Specifically, the three points are a point that laser beam splitter element 210 that is a diffraction grating for wavelength selection is disposed, for each of semiconductor laser modules 100a, between fifth optical element 350 and first reflecting mirror 375q, a point that fourteenth optical element 391 is disposed for each laser beam splitter element 210, and a point that seventh optical element 370r is a reflective diffraction grating.

In the present variation, each of laser beam splitter elements 210 is disposed between the SAC lenses and first reflecting mirror 375q. Fourteenth optical element 391 that serves as a cavity mirror on an emission side of a semiconductor laser element is disposed in the vicinity of laser beam splitter element 210 to face laser beam splitter element 210. Moreover, as shown in FIG. 40, laser beam splitter element 210 and fourteenth optical element 391 are fixed to module supporting component 163 on which semiconductor laser module 100a is mounted, which constitutes semiconductor laser module unit 1000. At this time, actuator 211 that is a rotary motor is fixed to module supporting component 163, and laser beam splitter element 210 is fixed to the rotation axis of actuator 211.

Laser beam splitter elements 210 are each an optical component that splits a first laser beam on the first optical axis (optical axis A1). Laser beam splitter elements 210 are each, for example, a diffraction grating having a predetermined diffraction grating pitch. For example, as shown in FIG. 40, part of first laser beam L15 incident on laser beam splitter element 210 travels as diffracted light beam L151 to fourteenth optical element 391 in accordance with a diffraction grating pitch and an incident angle of the first laser beam. In other words, a first laser beam split by laser beam splitter element 210 is incident on fourteenth optical element 391. A laser beam reflected by fourteenth optical element 391 is fed back to a luminous point of a semiconductor laser element of semiconductor laser module 100a having emitted a laser beam.

In the present variation, semiconductor laser elements form resonators between respective fourteenth optical elements 391 and respective back end faces of the semiconductor laser elements. To put it another way, in the present variation, the semiconductor laser elements form ECLDs with fourteenth optical elements 391.

A wavelength of a laser beam emitted from the above-described semiconductor laser element is determined by a diffraction grating pitch of laser beam splitter element 210 and an incident angle of the laser beam. In the meantime, laser beam splitter element 210 is fixed to the rotation axis of actuator 211 that rotates laser beam splitter element 210. Accordingly, by rotating actuators 211 at respective predetermined angles, it is possible to change incident angles of laser beams and adjust oscillation wavelengths of laser beams emitted from semiconductor laser modules 100a.

As stated above, most of each of the laser beams the oscillation wavelengths of which are determined and that are emitted from semiconductor laser modules 100a passes through laser beam splitter element 210 and travels to first reflecting mirror 375q. Subsequently, the laser beams are reflected by second reflecting mirror 376q and converged to a predetermined position of seventh optical element 370r.

Seventh optical element 370r reflects and combines the laser beams emitted from respective semiconductor laser modules 100a, With regard to the reflective diffraction grating, as described in Embodiment 4, exit angle βₒ of a laser beam that is an exiting diffracted light beam is determined by incident angle βᵢ of a laser beam incident on seventh optical element 370r (e.g., incident angle βᵢ (1) for first semiconductor laser module 101a), a diffraction grating pitch, and a wavelength. Accordingly, it is necessary to determine wavelengths of incident laser beams in accordance with the positions of semiconductor laser modules 100a and the directions of the emitted laser beams so that laser beams having exited seventh optical element 370r are combined, that is, the emission directions of the respective laser beams are made to coincide with each other.

Semiconductor laser modules 100a or semiconductor laser module units 1000 according to the present variation are capable of determining in advance wavelengths of laser beams to be emitted, Specifically, by, for example, rotary driving actuators 211, it is possible to control wavelengths of respective laser beams passing through laser beam splitter elements 210. For this reason, it is possible to cause the emission directions of the respective laser beams to coincide with each other by determining incident angle βᵢ to seventh optical element 370r based on the positions of respective semiconductor laser modules 100a and controlling the wavelengths of the respective laser beams.

Moreover, in the above-described configuration, the FAC lenses and the SAC lenses are provided outside semiconductor laser modules 100a. Consequently, it is possible to adjust wavelengths of laser beams emitted from semiconductor laser modifies 100a while adjusting traveling directions of the laser beams. Even if the FAC lenses and the SAC lenses that adjust the wavelengths and traveling directions of the emitted laser beams, laser beam splitter elements 210, and fourteenth optical elements 391 are fixed using a resin such as an ultraviolet curable adhesive, it is possible to inhibit the deterioration of the semiconductor laser elements due to the attachment of foreign objects etc. thereto since the semiconductor laser elements are hermetically sealed inside semiconductor laser modules 100a.

To summarize the above, as with Embodiment 4, such a configuration makes it possible to achieve light source module 1r capable of wavelength beam combining in the present variation.

### Embodiment 5

Next, Embodiment 5 will be described. The following mainly describes differences from Embodiment 2, and omits or simplifies description of common points,

FIG. 41 is a perspective view of a configuration of light source module 1s according to Embodiment 5.

It should be noted that, for simplicity, FIG. 41 does not illustrate frame 171 etc. described in Embodiment 2. In addition, semiconductor laser module 21s is indicated by a broken line in FIG. 41.

Light source module 1s has the same configuration as light source module 1a according to Embodiment 2 except mainly for the following one point. Specifically, the one point is a point that semiconductor laser elements are hermetically sealed by semiconductor laser module 21s.

In the present embodiment, multistep base 5b is provided to base 6.

Seventh optical element 370 that includes reflecting mirrors, FAG lenses each including a concave cylindrical face (e.g., second and fourth optical elements 320a and 340a), and SAC lenses each including a convex cylindrical face (e.g., fifth and sixth optical elements 350 and 360) are provided to multistep base 5b.

Multistep base 5a is hermetically sealed in semiconductor laser module 21s, A semiconductor laser element (e.g., first semiconductor laser element 11 or second semiconductor laser element 12) and eighth optical element 318a or tenth optical element 338 are provided to each step of multistep base 5a.

Ninth optical element 319a that is part of first optical element 310a and eleventh optical element 339a that is part of third optical element 330a constitute a light-transmissive window of semiconductor laser module 21s.

In other words, in the present embodiment, first semiconductor laser element 11, second semiconductor laser element 12, ninth optical element 319a, which is the part of first optical element 310a, and eleventh optical element 339a, which is the part of third optical element 330a, are hermetically sealed by semiconductor laser module 21s, ninth optical element 319a, which is the part of first optical element 310a, and eleventh optical element 339a, which is the part of third optical element 330a.

As with Embodiment 1, such a configuration makes it possible to achieve compact light source module 1s that inhibits the deterioration of first semiconductor laser element 11 and second semiconductor laser element 12 and has high laser beam coupling efficiency in seventh optical element 370.

### Variation 1 of Embodiment 5

Hereinafter, Variation 1 of Embodiment 5 will be described, FIG. 42 is a perspective view of a configuration of light source module 1t.

Light source module 1t has the same configuration as light source module 1s according to Embodiment 5 except mainly for the following one point, Specifically, the one point is a point that second optical element 320 and fourth optical element 340 that are FAC lenses are each a lens including a convex cylindrical face.

As with Embodiment 5, such a configuration makes it possible to achieve compact light source module 1t that inhibits the deterioration of first semiconductor laser element 11 and second semiconductor laser element 12 and has high laser beam coupling efficiency in an object.

### Embodiment 6

Next, Embodiment 6 will be described.

### [Configuration]

The following describes a configuration of a first semiconductor laser module included in a light source module according to Embodiment 6 with reference to FIG. 43,

FIG. 43 is a perspective view of a configuration of first semiconductor laser module 101u according to Embodiment 6. It should be noted that optical axes of laser beams are indicated by broken lines in FIG. 43.

The light source module according to Embodiment 6 has the same configuration as the light source module according to Variation 1 of Embodiment 2 except mainly for the following one point. Specifically, the one point is a point that semiconductor laser elements are hermetically sealed by first package 21u etc. of first semiconductor laser module 101u.

As shown in FIG. 43, first, second, and third semiconductor laser elements 11, 12, and 13 as examples of the semiconductor laser elements are hermetically sealed by first package 21u, and light-transmissive window 317, ninth optical element 319b, and eleventh optical element 339b that are integrally formed, and a lid (not shown). The semiconductor laser elements are arranged at predetermined intervals in a direction perpendicular to a direction in which laser beams are emitted.

Eighth optical element 318a that is part of first optical element 310b and ninth optical element 319b that is part of first optical element 310b are provided in a direction in which first, second, and third laser beams are emitted from first, second, and third semiconductor laser elements 11, 12, and 13. It should be noted that in the present embodiment, light-transmissive window 317, ninth optical element 319b, and eleventh optical element 339b are integrally formed, and eighth optical element 318a and tenth optical element 338a are integrally formed.

In the aforementioned embodiments, for example, in Embodiment 5, first optical element 310a is an optical component corresponding to first semiconductor laser element 11, and third optical element 330a is an optical component corresponding to second semiconductor laser element 12. In the present embodiment, however, first optical element 310b and third optical element 330b that are integrally formed are an optical component corresponding to first and second semiconductor laser elements 11 and 12, First optical element 310b and third optical element 330b that are integrally formed are an optical component having power along second optical axis F1 greater than power along third optical axis S1. As an example, eighth optical element 318b and tenth optical element 338b that constitute first optical element 310b and are integrally formed are a cylindrical lens having a power axis and a non-power axis. More specifically, eighth optical element 318b and tenth optical element 338b that are integrally formed are a cylindrical lens obtained by causing a length of eighth optical element 318a according to Variation 1 of Embodiment 2 in a direction along the non-power axis to be greater than an interval between the semiconductor laser elements. Moreover, ninth optical element 319b and eleventh optical element 339b that are integrally formed are also a cylindrical lens having a power axis and a non-power axis. More specifically, ninth optical element 319b and eleventh optical element 339b that are integrally formed are a cylindrical lens obtained by causing a length of ninth optical element 319a according to Variation 1 of Embodiment 2 in a direction along the non-power axis to be greater than an interval between the semiconductor laser elements. Such a configuration makes it possible to easily achieve first semiconductor laser module 101u including the semiconductor laser elements.

In the present embodiment, first, second, and third semiconductor laser elements 11, 12, and 13 are separately formed, separately mounted on one submount 50, and are what is called a hybrid array laser element. First semiconductor laser element 11 and second semiconductor laser element 12 are disposed so that second optical axis F1 of first laser beam L11 emitted from first semiconductor laser element 11 and fifth optical axis F2 of second laser beam L21 emitted from second semiconductor laser element 12 are parallel to the power axis of eighth optical element 318b and tenth optical element 338b. First optical element 310b reduces a first divergence angle of first laser beam L11 in the direction along second optical axis F1. Likewise, first optical element 310b reduces a fourth divergence angle of second laser beam L21 in the direction along fifth optical axis F2. In this case, however, positions of luminous points and laser beam emission directions of the semiconductor laser elements depend on mounting accuracy to submount 50. For example, if the mounting accuracy to submount 50 varies, the positions of the luminous points of the semiconductor laser elements also vary. For this reason, it is difficult to cause the directions in which the laser beams are emitted from the respective semiconductor laser elements to completely coincide with each other in a predetermined manner. Consequently, it is necessary to adjust each of the laser beams in order to cause the directions in which the laser beams are emitted from the respective semiconductor laser elements to completely coincide with each other.

In the light source module including first semiconductor laser module 101u, FAC lenses (e.g., second and fourth optical elements 320a and 340a) and SAC lenses (e.g., fifth and sixth optical elements 350 and 360) are disposed in positions that are outside first semiconductor laser module 101u and in emission directions of laser beams from first semiconductor laser module 101u. Even in such a case, it is easy to adjust the positions of the FAC lenses and the SAC lenses. Accordingly, since it is possible to separately adjust the divergence angles and traveling directions of the first, second, and third laser beams, it is possible to cause the first, second, and third laser beams to be incident on an object with high coupling efficiency.

In the present embodiment, electrical wiring is made easy even if the hybrid laser array element is disposed in first package 21u. Specifically, first metal film 137, second metal film 138, third metal film 1381, and fourth metal film 1382 that are insulated from each other are formed on submount 50. First semiconductor laser element 11 is mounted on first metal film 137 via a bonding material, second semiconductor laser element 12 is mounted on second metal film 138 via a bonding material, and third semiconductor laser element 13 is mounted on third metal film 1381 via a bonding material. The semiconductor laser elements are electrically connected in series with metal wires 190, 1901, 1902, 191, and 192, and metal wires 190p are connected to anode electrode 132 and cathode electrode 135. This configuration makes it possible to supply electric power to the hermetically sealed semiconductor laser elements using anode extraction electrode 131 and cathode extraction electrode 134 that are disposed outside.

### [Method of Manufacturing Semiconductor Laser Module]

Hereinafter, a method of manufacturing first semiconductor laser module 101u will be described with reference to FIG. 44,

FIG. 44 is a schematic diagram illustrating the method of manufacturing first semiconductor laser module 101u according to Embodiment 6.

First, first, second, and third semiconductor laser elements 11, 12, and 13 are mounted above submount 50 and connected with metal wires. Next, submount 50 on which first, second, and third semiconductor laser elements 11, 12, and 13 are mounted is disposed inside one first package 21u.

Then, eighth optical element 318a is fixed using first supporting component 161 so that eighth optical element 318a has a predetermined height and distance relative to first, second, and third semiconductor laser elements 11, 12, and 13. After that, ninth optical element 319b is fixed to cover opening 170 of one first package 21u. Finally, submount 50, anode electrode 132, and cathode electrode 135 are connected with metal wires not shown, and sealing is performed using a lid not shown.

Such a configuration and a method of manufacturing cause first, second, and third semiconductor laser elements 11, 12, and 13 to be hermetically sealed in one first package 21u.

### [Advantageous Effects Etc.]

As stated above, in the light source module according to the present embodiment, first optical element 310b and third optical element 330b are integrally formed.

In this manner, it is possible to decrease the number of components constituting first semiconductor laser module 101u.

Moreover, for example, in the light source module according to the present embodiment, first semiconductor laser element 11 and second semiconductor laser element 12 are provided separately.

In other words, a hybrid array laser element is achieved in the present embodiment, Even in such a case, it is easy to adjust the positions of the FAC lenses (e.g., second and fourth optical elements 320a and 340a) and the SAC lenses (e.g., fifth and sixth optical elements 350 and 360). As a result, the first, second, and third laser beams are incident on an object with high coupling efficiency.

### Embodiment 7

Next, Embodiment 7 will be described.

FIG. 45 is a perspective view of a configuration of first semiconductor laser module 101v according to Embodiment 7.

First semiconductor laser module 101v has the same configuration as the light source module according to Variation 2 of Embodiment 2 except mainly for the following two points. Specifically, the two points are a point that a lens array optical element is used as ninth optical element 319v and eleventh optical element 339v that are integrally formed, and a point that semiconductor laser array element 10v is obtained by forming first semiconductor laser element 11 and second semiconductor laser element 12 on the same semiconductor substrate.

Semiconductor laser array element 10v includes optical waveguides 61 formed on a common semiconductor substrate. Each of optical waveguides 61 is equivalent to a semiconductor laser element. As shown in FIG. 45, semiconductor laser array element 10v includes, for example, three optical waveguides 61 provided in a stripe shape. Three optical waveguides 61 are equivalent to first semiconductor laser element 11, second semiconductor laser element 12, and third semiconductor laser element 13, and each emit a laser beam. Since optical waveguides 61 are formed on the common semiconductor substrate, it is possible to reduce the intervals between optical waveguides 61 (e.g., from 100 μm to 1000 μm). As a result, it is possible to increase a number density of laser beams. In addition, since optical waveguides 61 are formed on the common semiconductor substrate by photolithography etc., it is possible to accurately conform the intervals between optical waveguides 61 formed on the common semiconductor substrate with each other, and to cause laser beam emission directions to accurately coincide with each other.

In the present embodiment, ninth optical element 319v and eleventh optical element 339v are integrally formed, and eighth optical element 318a and tenth optical element 338a are integrally formed. Likewise, second optical element 320a and fourth optical element 340a are integrally formed, and fifth optical element 350v and sixth optical element 360v are integrally formed.

For this reason, first and third optical elements 310v and 330v are disposed to correspond to the laser beams emitted from first semiconductor laser element 11, second semiconductor laser element 12, and third semiconductor laser element 13, In other words, first optical element 310v and third optical element 330v integrally formed are used to correspond to first semiconductor laser element 11 and second semiconductor laser element 12. Similarly, second optical element 320a and fourth optical element 340a integrally formed and fifth optical element 350v and sixth optical element 360v integrally formed are used for first semiconductor laser element 11 and second semiconductor laser element 12.

Second optical element 320a and fourth optical element 340a integrally formed have the same configuration as second optical element 320a according to Embodiment 2.

First and third optical elements 310v and 330v are each an optical component having power along second optical axis F1 greater than power along third optical axis S1. As an example, first optical element 310v and third optical element 330v that are integrally formed are a cylindrical lens having a power axis and a non-power axis.

Ninth optical element 9v and eleventh optical element 339v integrally formed are a lens array optical element. As with the lens array element according to Variation 2 of Embodiment 3, ninth optical element 319v and eleventh optical element 339v integrally formed include lenses each including a convex face. It should be noted that the convex faces of the lenses are located on a light-transmissive window 317 side of the lenses. The lenses serve as FA lenses. By using such first and third optical elements 310v and 330v for the semiconductor laser array element including the optical waveguides formed on the common semiconductor substrate, it is possible to reduce a divergence angle of first laser beam L11 in the direction along second optical axis F1, and a divergence angle of second laser beam L12 in the direction along fifth optical axis F2.

Moreover, fifth optical element 350v and sixth optical element 360v integrally formed are a lens array including (here three) convex faces to correspond to the laser beams emitted from the semiconductor laser elements.

In FIG. 45, second optical element 320a and fourth optical element 340a integrally formed and fifth optical element 350v and sixth optical element 360v integrally formed are disposed in an emission direction of first semiconductor laser module 101v. It is possible to use first semiconductor laser modules 101v for one light source module. In this case, second optical element 320a and fourth optical element 340a integrally formed and fifth optical element 350v and sixth optical element 360v integrally formed are disposed to correspond to respective laser beam emission directions of first semiconductor laser modules 101v. In the case of this light source module, positions of luminous points and laser beam emission directions between respective semiconductor laser elements mounted on different first semiconductor laser modules 101v depend on mounting accuracy of first semiconductor laser modules 101v on the light source module. For example, if the mounting accuracy of first semiconductor laser modules 101v varies, a position of a luminous point and a laser beam emission direction of a semiconductor laser element also vary with respect to positions of luminous points and laser beam emission directions of other semiconductor laser elements. For this reason, it is difficult to cause an emission direction of a laser beam from a semiconductor laser element to completely coincide with emission directions of laser beams from other semiconductor laser elements in a predetermined manner. Accordingly, by adjusting, for each first semiconductor laser module 101v, second optical element 320a and fourth optical element 340a integrally formed and fifth optical element 350v and sixth optical element 360v integrally formed, it is possible to cause a direction in which first semiconductor laser module 101v emits a laser beam to coincide with directions in which other first semiconductor laser modifies 101v emit laser beams.

### Embodiment 8

Next, Embodiment 8 will be described. The following describes a configuration of a first semiconductor laser module included in a light source module according to Embodiment 8 with reference to FIG. 46 and FIG. 47.

FIG. 46 is a perspective view of a configuration of first semiconductor laser module 101w according to Embodiment 8. FIG. 47 is a schematic diagram illustrating an optical system of light source module 1w according to Embodiment 8.

First semiconductor laser module 101w has the same configuration as first semiconductor laser module 101v according to Embodiment 7 except mainly for the following one point.

Specifically, the one point is a point that fifteenth optical element 392 that is a beam twister element is disposed between first optical element 310w and light-transmissive window 317.

Moreover, light source module 1w has the same configuration as light source module 1q according to Embodiment 4 except mainly for the following one point, Specifically, the one point is a point that first semiconductor laser element 11w emits first laser beams.

It should be noted that light source module 1w according to the present embodiment includes semiconductor laser modifies 100w, Semiconductor laser modifies 100w according to the present embodiment other than first semiconductor laser module 101w have the same configuration as first semiconductor laser module 101w. In addition, laser beams emitted from respective semiconductor laser modules 100w have different wavelengths.

First semiconductor laser element 11w according to the present embodiment includes optical waveguides 61 as with Embodiment 7, and emits a first laser beam through each of optical waveguides 61.

First optical element 10w, fifteenth optical element 392, and light-transmissive window 317 are sequentially disposed in the emission direction of first semiconductor laser element 11w.

Fifteenth optical element 392 includes a beam twister element. More specifically, fifteenth optical element 392 is a cylindrical lens array element. Fifteenth optical element 392 has a structure in which a power axis of a cylindrical lens is inclined at 45° from a fast axis.

As a result, the first laser beams emitted from first semiconductor laser element 11w rotate by 90° about a first optical axis (optical axis A1). In other words, fifteenth optical element 392 rotates by 90° the fast axes and the slow axes of the first laser beams emitted from first semiconductor laser element 11w. Accordingly, although the fast axes and the slow axes of the first laser beams having been just emitted from first semiconductor laser element 11w are parallel to the x direction and the y direction, respectively, the fast axes and the slow axes of the first laser beams having just passed through the beam twister element become parallel to the ξ direction and the η direction, respectively.

Moreover, fifth optical element 350 and second optical element 320w are used in the present embodiment. As stated above, since the directions along the fast axes and the slow axes are interchanged with each other, fifth optical element 350 and second optical element 320w serve as a SAC lens and a FAC lens, respectively. Second optical element 320w is a lens array including (three) cylindrical convex faces. Fifth optical element 350 is a lens including a cylindrical convex face.

As shown in FIG. 47, as with Embodiment 4, in light source module 1w, semiconductor laser modifies 100w including first semiconductor laser module 101w and second semiconductor laser module 102w are arranged in a circular arc.

The above-described configuration is expected to produce the same advantageous effects as Embodiment 4.

Additionally, since first semiconductor laser element 11w according to the present embodiment emits laser beams, the light source module according to the present embodiment is capable of increasing a light density of the laser beams.

### Embodiment 9

Next, Embodiment 9 will be described. The following describes a configuration of a first semiconductor laser module included in a light source module according to Embodiment 9 with reference to FIG. 48.

FIG. 48 is a perspective view of a configuration of first semiconductor laser module 101x according to Embodiment 9.

First semiconductor laser module 101x according to Embodiment 9 has the same configuration as first semiconductor laser module 101w according to Embodiment 8 except mainly for the following four points. Specifically, the four points are a point that semiconductor laser array element 10x including first, second, and third semiconductor laser elements is provided, a point that first optical element 310x and third optical element 330x are integrally formed, a point that second optical element 320x and fourth optical element 340x are integrally formed, and a point that fifth optical element 350x and sixth optical element 360x are integrally formed.

It should be noted that first optical element 310x and third optical element 330x integrally formed have the same configuration as first optical element 310w according to Embodiment 8, Second optical element 320x and fourth optical element 340x integrally formed have the same configuration as second optical element 320w according to Embodiment 8. Fifth optical element 350x and sixth optical element 360x integrally formed have the same configuration as fifth optical element 350 according to Embodiment 8.

The above-described configuration is expected to produce the same advantageous effects as Embodiment 4.

### OTHER EMBODIMENTS

Although the light source modifies according to the present disclosure have been described based on the embodiments and variations above, the present disclosure is not limited to the embodiments and variations. Forms obtained by various modifications to the respective embodiments that can be conceived by a person skilled in the art as well as forms realized by combining some constituent elements in the respective embodiments and variations are included in the scope of the present disclosure as long as they do not depart from the essence of the present disclosure.

Moreover, various modifications, replacements, additions, omissions, etc. can be carried out for the aforementioned embodiments within the scope of the claims or equivalents thereof.

It should be noted that with regard to the lenses each including the convex or concave cylindrical face, although a convex face or a concave face may be a true cylindrical face, the convex face or the concave face may be in a shape slightly different from a true cylindrical shape. By causing the shape to be slightly different from the true cylindrical shape, it is possible to reduce an aberration.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

According to the present disclosure, it is possible to provide a compact light source module that inhibits the deterioration of semiconductor laser elements and has high laser beam coupling efficiency in an object.

1. A light source module comprising:
a first semiconductor laser module including a first semiconductor laser element hermetically sealed and a first optical element on which a first laser beam emitted from the first semiconductor laser element is incident;
a second optical element on which the first laser beam having passed through the first optical element is incident;
a second semiconductor laser module including a second semiconductor laser element hermetically sealed and a third optical element on which a second laser beam emitted from the second semiconductor laser element is incident; and
a fourth optical element on which the second laser beam having passed through the third optical element is incident,
wherein the first laser beam having passed through the second optical element and the second laser beam having passed through the fourth optical element are combined,
a traveling direction of the first laser beam along a first optical axis is defined as a first direction, the first optical axis being an optical axis from the first semiconductor laser element to the second optical element,
the first laser light has a second optical axis perpendicular to the first direction, and a third optical axis perpendicular to the first direction and the second optical axis,
the first optical element has power along the second optical axis greater than power along the third optical axis,
the first laser beam prior to reaching the first optical element has a first divergence angle θfd1 and a second divergence angle θsd1, the first divergence angle θfd1 being a divergence angle in a direction along the second optical axis, the second divergence angle θsd1 being a divergence angle in a direction along the third optical axis,
the first divergence angle θfd1 and the second divergence angle θsd1 satisfy 90°>θfd1>θsd1>0,
a third divergence angle θfd12 decreases from the first divergence angle θfd1, the third divergence angle θfd12 being a divergence angle of the first laser beam exiting the first optical element in the direction along the second optical axis,
the first laser beam is collimated in the direction along the second optical axis after the first laser beam exits the second optical element,
a traveling direction of the second laser beam along a fourth optical axis is defined as a second direction, the fourth optical axis being an optical axis from the second semiconductor laser element to the fourth optical element,
the second laser beam has a fifth optical axis perpendicular to the second direction, and a sixth optical axis perpendicular to the second direction and the fifth optical axis,
the third optical element has power along the fifth optical axis greater than power along the sixth optical axis,
the second laser beam prior to reaching the third optical element has a fourth divergence angle θfd2 and a fifth divergence angle θsd2, the fourth divergence angle θfd2 being a divergence angle in a direction along the fifth optical axis, the fifth divergence angle θsd2 being a divergence angle in a direction along the sixth optical axis,
the fourth divergence angle θfd2 and the fifth divergence angle θsd2 satisfy 90°>θfd2>θsd2>0,
a sixth divergence angle θfd22 decreases from the fourth divergence angle θfd2, the sixth divergence angle θfd22 being a divergence angle of the second laser beam exiting the third optical element in the direction along the fifth optical axis, and
the second laser beam is collimated in the direction along the fifth optical axis after the second laser beam exits the fourth optical element.

2. The light source module according to claim 1,
wherein with regard to the first laser beam and the second laser beam combined,
the first direction coincides with the second direction, and
the second optical axis coincides with the fifth optical axis.

3. The light source module according to claim 1,
wherein the first semiconductor laser module includes:
a light-transmissive window through which the first laser beam passes to an outside of the first semiconductor laser module;
a package including a plate-shaped bottom and a frame body in a center of which a first opening is provided; and
a lid,
the first semiconductor laser element is disposed in the first opening,
the lid covers an upper portion of the first opening, and
the first semiconductor laser element is hermetically sealed by the light-transmissive window, the package, and the lid.

4. The light source module according to claim 1,
wherein the first semiconductor laser module and the second semiconductor laser module are disposed next to each other in the direction along the third optical axis.

5. The light source module according to claim 1,
wherein the first semiconductor laser module includes a cathode extraction electrode,
the second semiconductor laser module includes an anode extraction electrode, and
the cathode extraction electrode of the first semiconductor laser module and the anode extraction electrode of the second semiconductor laser module are electrically connected by a metal wire.

6. The light source module according to claim 1,
wherein at least a portion of the first optical element and at least a portion of the third optical element are each fixed by a bonding material comprising an inorganic material.

7. A light source module comprising:
a semiconductor laser module including a first semiconductor laser element hermetically sealed, a second semiconductor laser element hermetically sealed, a first optical element on which a first laser beam emitted from the first semiconductor laser element is incident, and a third optical element on which second laser beam emitted from the second semiconductor laser element is incident;
a second optical element on which the first laser beam having passed through the first optical element is incident; and
a fourth optical element on which the second laser beam having passed through the third optical element is incident,
wherein the first laser beam having passed through the second optical element and the second laser beam having passed through the fourth optical element are combined,
a traveling direction of the first laser beam along a first optical axis is defined as a first direction, the first optical axis being an optical axis from the first semiconductor laser element to the second optical element,
the first laser beam has a second optical axis perpendicular to the first direction, and a third optical axis perpendicular to the first direction and the second optical axis,
the first optical element has power along the second optical axis greater than power along the third optical axis,
the first laser beam prior to reaching the first optical element has a first divergence angle θfd1 and a second divergence angle θsd1, the first divergence angle θfd1 being a divergence angle in a direction along the second optical axis, the second divergence angle θsd1 being a divergence angle in a direction along the third optical axis,
the first divergence angle θfd1 and the second divergence angle θsd1 satisfy 90°>θfd1>θsd1>0,
a third divergence angle θfd12 decreases from the first divergence angle θfd1, the third divergence angle θfd12 being a divergence angle of the first laser beam exiting the first optical element in the direction along the second optical axis,
the first laser beam is collimated in the direction along the second optical axis after the first laser beam exits the second optical element,
a traveling direction of the second laser beam along a fourth optical axis is defined as a second direction, the fourth optical axis being an optical axis from the second semiconductor laser element to the fourth optical element,
the second laser beam has a fifth optical axis perpendicular to the second direction, and a sixth optical axis perpendicular to the second direction and the fifth optical axis,
the third optical element has power along the fifth optical axis greater than power along the sixth optical axis,
the second laser beam prior to reaching the third optical element has a fourth divergence angle θfd2 and a fifth divergence angle θsd2, the fourth divergence angle θfd2 being a divergence angle in a direction along the fifth optical axis, the fifth divergence angle θsd2 being a divergence angle in a direction along the sixth optical axis,
the fourth divergence angle θfd2 and the fifth divergence angle θsd2 satisfy 90°>θfd2>θsd2>0,
a sixth divergence angle θfd22 decreases from the fourth divergence angle θfd2, the sixth divergence angle θfd22 being a divergence angle of the second laser beam exiting the third optical element in the direction along the fifth optical axis, and
the second laser beam is collimated in the direction along the fifth optical axis after the second laser beam exits the fourth optical element.

8. The light source module according to claim 7,
wherein the first optical element and the third optical element are provided integrally.

9. The light source module according to claim 7,
wherein the first semiconductor laser element and the second semiconductor laser element are provided separately.

10. The light source module according to claim 1,
wherein the first laser beam having passed through the first optical element converges in the direction along the second optical axis toward the second optical element, and
the second laser beam having passed through the third optical element converges in the direction along the fifth optical axis toward the fourth optical element.

11. The light source module according to claim 10,
wherein the third divergence angle θfd12 of the first laser beam having passed through the first optical element satisfies θfc1=−θfd12>0 as a first convergence angle θfc1,
the sixth divergence angle θfd22 of the second laser beam having passed through the third optical element satisfies θfc2=−θfd22>0 as a second convergence angle θfc2, and
the first divergence angle θfd1, the first convergence angle θfc1, the fourth divergence angle θfd2, and the second convergence angle θfc2 satisfy θfd1>θfc1>0 and θfd2>θfc2>0.

12. The light source module according to claim 10,
wherein the second optical element is a lens that has a first power axis and a first non-power axis perpendicular to the first power axis, and includes a concave cylindrical face along the first power axis,
the first power axis is parallel to the second optical axis,
the fourth optical element is a lens that has a second power axis and a second non-power axis perpendicular to the second power axis, and includes a concave cylindrical face along the second power axis, and
the second power axis is parallel to the fifth optical axis.

13. The light source module according to claim 1,
wherein the second optical element is a lens that has a first power axis and a first non-power axis perpendicular to the first power axis, and includes a convex cylindrical face along the first power axis,
the first power axis is parallel to the second optical axis,
the fourth optical element is a lens that has a second power axis and a second non-power axis perpendicular to the second power axis, and includes a convex cylindrical face along the second power axis, and
the second power axis is parallel to the fifth optical axis.

14. The light source module according to claim 1, further comprising:
a fifth optical element on which the first laser beam having passed through the first optical element is incident; and
a sixth optical element on which the second laser beam having passed through the third optical element is incident,
wherein the first laser beam is collimated in the direction along the third optical axis after the first laser beam passes through the fifth optical element,
the second laser beam is collimated in the direction along the sixth optical axis after the second laser beam passes through the sixth optical element, and
the first laser beam having passed through the fifth optical element and the second laser beam having passed through the sixth optical element are incident on an object.

15. The light source module according to claim 1,
wherein the first optical element includes a lens that has a third power axis and a third non-power axis perpendicular to the third power axis, and includes a convex or concave cylindrical face along the third power axis,
the third power axis is parallel to the second optical axis,
the third optical element includes a lens that has a fourth power axis and a fourth non-power axis perpendicular to the fourth power axis, and includes a convex cylindrical face or a concave cylindrical face along the fourth power axis, and
the fourth power axis is parallel to the fifth optical axis.

16. The light source module according to claim 1,
wherein the first optical element includes at least an eighth optical element and a ninth optical element, and
the third optical element includes at least a tenth optical element and an eleventh optical element.

17. The light source module according to claim 1,
wherein the first laser beam has a wavelength different from a wavelength of the second laser beam.

18. The light source module according to claim 1, further comprising:
a thirteenth optical element between the first semiconductor laser element and the first optical element,
wherein the thirteenth optical element is an upward-reflecting mirror.

19. The light source module according to claim 1,
wherein the first semiconductor laser element is a nitride-based semiconductor laser element, and
the second semiconductor laser element is a nitride-based semiconductor laser element.

20. The light source module according to claim 1,
wherein the first semiconductor laser element emits laser beams, and
the second semiconductor laser element emits laser beams.

21. A light source module comprising:
a first semiconductor laser module including a first semiconductor laser element hermetically sealed;
a first optical element included in the first semiconductor laser module or a second optical element provided outside the first semiconductor laser module, the first optical element and the second optical element being each an optical element on which a first laser beam emitted from the first semiconductor laser element is incident;
a fifth optical element on which the first laser beam having passed through the first optical element or the second optical element is incident;
a reflecting mirror that reflects the first laser beam having passed through the fifth optical element;
a second semiconductor laser module including a second semiconductor laser element hermetically sealed;
a third optical element included in the second semiconductor laser module or a fourth optical element provided outside the second semiconductor laser module, the third optical element and the fourth optical element being each an optical element on which a second laser beam emitted from the second semiconductor laser element is incident;
a sixth optical element on which the second laser beam having passed through the third optical element or the fourth optical element is incident;
an other reflecting mirror that is different from the reflecting mirror and reflects the second laser beam having passed through the sixth optical element;
a base; and
a multistep base that is provided above a top surface of the base and includes steps that are stair-like and have different heights from the top surface of the base,
wherein a traveling direction of the first laser beam along a first optical axis is defined as a first direction, the first optical axis being an optical axis from the first semiconductor laser element to the fifth optical element,
the first laser beam has a second optical axis perpendicular to the first direction, and a third optical axis perpendicular to the first direction and the second optical axis,
the first optical element or the second optical element has power along the second optical axis greater than power along the third optical axis,
the fifth optical element has power along the third optical axis greater than power along the second optical axis,
a traveling direction of the second laser beam along a fourth optical axis is defined as a second direction, the fourth optical axis being an optical axis from the second semiconductor laser element to the sixth optical element,
the second laser beam has a fifth optical axis perpendicular to the second direction, and a sixth optical axis perpendicular to the second direction and the fifth optical axis,
the third optical element or the fourth optical element has power along the fifth optical axis greater than power along the sixth optical axis,
the sixth optical element has power along the sixth optical axis greater than power along the fifth optical axis,
the first laser beam reflected by the reflecting mirror and the second laser beam reflected by the other reflecting mirror are combined,
the first semiconductor laser module, the first optical element or the second optical element, the fifth optical element, and the reflecting mirror are provided on one step among the steps, and
the second semiconductor laser module, the third optical element or the fourth optical element, the sixth optical element, and the other reflecting mirror are provided on an other step different from the one step among the steps.

22. The light source module according to claim 21,
wherein the first laser beam is collimated in a direction along the third optical axis and in a direction along the second optical axis after the first laser beam passes through the fifth optical element,
the second laser beam is collimated in a direction along the sixth optical axis and in a direction along the fifth optical axis after the second laser beam passes through the sixth optical element.

23. A light source module comprising:
a first semiconductor laser module including a first semiconductor laser element hermetically sealed;
a first optical element included in the first semiconductor laser module or a second optical element provided outside the first semiconductor laser module, the first optical element and the second optical element being each an optical element on which a first laser beam emitted from the first semiconductor laser element is incident;
a fifth optical element on which the first laser beam having passed through the first optical element or the second optical element is incident;
a reflecting mirror that reflects the first laser beam having passed through the fifth optical element;
a second semiconductor laser module including a second semiconductor laser element hermetically sealed;
a third optical element included in the second semiconductor laser module or a fourth optical element provided outside the second semiconductor laser module, the third optical element and the fourth optical element being each an optical element on which a second laser beam emitted from the second semiconductor laser element is incident;
a sixth optical element on which the second laser beam having passed through the third optical element or the fourth optical element is incident;
an other reflecting mirror that is different from the reflecting mirror and reflects the second laser beam having passed through the sixth optical element; and
a multistep base including steps,
wherein a traveling direction of the first laser beam along a first optical axis is defined as a first direction, the first optical axis being an optical axis from the first semiconductor laser element to the fifth optical element,
the first laser beam has a second optical axis perpendicular to the first direction, and a third optical axis perpendicular to the first direction and the second optical axis,
the first optical element or the second optical element has power along the second optical axis greater than power along the third optical axis,
the fifth optical element has power along the third optical axis greater than power along the second optical axis,
a traveling direction of the second laser beam along a fourth optical axis is defined as a second direction, the fourth optical axis being an optical axis from the second semiconductor laser element to the sixth optical element,
the second laser beam has a fifth optical axis perpendicular to the second direction, and a sixth optical axis perpendicular to the second direction and the fifth optical axis,
the third optical element or the fourth optical element has power along the fifth optical axis greater than power along the sixth optical axis,
the sixth optical element has power along the sixth optical axis greater than power along the fifth optical axis,
the first laser beam reflected by the reflecting mirror and the second laser beam reflected by the other reflecting mirror are combined,
the first semiconductor laser module, the first optical element or the second optical element, the fifth optical element, and the reflecting mirror are provided on one step among the steps, and
the second semiconductor laser module, the third optical element or the fourth optical element, the sixth optical element, and the other reflecting mirror are provided on an other step different from the one step among the steps,
the first semiconductor laser module includes:
a package including a frame body in a center of which a first opening is provided; and
a lid,
the lid covers an upper portion of the first opening, and
a direction in which the upper portion is viewed from the first opening is a direction parallel to the second optical axis.

24. The light source module according to claim 23,
the first laser beam is collimated in a direction along the third optical axis and in a direction along the second optical axis after the first laser beam passes through the fifth optical element,
the second laser beam is collimated in a direction along the sixth optical axis and in a direction along the fifth optical after the second laser beam passes through the sixth optical element.

25. The light source module according to claim 23, comprising:
a light-transmissive window through which the first laser beam passes to an outside of the first semiconductor laser module,
wherein the first semiconductor laser element is disposed in the first opening.
